(19) United States
(12) Patent Application Publication
(10) Pub. No.: US 2026/0231390 A1
(43) Pub. Date: Aug. 6, 2026

(54) SEMICONDUCTOR DEVICE

(71) Applicant: Semiconductor Energy Laboratory Co., Ltd., Atsugi-shi, Kanagawa-ken (JP)

(72) Inventors: Shunpei YAMAZAKI, Setagaya (JP); Hiroki INOUE, Atsugi (JP); Takanori MATSUZAKI, Atsugi (JP); Yuto YAKUBO, Atsugi (JP)

(21) Appl. No.: 19/150,256

(22) PCT Filed: Feb. 16, 2024
(86) PCT No.: PCT/IB2024/051459

§ 371 Date: Jul. 23, 2025

(30) Foreign Application Priority Data
Feb. 24, 2023 (JP) 2023-026969
Sep. 5, 2023 (JP) 2023-143819

(51) Int. Cl. H10B 12/00

(52) U.S. Cl. CPC H10B 12/00

(57) ABSTRACT

A small-sized semiconductor device is provided. The semiconductor device includes a CPU, a switch circuit, and a plurality of memory cell arrays. The CPU includes a register circuit. The register circuit includes a volatile flip-flop circuit and a nonvolatile backup circuit. The flip-flop circuit and circuits other than the backup circuit included in the CPU are provided in a first layer and each include a transistor including silicon in a channel formation region. The switch circuit and the backup circuit are provided in a second layer over the first layer and each include a transistor including a metal oxide in a channel formation region. A memory cell array to which data is written or a memory cell array from which data is read can be selected by the switch circuit. The switch circuit can retain a selection result of the memory cell array to which data is written or the memory cell array from which data is read.

### TECHNICAL FIELD

One embodiment of the present invention relates to a semiconductor device. One embodiment of the present invention relates to a memory device. One embodiment of the present invention relates to a method for driving a semiconductor device. One embodiment of the present invention relates to a method for driving a memory device.

Note that in this specification and the like, a semiconductor device generally means a device that can function by utilizing semiconductor characteristics. A semiconductor element such as a transistor, a semiconductor circuit, an arithmetic device, and a memory device are each one embodiment of a semiconductor device. It can be sometimes said that a display device (a liquid crystal display device, a light-emitting display device, and the like), a projection device, a lighting device, an electro-optical device, a power storage device, a memory device, a semiconductor circuit, an imaging device, an electronic appliance, and the like include a semiconductor device.

One embodiment of the present invention is not limited to the above technical field. One embodiment of the invention disclosed in this specification and the like relates to an object, a method, or a manufacturing method. One embodiment of the present invention relates to a process, a machine, manufacture, or a composition of matter.

### BACKGROUND ART

A semiconductor circuit (IC chip) of a CPU (Central Processing Unit), a memory, and the like is mounted on a printed wiring board or the like to be used as one of components of a variety of electronic appliances. A technique in which a transistor is formed using a semiconductor thin film has attracted attention. The transistor is practically used in an electronic device such as an image display device (also simply referred to as a display device) and is expected to be used in the semiconductor circuit as well.

A silicon-based semiconductor material is widely known as a semiconductor thin film applicable to the transistor, and a metal oxide has been attracting attention as another material. It is known that the current flowing through a transistor including a metal oxide in the non-conducting state (off state) is extremely low.

For example, Patent Document 1 discloses a memory device and the like that can retain stored contents for a long time by utilizing a characteristic of a low leakage current of a transistor including a metal oxide.

In recent years, demand for an integrated circuit with higher density has risen with reductions in size and weight of electronic appliances. For example, Patent Document 2 and Non-Patent Document 1 each disclose a technique to achieve an integrated circuit with higher density by making a plurality of memory cells overlap each other by stacking a first transistor using a metal oxide film and a second transistor using a metal oxide film.

Furthermore, by employing vertical transistors, an integrated circuit with higher density can be achieved. For example, Patent Document 3 discloses a vertical transistor in which a side surface of a metal oxide is covered with a gate electrode with a gate insulating layer therebetween.

### REFERENCES

### Patent Documents

[Patent Document 1] Japanese Published Patent Application No. 2011-151383
[Patent Document 2] PCT International Publication No. 2021/053473
[Patent Document 3] Japanese Published Patent Application No. 2013-211537

### Non-Patent Document

[Non-Patent Document 1]
[Non-Patent Document 1] M. Oota et. al, “3D-Stacked CAAC-In—Ga—Zn Oxide FETs with Gate Length of 72 nm”, IEDM Tech. Dig., 2019, pp. 50-53

### SUMMARY OF THE INVENTION

### Problems to be Solved by the Invention

A transistor including silicon, specifically, a transistor including silicon in a channel formation region (also referred to as a Si transistor), sometimes has a higher on-state current than a transistor including a metal oxide, specifically, a transistor including a metal oxide in a channel formation region (also referred to as an OS transistor). For example, a Si transistor including silicon with high crystallinity, such as single crystal silicon or polycrystalline silicon, in a channel formation region has a higher on-state current than an OS transistor. Therefore, transistors included in a CPU, for example, are preferably Si transistors. For example, Si transistor are preferably used in a control circuit having a function of controlling the driving of the CPU and a register circuit having a function of retaining data used for arithmetic operations of the CPU.

The register circuit includes a flip-flop circuit and can retain data by the flip-flop circuit. However, when supply of power supply voltage to the flip-flop circuit is stopped, the retained data is lost. Thus, when a nonvolatile backup circuit is provided in the register circuit and backs up data in the flip-flop circuit, the data can be recovered even when the data in the flip-flop circuit is lost. Accordingly, the CPU can be power-gated, so that power consumption of a semiconductor device including the CPU can be reduced. An OS transistor having a lower off-state current than a Si transistor is preferably used in the backup circuit, for example.

As described above, it is preferable that Si transistors be used for the control circuit, the flip-flop circuit, and the like included in the CPU and OS transistors be used for the backup circuit. In this case, for example, the control circuit, the flip-flop circuit, and the like are provided in a first layer, and the backup circuit is provided in a second layer over the first layer. Here, for example, in the case where the backup circuit included in the CPU is provided in the second layer and circuits other than the backup circuit are provided in the first layer, the number of elements such as transistors provided in the second layer is smaller than the number of elements such as transistors provided in the first layer. Thus, a dead space (a region where elements are not provided) is larger in the second layer than in the first layer.

An object of one embodiment of the present invention is to provide a semiconductor device with a small dead space. Another object of one embodiment of the present invention is to provide a small-sized semiconductor device. Another object of one embodiment of the present invention is to provide a semiconductor device with low power consumption. Another object of one embodiment of the present invention is to provide a semiconductor device that is driven at high speed. Another object of one embodiment of the present invention is to provide a semiconductor device with a high degree of integration. Another object of one embodiment of the present invention is to provide a semiconductor device with favorable electrical characteristics. Another object of one embodiment of the present invention is to provide a semiconductor device with high reliability. Another object of one embodiment of the present invention is to provide a novel semiconductor device. Another object of one embodiment of the present invention is to provide a novel memory device. Another object of one embodiment of the present invention is to provide a method for driving a novel semiconductor device. Another object of one embodiment of the present invention is to provide a method for driving a novel memory device.

The description of a plurality of objects does not preclude the existence of each object. One embodiment of the present invention does not necessarily achieve all the objects described as examples. Furthermore, objects other than those listed will be apparent from the description of this specification, and such objects can be objects of one embodiment of the present invention.

### Means for Solving the Problems

One embodiment of the present invention is a semiconductor device including a CPU, a switch circuit, a first memory cell array, and a second memory cell array. The CPU includes a control circuit and a register circuit. The register circuit includes a flip-flop circuit and a backup circuit. First memory cells are arranged in a matrix in the first memory cell array. Second memory cells are arranged in a matrix in the second memory cell array. The control circuit and the flip-flop circuit are provided in a first layer. The switch circuit and the backup circuit are provided in a second layer over the first layer. The first memory cell array and the second memory cell array are provided in a third layer over the second layer. The switch circuit has a function of supplying a signal to one of the first memory cell and the second memory cell. The control circuit and the flip-flop circuit each include a transistor including silicon in a channel formation region. The switch circuit and the backup circuit each include a transistor including a metal oxide in a channel formation region.

Another embodiment of the present invention is a semiconductor device including a CPU, a switch circuit, a first memory cell array, and a second memory cell array. The CPU includes a control circuit and a register circuit. The register circuit includes a flip-flop circuit and a backup circuit. First memory cells are arranged in a matrix in the first memory cell array. Second memory cells are arranged in a matrix in the second memory cell array. The first memory cell includes a first transistor and a second transistor. The second memory cell includes a third transistor and a fourth transistor. The control circuit and the flip-flop circuit are provided in a first layer. The switch circuit and the backup circuit are provided in a second layer over the first layer. The first transistor and the third transistor are provided in a third layer over the second layer. The second transistor and the fourth transistor are provided in a fourth layer over the third layer. The switch circuit has a function of supplying a signal to one of the first memory cell and the second memory cell. The control circuit and the flip-flop circuit each include a transistor including silicon in a channel formation region. The switch circuit and the backup circuit each include a transistor including a metal oxide in a channel formation region. The first to fourth transistors each include a metal oxide in a channel formation region.

In the above embodiment, the switch circuit may include a fifth transistor, a sixth transistor, a seventh transistor, and an eighth transistor. The signal may be supplied to one of a source and a drain of the fifth transistor and one of a source and a drain of the sixth transistor. A gate of the fifth transistor may be electrically connected to one of a source and a drain of the seventh transistor. A gate of the sixth transistor may be electrically connected to one of a source and a drain of the eighth transistor. A first selection signal may be supplied to the other of the source and the drain of the seventh transistor. A second selection signal may be supplied to the other of the source and the drain of the eighth transistor. The signal may be output from the other of the source and the drain of the fifth transistor or the other of the source and the drain of the sixth transistor based on the first selection signal and the second selection signal. When the signal is output from the other of the source and the drain of the fifth transistor, the signal may be supplied to the first memory cell. When the signal is output from the other of the source and the drain of the sixth transistor, the signal may be supplied to the second memory cell.

In the above embodiment, the switch circuit may include a first capacitor and a second capacitor. One electrode of the first capacitor may be electrically connected to the gate of the fifth transistor. The other electrode of the first capacitor may be electrically connected to the other of the source and the drain of the fifth transistor. One electrode of the second capacitor may be electrically connected to a gate of the seventh transistor. The other electrode of the second capacitor may be electrically connected to the other of the source and the drain of the seventh transistor.

In the above embodiment, the third layer may include a first insulating layer. The fourth layer may include a second insulating layer. The first insulating layer may include a first opening portion and a second opening portion. The second insulating layer may include a third opening portion and a fourth opening portion. The channel formation region of the first transistor may include a region along a side surface of the first opening portion. The channel formation region of the second transistor may include a region along a side surface of the second opening portion. The channel formation region of the third transistor may include a region along a side surface of the third opening portion. The channel formation region of the fourth transistor may include a region along a side surface of the fourth opening portion.

In the above embodiment, the first memory cell may have a function of retaining first data. The second memory cell may have a function of retaining second data. The first data and the second data may differ in type.

In the above embodiment, the first data or the second data may be program data.

### Effect of the Invention

One embodiment of the present invention can provide a semiconductor device with a small dead space. Another embodiment of the present invention can provide a small-sized semiconductor device. Another embodiment of the present invention can provide a semiconductor device with low power consumption. Another embodiment of the present invention can provide a semiconductor device that is driven at high speed. Another embodiment of the present invention can provide a semiconductor device with a high degree of integration. Another embodiment of the present invention can provide a semiconductor device with favorable electrical characteristics. Another embodiment of the present invention can provide a semiconductor device with high reliability. Another embodiment of the present invention can provide a novel semiconductor device. Another embodiment of the present invention can provide a novel memory device. Another embodiment of the present invention can provide a method for driving a novel semiconductor device. Another embodiment of the present invention can provide a method for driving a novel memory device.

The description of a plurality of effects does not preclude the existence of other effects. In addition, one embodiment of the present invention does not necessarily achieve all the effects described as examples. In one embodiment of the present invention, objects, effects, and novel features other than the above will be apparent from the description of this specification and the drawings.

### BRIEF DESCRIPTION OF THE DRAWINGS

FIG. 1 is a perspective view illustrating a structure example of a semiconductor device.

FIG. 2 is a block diagram illustrating a structure example of a semiconductor device.

FIG. 3A to FIG. 3D are circuit diagrams illustrating structure examples of switch circuits.

FIG. 4A and FIG. 4B are timing charts each showing an example of a method for driving a switch circuit.

FIG. 5 is a block diagram illustrating a structure example of a semiconductor device.

FIG. 6 is a circuit diagram illustrating a structure example of a semiconductor device.

FIG. 7 is a circuit diagram illustrating a structure example of a semiconductor device.

FIG. 8A and FIG. 8B are circuit diagrams illustrating structure examples of a register circuit.

FIG. 9 is a circuit diagram illustrating a structure example of a register circuit.

FIG. 10 is a timing chart showing an example of a method for driving a register circuit.

FIG. 11A to FIG. 11D are circuit diagrams illustrating structure examples of a memory cell.

FIG. 12 is a timing chart showing an example of a method for driving a memory cell.

FIG. 13A and FIG. 13B are perspective views illustrating structure examples of a memory cell.

FIG. 14A and FIG. 14B are plan views each illustrating a structure example of a transistor.

FIG. 14C to FIG. 14E are cross-sectional views illustrating structure examples of a memory cell.

FIG. 15A is a perspective view illustrating a structure example of a memory cell. FIG. 15B and FIG. 15C are cross-sectional views illustrating structure examples of a memory cell.

FIG. 16A is a cross-sectional view illustrating a structure example of a transistor. FIG. 16B is a plan view illustrating a structure example of a transistor.

FIG. 17A is a plan view illustrating a structure example of a transistor. FIG. 17B to FIG. 17D are cross-sectional views illustrating a structure example of a transistor.

FIG. 18 is a cross-sectional view illustrating a structure example of a semiconductor device.

FIG. 19 is a cross-sectional view illustrating a structure example of a semiconductor device.

FIG. 20 is a cross-sectional view illustrating a structure example of a semiconductor device.

FIG. 21 is a cross-sectional view illustrating a structure example of a semiconductor device.

FIG. 22 is a cross-sectional view illustrating a structure example of a semiconductor device.

FIG. 23 is a cross-sectional view illustrating a structure example of a semiconductor device.

FIG. 24A and FIG. 24B are perspective views illustrating a structure example of a semiconductor device.

FIG. 25 is a perspective view illustrating a structure example of a semiconductor device.

FIG. 26A and FIG. 26B are diagrams illustrating examples of electronic components.

FIG. 27A and FIG. 27B are diagrams illustrating examples of electronic appliances. FIG. 27C to FIG. 27E are diagrams illustrating an example of a large computer.

FIG. 28 is a diagram illustrating an example of space equipment.

FIG. 29 is a diagram illustrating an example of a storage system that can be used in a data center.

FIG. 30A and FIG. 30B are diagrams each illustrating a hierarchy of a variety of memory devices.

FIG. 31 is a block diagram illustrating a TEG of Example.

FIG. 32 is a timing chart showing the operation of a TEG of Example.

FIG. 33 is a graph showing the rate of correct bits against data retention time in a memory device of Example.

FIG. 34A to FIG. 34E are images each showing a planar layout of a chip of Example.

FIG. 35A and FIG. 35B are STEM images of Example.

### MODE FOR CARRYING OUT THE INVENTION

Embodiments will be described below with reference to the drawings. Note that the embodiments can be implemented with many different modes, and it will be readily appreciated by those skilled in the art that modes and details can be changed in various ways without departing from the spirit and scope thereof. Therefore, the present invention should not be construed as being limited to the description of embodiments below.

In the drawings, the size, the layer thickness, or the region is exaggerated for clarity in some cases. Therefore, the size, the layer thickness, or the region is not limited to the illustrated scale. Note that the drawings schematically illustrate ideal examples, and embodiments of the present invention are not limited to shapes, values, and the like illustrated in the drawings.

Unless otherwise specified, off-state current in this specification and the like refers to drain current of a transistor in an off state (also referred to as a non-conducting state or a cutoff state). Unless otherwise specified, the off state refers to a state where voltage Vgs between a gate and a source is lower than threshold voltage Vth in an n-channel transistor (higher than Vth in a p-channel transistor).

In this specification and the like, a metal oxide is an oxide of a metal in a broad sense. Metal oxides are classified into an oxide insulator, an oxide conductor (including a transparent oxide conductor), an oxide semiconductor (also simply referred to as OS), and the like. For example, in the case where a metal oxide is used for an active layer of a transistor, the metal oxide is referred to as an oxide semiconductor in some cases. That is, an OS transistor can also be referred to as a transistor including a metal oxide or an oxide semiconductor.

### Embodiment 1

In this embodiment, structure examples of a semiconductor device will be described with reference to drawings. Specifically, structure examples of a memory device that is one embodiment of a semiconductor device will be described with reference to drawings.

One embodiment of the present invention relates to a semiconductor device including a CPU, a driver circuit, and a plurality of memory cell arrays. The memory cell arrays are provided over a layer where the CPU and the driver circuit are provided.

In each of the memory cell arrays, memory cells are arranged in a matrix. The driver circuit has a function of driving the memory cells. The driver circuit has functions of writing data to the memory cells and reading data from the memory cells by supplying signals to the memory cells, for example.

The CPU includes a control circuit, a register circuit, and the like. The control circuit has a function of controlling the driving of the CPU and is also referred to as a CPU control circuit. The register circuit includes a flip-flop circuit and a backup circuit. The flip-flop circuit has a function of retaining data used for arithmetic operations of the CPU. The backup circuit has a function of backing up data in the flip-flop circuit.

The flip-flop circuit is a volatile circuit, and data retained therein is lost when supply of power supply voltage to the CPU is stopped. Meanwhile, the backup circuit is a nonvolatile circuit and can retain data for a long time even when supply of power supply voltage to the CPU is stopped. Thus, by providing the backup circuit in the register circuit to back up data in the flip-flop circuit, the data can be recovered from the backup circuit even when the data in the flip-flop circuit is lost. Consequently, the CPU can be power-gated, so that power consumption of the semiconductor device can be reduced.

Here, a transistor with a low off-state current is preferably used for the backup circuit, in which case data can be retained for a long time. For example, an OS transistor is preferably used for the backup circuit. Meanwhile, a transistor with a high on-state current is preferably used for circuits other than the backup circuit, such as the control circuit and the flip-flop circuit, in which case the CPU can be driven at high speed. For example, a Si transistor is preferably used for the circuits other than the backup circuit.

In the case where the transistor included in the backup circuit and the transistor included in the circuits other than the backup circuit have different structures as described above, the backup circuit is provided in a layer different from the other circuits. For example, the circuits other than the backup circuit are provided in a first layer, and the backup circuit is provided in a second layer over the first layer. In this case, the number of elements such as transistors provided in the second layer is smaller than the number of elements such as transistors provided in the first layer. Thus, a dead space is larger in the second layer than in the first layer.

In the semiconductor device of one embodiment of the present invention, a switch circuit is provided in the second layer where the backup circuit is provided. The switch circuit has a function of supplying, to any one of the plurality of memory cell arrays, a signal supplied from the driver circuit. The switch circuit has a function of selecting, for example, a memory cell array to which data is to be written or a memory cell array from which data is to be read. The switch circuit can select a memory cell array to which data is to be written or a memory cell array from which data is to be read, for example, on the basis of a selection signal.

In this specification and the like, supplying a signal to at least one of the memory cells provided in a memory cell array is sometimes referred to as supplying a signal to the memory cell array. Writing data to at least one of the memory cells provided in a memory cell array is referred to as writing data to the memory cell. Reading data from at least one of the memory cells provided in a memory cell array is referred to as reading data from the memory cell.

When the switch circuit is provided for the split memory cell arrays, a load on the driver circuit can be reduced while an increase in the area occupied by the driver circuit is suppressed. Thus, a small-sized semiconductor device that is driven at high speed can be provided.

By providing the switch circuit in the second layer where the backup circuit is provided, the dead space in the second layer can be reduced. Hence, a semiconductor device that is smaller in size than when the switch circuit is provided in the first layer, for example, can be provided. Moreover, transistors included in the switch circuit can be OS transistors. Thus, a selection result of a memory cell array to which data is written or a memory cell array from which data is read, for example, can be retained in the switch circuit for a long time. Accordingly, it is not necessary to supply a selection signal to the switch circuit while data is written to the memory cells provided in the same memory cell array or data is read from the memory cells provided in the same memory cell array, for example. Consequently, a semiconductor device with low power consumption can be provided. In particular, power consumption of the semiconductor device can be reduced more favorably as a period during which data is written to the memory cells provided in the same memory cell array or a period during which data is read from the memory cells provided in the same memory cell array is longer.

### Structure Example_1 of Semiconductor Device

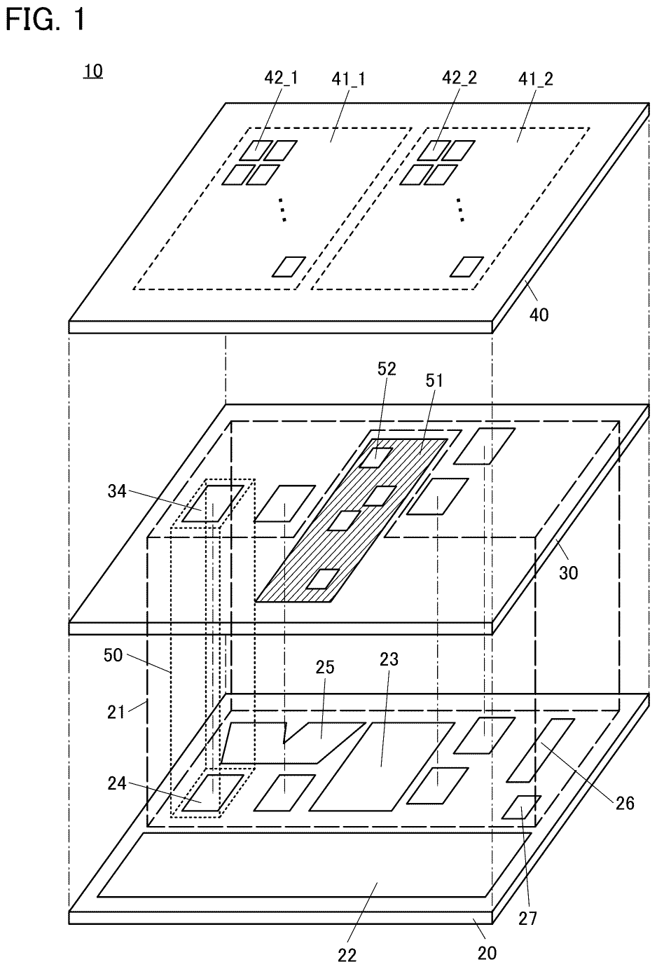

FIG. 1 is a perspective view illustrating a structure example of a semiconductor device 10 that is the semiconductor device of one embodiment of the present invention. The perspective view is also referred to as a block diagram. The semiconductor device 10 includes a layer 20, a layer 30 over the layer 20, and a layer 40 over the layer 30. In FIG. 1, the layer 20, the layer 30, the layer 40, and the like are illustrated apart from each other in order to easily recognize the structure example of each layer; however, in reality, the layer 30 may be in contact with the top surface of the layer 20 and the layer 40 may be in contact with the top surface of the layer 30.

The semiconductor device 10 includes a CPU 21, a driver circuit 22, a switch circuit group 51, and a memory cell array 41. In the memory cell array 41, memory cells 42 are arranged in a matrix. The semiconductor device 10 includes a plurality of the memory cell arrays 41. FIG. 1 illustrates an example in which the semiconductor device 10 includes a memory cell array 41_1 and a memory cell array 41_2 as the memory cell arrays 41. Here, the memory cells 42 arranged in the memory cell array 41_1 are referred to as memory cells 42_1, and the memory cells 42 arranged in the memory cell array 41_2 are referred to as memory cells 42_2. Because of including the memory cell arrays 41, the semiconductor device 10 can be regarded as a memory device.

In this specification, the drawings, and the like, when a plurality of components are denoted with the same reference numerals, and in particular need to be distinguished from each other, an identification sign such as “_1”, “[1]”, “[1,1]”, or “<1>” is sometimes added to the reference numerals. When matters common to a plurality of components with identification signs are described or they do not need to be distinguished from each other, no identification sign is added in the description in some cases.

The memory cell array 41 is provided to include a region overlapping the CPU 21 and the driver circuit 22. Thus, the semiconductor device can be downsized as compared with the case where the memory cell array 41 is provided in the same layer as the CPU 21, the driver circuit 22, and the like, for example.

Although a block diagram in which components are classified by their functions and shown as independent blocks is shown in the drawing attached to this specification, it is difficult to completely separate actual components according to their functions and one component can relate to a plurality of functions.

The CPU 21 is provided across the layer 20 and the layer 30. The CPU 21 includes a control circuit 23, a register circuit 50, an arithmetic circuit 25, a cache memory 26, a memory controller 27, and the like. The register circuit 50 includes a flip-flop circuit 24 and a backup circuit 34. Note that the CPU 21, the cache memory 26, the memory controller 27, and the like are also circuits. The memory cell 42 is also a circuit.

The control circuit 23, the arithmetic circuit 25, the cache memory 26, the memory controller 27, and the flip-flop circuit 24 are provided in the layer 20. The backup circuit 34 is provided in the layer 30. Since the flip-flop circuit 24 is provided in the layer 20 and the backup circuit 34 is provided in the layer 30, the register circuit 50 is provided across the layer 20 and the layer 30.

The components of the register circuit 50 are interspersed as illustrated in FIG. 1. Thus, the dead space in the layer 20 can be reduced, so that the semiconductor device 10 can be downsized.

The backup circuit 34 is preferably provided to include a region overlapping the flip-flop circuit 24. In that case, the connection distance (wiring length) between the flip-flop circuit 24 and the backup circuit 34 can be shortened. This can reduce the wiring resistance and parasitic capacitance of a wiring that electrically connects the flip-flop circuit 24 and the backup circuit 34. As a result, the time taken for charging and discharging the wiring is shortened, so that the register circuit 50 can be driven at high speed. Moreover, power consumption of the semiconductor device 10 can be reduced.

The control circuit 23 has a function of controlling the driving of the CPU 21. The control circuit 23 can control the driving of the CPU 21 by supplying a control signal to another circuit included in the CPU 21, for example. The control signal can be a clock signal, a timing signal, or the like. The control circuit 23 is also referred to as a CPU control circuit.

The flip-flop circuit 24 has functions of retaining data used for arithmetic operations of the CPU 21 and outputting the data in accordance with a control signal generated by the control circuit 23, for example. The backup circuit 34 has a function of backing up data retained in the flip-flop circuit 24.

The flip-flop circuit 24 is a volatile circuit, and data retained therein is lost when supply of power supply voltage to the CPU 21 is stopped. Meanwhile, the backup circuit 34 is a nonvolatile circuit and can retain data for a long time even when supply of power supply voltage to the CPU is stopped. Thus, by providing the backup circuit 34 in the register circuit 50 to back up data in the flip-flop circuit 24, the data can be recovered even when the data in the flip-flop circuit 24 is lost. Consequently, the CPU 21 can be power-gated, so that the semiconductor device 10 can have low power consumption.

The arithmetic circuit 25 has a function of performing a variety of arithmetic processing such as four arithmetic operations and logic operations. The cache memory 26 has a function of temporarily retaining frequently used data. The memory controller 27 has a function of controlling the driving of the driver circuit 22. The memory controller 27 can control driving of the driver circuit 22 by supplying a control signal to the driver circuit 22, for example. As described above, the control signal can be a clock signal, a timing signal, or the like. The memory controller 27 is also referred to as a driving control circuit, a memory control circuit, a memory driving control circuit, or the like.

The driver circuit 22 has functions of writing data to the memory cell 42 and reading data from the memory cell 42 by supplying a signal to the memory cell 42, for example. The driver circuit 22 is also referred to as a memory driver circuit, a memory cell driver circuit, or a memory cell array driver circuit.

The circuits and the like provided in the layer 20 are preferably driven at high speed. Thus, transistors included in the circuits and the like provided in the layer 20 are preferably transistors with high field-effect mobility. As the transistors, Si transistors, specifically transistors including silicon with high crystallinity, such as single crystal silicon or polycrystalline silicon, in their channel formation regions can be suitably used, for example. In the circuits and the like provided in the layer 20, a CMOS (Complementary Metal Oxide Semiconductor) is preferably provided, for example.

The backup circuit 34 is preferably capable of retaining data for a long time. Accordingly, the frequency of rewriting data to the backup circuit 34 can be reduced, so that the semiconductor device 10 can have low power consumption. In the backup circuit 34, a transistor having a lower off-state current than a Si transistor is preferably used, for example. An example of such a transistor is an OS transistor.

In the case where the transistor included in the backup circuit 34 and the transistor included in the circuits and the like other than the backup circuit 34 have different structures as described above, the backup circuit 34 is provided in a layer different from the other circuits and the like. For example, the circuits and the like other than the backup circuit 34 are provided in the layer 20, and the backup circuit 34 is provided in the layer 30. In this case, the number of elements such as transistors provided in the layer 30 is smaller than the number of elements such as transistors provided in the layer 20. Thus, a dead space is larger in the layer 30 than in the layer 20.

In the semiconductor device 10, a switch circuit 52 is provided in the layer 30 where the backup circuit 34 is provided. A plurality of the switch circuits 52 can be provided in the layer 30. The plurality of switch circuits 52 are collectively referred to as the switch circuit group 51. Although the switch circuit group 51 is one region in FIG. 1, the switch circuit group 51 may be a plurality of regions separated from each other.

The switch circuit group 51 can include a region overlapping the CPU 21. The switch circuit group 51 can include a region overlapping the driver circuit 22. FIG. 1 illustrates an example in which the switch circuit group 51 includes a region overlapping the control circuit 23. Note that the switch circuit group 51 may include a region overlapping a circuit other than the control circuit 23 in the CPU 21. The switch circuit group 51 does not necessarily overlap the control circuit 23.

The switch circuit 52 has a function of supplying, to one of the memory cell array 41_1 and the memory cell array 41_2, a signal supplied from the driver circuit 22. The switch circuit 52 has a function of selecting, for example, the memory cell array 41 to which data is to be written or the memory cell array 41 from which data is to be read.

The switch circuit group 51 is provided for the split memory cell arrays 41, whereby a load on the driver circuit 22 can be reduced while an increase in the area occupied by the driver circuit 22 is suppressed. Thus, the semiconductor device 10 can be small in size and driven at high speed. Note that at least part of the switch circuit group 51 may be included in the CPU 21. In other words, at least one switch circuit 52 may be provided in the CPU 21.

When the switch circuit group 51 is provided in the layer 30 where the backup circuit 34 is provided, the dead space in the layer 30 can be smaller than that in the case where the switch circuit group 51 is provided in the layer 20, for example, and thus the semiconductor device 10 can be a small-sized semiconductor device. Moreover, transistors provided in the switch circuit group 51 can be OS transistors. Consequently, a selection result of the memory cell array 41 to which data is written or the memory cell array 41 from which data is read, for example, can be retained in the switch circuit 52 for a long time. Accordingly, it is not necessary to supply a selection signal to the switch circuit 52 while data is written to the memory cells 42 provided in one memory cell array 41 or data is read from the memory cells 42 provided in one memory cell array 41, for example. Therefore, the semiconductor device 10 can be a semiconductor device with low power consumption.

Note that the CPU 21 may be a GPU (Graphics Processing Unit), for example. The GPU can be provided with the register circuit 50 including the flip-flop circuit 24 and the backup circuit 34, and the switch circuit group 51 can be provided in the same layer as the backup circuit 34.

Here, power consumption of the semiconductor device 10 can be reduced more favorably as a period during which data is written to the memory cells 42 provided in one memory cell array 41 or a period during which data is read from the memory cells 42 provided in one memory cell array 41 is longer. Thus, for example, the memory cells 42 provided in one memory cell array 41 preferably retain data of the same type. In other words, data of different types are preferably retained in the memory cells 42 provided in different memory cell arrays 41. For example, first data retained in the memory cell 42_1 and second data retained in the memory cell 42_2 preferably differ in type.

For example, one of the first data and the second data can be program data, and the other of the first data and the second data can be data created by the user of the semiconductor device 10. For example, the other of the first data and the second data can be data that is created by the user operating an application program and stored in a file. Here, for example, the one of the first data and the second data may be not stored in a storage device, and the other of the first data and the second data may be stored in a storage device. Examples of a storage device include recording media drives such as a hard disk drive (HDD) and a solid state drive (SSD), a flash memory, a Blu-ray Disc (Blu-rayDisk) (registered trademark), and a DVD (Digital Versatile Disc).

In this specification and the like, data stored in a file is referred to as file data in some cases.

Alternatively, data may be retained in different memory cell arrays 41 depending on application programs. For example, program data, file data, and the like created by a first application program may be used as the first data, and program data, file data, and the like created by a second application program may be used as the second data.

For example, frequently used data may be retained in both the memory cell 42_1 and the memory cell 42_2. For example, data that is frequently used among data used by an operating system may be retained in both the memory cell 42_1 and the memory cell 42_2.

Here, the number of memory cells 42 may differ between the memory cell arrays 41. For example, the number of memory cells 42_1 and the number of memory cells 42_2 may be different from each other. For example, in the case where the number of memory cells 42_1 is smaller than the number of memory cells 42_2, of the first data and the second data, the data with a smaller capacity can be retained in the memory cell 42_1 and the data with a larger capacity can be retained in the memory cell 42_2. Thus, it is sometimes possible to lengthen a period during which data is written to the memory cells 42 provided in one memory cell array 41 and a period during which data is read from the memory cells 42 provided in one memory cell array 41.

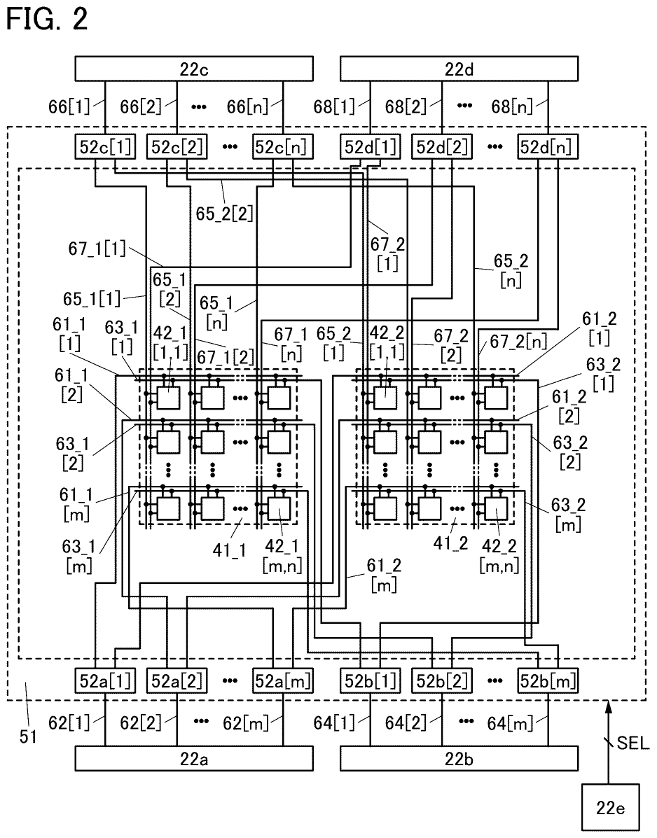

FIG. 2 is a block diagram illustrating a more detailed structure example of the driver circuit 22, the memory cell array 41_1, the memory cell array 41_2, and the switch circuit group 51 than in FIG. 1. FIG. 2 illustrates an example in which the memory cells 42_1 and the memory cells 42_2 are independently arranged in a matrix of m rows and n columns (m and n are each an integer greater than or equal to 1). Here, the memory cell 42_1 in the first row and the first column, the memory cell 42_1 in the m-th row and the n-th column, the memory cell 42_2 in the first row and the first column, and the memory cell 42_2 in the m-th row and the n-th column are respectively referred to as a memory cell 42_1[1,1], a memory cell 42_1[m,n], a memory cell 42_2[1,1], and a memory cell 42_2[m,n].

Regarding the memory cells 42_1 and the memory cells 42_2, the memory cells 42 in the same row can be electrically connected to one wiring 61 and one wiring 63. For example, the memory cells 42_1 in the first row can be electrically connected to a wiring 61_1[1] and a wiring 63_1[1], the memory cells 42_1 in the second row can be electrically connected to a wiring 61_1[2] and a wiring 63_1[2], and the memory cells 42_1 in the m-th row can be electrically connected to a wiring 61_1[m] and a wiring 63_1[m]. Similarly, the memory cells 42_2 in the first row can be electrically connected to a wiring 61_2[1] and a wiring 63_2[1], the memory cells 42_2 in the second row can be electrically connected to a wiring 61_2[2] and a wiring 63_2[2], and the memory cells 42_2 in the m-th row can be electrically connected to a wiring 61_2[m] and a wiring 63_2[m]. The wiring 61 and the wiring 63 function as word lines.

The memory cells 42 in the same column can be electrically connected to one wiring 65 and one wiring 67. For example, the memory cells 42_1 in the first column can be electrically connected to a wiring 65_1[1] and a wiring 67_1[1], the memory cells 42_1 in the second column can be electrically connected to a wiring 65_1[2] and a wiring 67_1[2], and the memory cells 42_1 in the n-th row can be electrically connected to a wiring 65_1[n] and a wiring 67_1[n]. Similarly, the memory cells 42_2 in the first column can be electrically connected to a wiring 65_2[1] and a wiring 67_2[1], the memory cells 42_2 in the second column can be electrically connected to a wiring 65_2[2] and a wiring 67_2[2], and the memory cells 42_2 in the n-th row can be electrically connected to a wiring 65_2[n] and a wiring 67_2[n]. The wiring 65 and the wiring 67 function as bit lines.

The switch circuit group 51 includes m switch circuits 52a, m switch circuits 52b, n switch circuits 52c, and n switch circuits 52d as the switch circuits 52. Here, the m switch circuits 52a are referred to as a switch circuit 52a[1] to a switch circuit 52a[m] and the m switch circuits 52b are referred to as a switch circuit 52b[1] to a switch circuit 52b[m] to make a distinction. The n switch circuits 52c are referred to as a switch circuit 52c[1] to a switch circuit 52c[n] and the n switch circuits 52d are referred to as a switch circuit 52d[1] to a switch circuit 52d[n] to make a distinction.

The switch circuit 52a[i] (i is an integer greater than or equal to 1 and less than or equal to m) is electrically connected to a wiring 62[i]. The switch circuit 52b[i] is electrically connected to a wiring 64[i]. The switch circuit 52c[j] (j is an integer greater than or equal to 1 and less than or equal to n) is electrically connected to a wiring 66[j]. The switch circuit 52d[j] is electrically connected to a wiring 68[j]. The wiring 62 and the wiring 64 function as word lines, and the wiring 66 and the wiring 68 function as bit lines.

FIG. 2 illustrates a word line driver circuit 22a, a word line driver circuit 22b, a bit line driver circuit 22c, a bit line driver circuit 22d, and a switch driver circuit 22e as the driver circuit 22.

The word line driver circuit 22a has a function of selecting, row by row, the memory cells 42 to which data is to be written. The word line driver circuit 22a generates a signal and supplies the signal to the memory cell 42 through the wiring 62 and the wiring 61, whereby the memory cell 42 to which data is to be written can be selected. Here, the wiring 61 and the wiring 62 are also referred to as write word lines, and the word line driver circuit 22a is also referred to as a write word line driver circuit. The signal is also referred to as a write signal.

The word line driver circuit 22b has a function of selecting, row by row, the memory cells 42 from which data is to be read. The word line driver circuit 22b generates a signal and supplies the signal to the memory cell 42 through the wiring 64 and the wiring 63, whereby the memory cell 42 from which data is to be read can be selected. Here, the wiring 63 and the wiring 64 are also referred to as read word lines, and the word line driver circuit 22b is also referred to as a read word line driver circuit. The signal is also referred to as a read signal.

The bit line driver circuit 22c has a function of writing data to the memory cell 42 selected by the word line driver circuit 22a. Specifically, the bit line driver circuit 22c has a function of writing data through the wiring 66 and the wiring 65 to the memory cell 42 selected with a write signal by the word line driver circuit 22a. Here, the wiring 65 and the wiring 66 are also referred to as write bit lines, and the bit line driver circuit 22c is also referred to as a write bit line driver circuit. Data written to the memory cell 42 by the bit line driver circuit 22c is also referred to as write data.

The bit line driver circuit 22d has a function of amplifying data that is output from the memory cell 42 to the wiring 67 and supplied to the bit line driver circuit 22d through the wiring 68. The bit line driver circuit 22d has a function of reading data retained in the memory cell 42 by outputting the amplified data to, for example, the outside of the semiconductor device 10. Moreover, the bit line driver circuit 22d has a function of precharging the wiring 68 and the wiring 67 by supplying a precharge signal before data reading from the memory cell 42. Here, the wiring 67 and the wiring 68 are also referred to as read bit lines, and the bit line driver circuit 22d is also referred to as a read bit line driver circuit. Data read from the memory cell 42 by the bit line driver circuit 22d is also referred to as read data.

The switch circuit 52a has a function of supplying, to one of the memory cell 42_1 and the memory cell 42_2, a write signal supplied from the wiring 62. The switch circuit 52b has a function of supplying, to one of the memory cell 42_1 and the memory cell 42_2, a read signal supplied from the wiring 64. The switch circuit 52c has a function of supplying, to one of the memory cell 42_1 and the memory cell 42_2, write data supplied from the wiring 66. The switch circuit 52d has a function of supplying, to the bit line driver circuit 22d, one of data output from the memory cell 42_1 and data output from the memory cell 42_2.

The switch driver circuit 22e has a function of controlling the driving of the switch circuit 52. Specifically, the switch driver circuit 22e has a function of controlling the driving of the switch circuit 52 by supplying a selection signal SEL to the switch circuit 52. For example, the switch circuit 52a has a function of outputting, to one of the wiring 61_1 and the wiring 61_2, a write signal supplied from the wiring 62 on the basis of the selection signal SEL. The switch circuit 52b has a function of outputting, to one of the wiring 63_1 and the wiring 63_2, a read signal supplied from the wiring 64 on the basis of the selection signal SEL. The switch circuit 52c has a function of outputting, to one of the wiring 65_1 and the wiring 65_2, write data supplied from the wiring 66 on the basis of the selection signal SEL. The switch circuit 52d has a function of outputting, to the wiring 68, one of read data supplied from the wiring 67_1 and read data supplied from the wiring 67_2 on the basis of the selection signal SEL.

In the drawings attached to this specification, signals are indicated by arrows.

Providing the switch circuits 52 in the semiconductor device 10 as described above enables the memory cell array 41 to be split into a plurality of memory cell arrays. The semiconductor device 10 is provided with the switch circuits 52 and the memory cell array 41 is split into a plurality of memory cell arrays, whereby the area occupied by the word line driver circuit 22a, the word line driver circuit 22b, the bit line driver circuit 22c, the bit line driver circuit 22d, and the like can be inhibited from increasing and additionally, the load on these driver circuits can be reduced. Thus, the semiconductor device 10 can be small in size and driven at high speed.

### [Switch Circuit]

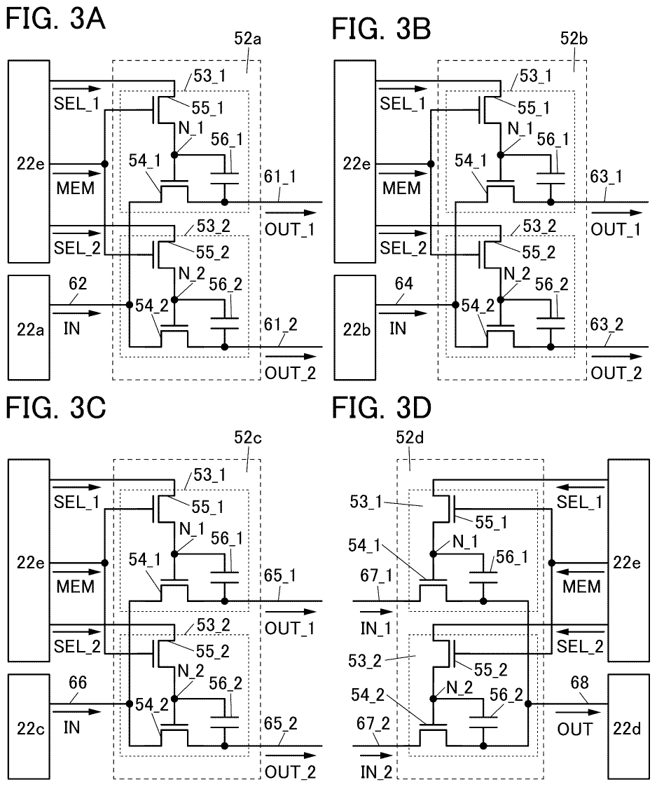

FIG. 3A, FIG. 3B, FIG. 3C, and FIG. 3D are circuit diagrams illustrating structure examples of the switch circuit 52a, the switch circuit 52b, the switch circuit 52c, and the switch circuit 52d, respectively. The switch circuit 52a, the switch circuit 52b, the switch circuit 52c, and the switch circuit 52d each include a circuit 53. FIG. 3A, FIG. 3B, FIG. 3C, and FIG. 3D illustrate examples in which the switch circuit 52 includes a circuit 53_1 and a circuit 53_2 as the circuit 53.

The circuit 53_1 includes a transistor 54_1, a transistor 55_1, and a capacitor 56_1. The circuit 53_2 includes a transistor 54_2, a transistor 55_2, and a capacitor 56_2. Note that the circuit 53 may omit the capacitor 56.

One of a source and a drain of the transistor 54_1 and one of a source and a drain of the transistor 54_2 in the switch circuit 52a are electrically connected to the word line driver circuit 22a through the wiring 62. One of the source and the drain of the transistor 54_1 and one of the source and the drain of the transistor 54_2 in the switch circuit 52b are electrically connected to the word line driver circuit 22b through the wiring 64. One of the source and the drain of the transistor 54_1 and one of the source and the drain of the transistor 54_2 in the switch circuit 52c are electrically connected to the bit line driver circuit 22c through the wiring 66. One of the source and the drain of the transistor 54_1 in the switch circuit 52d is electrically connected to the wiring 67_1, and one of the source and the drain of the transistor 54_2 in the switch circuit 52d is electrically connected to the wiring 67_2.

In the switch circuit 52a, the switch circuit 52b, and the switch circuit 52c, a signal supplied to the one of the source and the drain of the transistor 54_1 and the one of the source and the drain of the transistor 54_2 is referred to as a signal IN. The signal IN can be a write signal in the switch circuit 52a, a read signal in the switch circuit 52b, and write data in the switch circuit 52c.

In the switch circuit 52d, a signal supplied to the one of the source and the drain of the transistor 54_1 is referred to as a signal IN_1, and a signal supplied to the one of the source and the drain of the transistor 54_2 is referred to as a signal IN_2. The signal IN_1 and the signal IN_2 can be read data.

In the switch circuit 52a, the switch circuit 52b, the switch circuit 52c, and the switch circuit 52d, a gate of the transistor 54_1 is electrically connected to one of a source and a drain of the transistor 55_1 and one electrode of the capacitor 56_1. A gate of the transistor 54_2 is electrically connected to one of a source and a drain of the transistor 55_2 and one electrode of the capacitor 56_2. Here, a node where the gate of the transistor 54_1, the one of the source and the drain of the transistor 55_1, and the one electrode of the capacitor 56_1 are electrically connected to each other is referred to as a node N_1. Moreover, a node where the gate of the transistor 54_2, the one of the source and the drain of the transistor 55_2, and the one electrode of the capacitor 56_2 are electrically connected to each other is referred to as a node N_2.

The other of the source and the drain of the transistor 55_1, the other of the source and the drain of the transistor 55_2, a gate of the transistor 55_1, and a gate of the transistor 55_2 are electrically connected to the switch driver circuit 22e. The switch driver circuit 22e supplies a selection signal SEL_1 to the other of the source and the drain of the transistor 55_1 and supplies a selection signal SEL_2 to the other of the source and the drain of the transistor 55_2. The switch driver circuit 22e supplies a selection result write signal MEM to the gate of the transistor 55_1 and the gate of the transistor 55_2.

In the switch circuit 52a, the other of the source and the drain of the transistor 54_1 and the other electrode of the capacitor 56_1 are electrically connected to the wiring 61_1, and the other of the source and the drain of the transistor 54_2 and the other electrode of the capacitor 56_2 are electrically connected to the wiring 61_2. In the switch circuit 52b, the other of the source and the drain of the transistor 54_1 and the other electrode of the capacitor 56_1 are electrically connected to the wiring 63_1, and the other of the source and the drain of the transistor 54_2 and the other electrode of the capacitor 56_2 are electrically connected to the wiring 63_2. In the switch circuit 52c, the other of the source and the drain of the transistor 54_1 and the other electrode of the capacitor 56_1 are electrically connected to the wiring 65_1, and the other of the source and the drain of the transistor 54_2 and the other electrode of the capacitor 56_2 are electrically connected to the wiring 65_2. In the switch circuit 52d, the other of the source and the drain of the transistor 54_1, the other electrode of the capacitor 56_1, the other of the source and the drain of the transistor 54_2, and the other electrode of the capacitor 56_2 are electrically connected to the bit line driver circuit 22d through the wiring 68.

In the switch circuit 52a, the switch circuit 52b, and the switch circuit 52c, a signal output from the other of the source and the drain of the transistor 54_1 is referred to as a signal OUT_1, and a signal output from the other of the source and the drain of the transistor 54_2 is referred to as a signal OUT_2. The signal OUT_1 and the signal OUT_2 can be write signals in the switch circuit 52a, read signals in the switch circuit 52b, and write data in the switch circuit 52c.

In the switch circuit 52d, a signal output from the other of the source and the drain of the transistor 54_1 and the other of the source and the drain of the transistor 54_2 is referred to as a signal OUT. The signal OUT can be read data.

In the case where the transistor 55_1 and the transistor 55_2 are n-channel transistors, the potential of the selection signal SEL_1 can be supplied to the node N_1 and the potential of the selection signal SEL_2 can be supplied to the node N_2 by setting the selection result write signal MEM to a high potential. Thus, the selection result represented by the selection signal SEL can be written to the switch circuit 52. By setting the selection result write signal MEM to a low potential, the selection result can be retained in the switch circuit 52.

In this specification and the like, the description is made on the assumption that the transistors are n-channel transistors unless otherwise specified. Note that the description in this specification and the like can be referred to for the case where the transistors are p-channel transistors by appropriately inverting the potential levels, for example.

The switch circuit 52a, the switch circuit 52b, and the switch circuit 52c output the signal OUT_1 when the potential of the node N_1 is a high potential and the potential of the node N_2 is a low potential, for example. The switch circuit 52a, the switch circuit 52b, and the switch circuit 52c output the signal OUT_2 when the potential of the node N_1 is a low potential and the potential of the node N_2 is a high potential, for example. Accordingly, the signal IN is output as the signal OUT_1 or the signal OUT_2 on the basis of the selection signal SEL_1 and the selection signal SEL_2, for example. The signal OUT_1 is supplied to the memory cell 42_1 illustrated in FIG. 1 and FIG. 2. The signal OUT_2 is supplied to the memory cell 42_2 illustrated in FIG. 1 and FIG. 2.

The switch circuit 52d outputs the signal IN_1 as the signal OUT when the potential of the node N_1 is a high potential and the potential of the node N_2 is a low potential, for example. The switch circuit 52d outputs the signal IN_2 as the signal OUT when the potential of the node N_1 is a low potential and the potential of the node N_2 is a high potential, for example. Accordingly, one of the signal IN_1 and the signal IN_2 is output as the signal OUT on the basis of the selection signal SEL_1 and the selection signal SEL_2, for example. The signal IN_1 is supplied from the memory cell 42_1 illustrated in FIG. 1 and FIG. 2 to the switch circuit 52d. The signal IN_2 is supplied from the memory cell 42_2 illustrated in FIG. 1 and FIG. 2 to the switch circuit 52d.

The off-state current of an OS transistor is extremely low. Hence, the use of an OS transistor as the transistor 55 enables the potential of the node N to be retained for a long time. Consequently, the selection result written to the switch circuit 52 can be retained for a long time. For example, the selection result of the memory cell array 41 to which data is written or the memory cell array 41 from which data is read can be retained in the switch circuit 52 for a long time, as described above. Thus, the frequency of supplying the selection signal SEL to the switch circuit 52 can be decreased while data is written to the memory cells 42 provided in one memory cell array 41 or data is read from the memory cells 42 provided in one memory cell array 41. Therefore, the semiconductor device 10 can be a semiconductor device with low power consumption.

As described above, power consumption of the semiconductor device 10 can be reduced more favorably as a period during which data is written to the memory cells 42 provided in one memory cell array 41 or a period during which data is read from the memory cells 42 provided in one memory cell array 41 is longer. Thus, for example, the memory cells 42 provided in one memory cell array 41 preferably retain data of the same type.

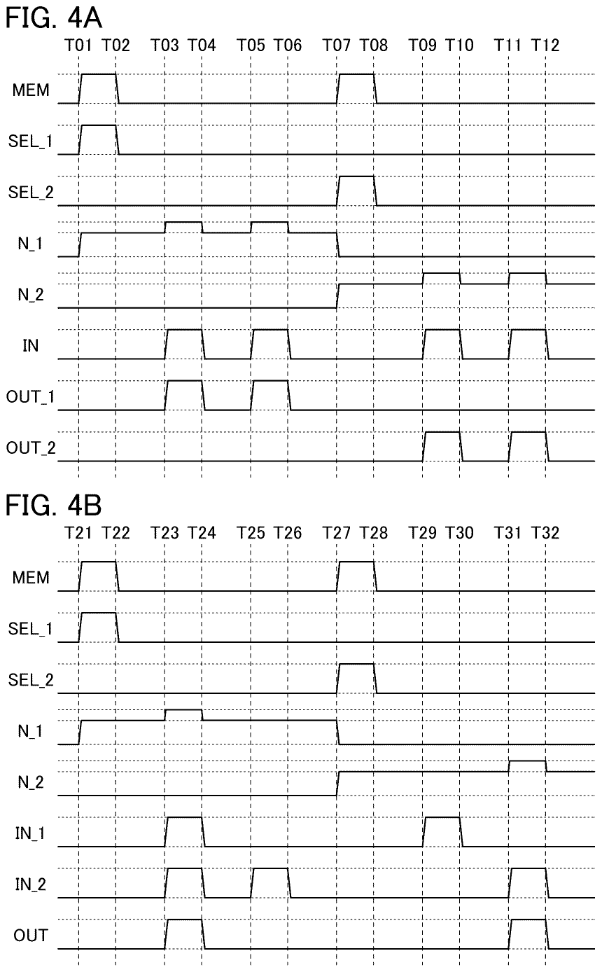

FIG. 4A is a timing chart showing an example of a method for driving the switch circuit 52a, the switch circuit 52b, and the switch circuit 52c. FIG. 4A shows an example of changes over time in the potentials of the selection result write signal MEM, the selection signal SEL_1, the selection signal SEL_2, the node N_1, the node N_2, the signal IN, the signal OUT_1, and the signal OUT_2 from Time T01 to Time T12. Note that before Time T01, the potentials of the selection result write signal MEM, the selection signal SEL_1, the selection signal SEL_2, the node N_1, the node N_2, the signal IN, the signal OUT_1, and the signal OUT_2 are each set to a low potential.

At Time T01, the potentials of the selection result write signal MEM and the selection signal SEL_1 are set to a high potential. By setting the potential of the selection result write signal MEM to a high potential, the transistor 55_1 and the transistor 55_2 are turned on. Thus, the node N_1 has a potential corresponding to the potential of the selection signal SEL_1, and the node N_2 has a potential corresponding to the potential of the selection signal SEL_2. Consequently, a selection result is written to the switch circuit 52. Specifically, a selection result that the circuit 53_1 has been selected is written to the switch circuit 52. Here, the potential of the node N_1 may become a value obtained by subtracting the threshold voltage of the transistor 55_1 from the potential of the selection signal SEL_1, for example.

At Time T02, the potentials of the selection result write signal MEM and the selection signal SEL_1 are set to a low potential. By setting the potential of the selection result write signal MEM to a low potential, the transistor 55_1 and the transistor 55_2 are turned off. Thus, the selection result is retained in the switch circuit 52.

At Time T03, the potential of the signal IN becomes a high potential. Thus, the potential of the signal OUT_1 becomes a high potential. Meanwhile, the potential of the signal OUT_2 remains a low potential. Accordingly, the signal IN is output as the signal OUT_1 on the basis of the selection result retained in the switch circuit 52.

Here, the potential of the one of the source and the drain of the transistor 54_1 increases, and accordingly, the potential of the other electrode of the capacitor 56_1 also increases. Since the transistor 55_1 is in an off state and the node N_1 is in a floating state, the potential of the node N_1 also increases owing to capacitive coupling of the capacitor 56_1. This can inhibit the potential of the gate of the transistor 55_1 from increasing and the potential of the signal OUT_1 from becoming lower than the potential of the signal IN, for example.

In this specification and the like, increasing the potential of a gate of a transistor along with an increase in the potential of a source or a drain thereof by utilizing capacitive coupling is referred to as bootstrapping. At Time T03, the potential of the node N_1 increases owing to bootstrapping. Note that even in the case where the capacitor 56_1 is not provided in the circuit 53_1, the potential of the node N_1 may increase owing to the gate capacitance of the transistor 54_1, for example.

At Time T04, the potential of the signal IN becomes a low potential. Thus, the potential of the signal OUT_1 becomes a low potential. Moreover, the potential of the node N_1 that has been increased by bootstrapping also decreases.

At Time T05, the potential of the signal IN becomes a high potential again, and at Time T06, the potential of the signal IN becomes a low potential. In synchronization with this, the potentials of the node N_1 and the signal OUT_1 change in the same manner as those from Time T03 to Time T04.

From Time T05 to Time T06, the selection result is retained in the switch circuit 52. Thus, the signal IN is output as the signal OUT_1 from the switch circuit 52 although the potential of the selection signal SEL_1 is a low potential.

At Time T07, the potentials of the selection result write signal MEM and the selection signal SEL_2 are set to a high potential. Thus, a selection result is written to the switch circuit 52, which is similar at Time T01. Specifically, a selection result that the circuit 53_2 has been selected is written to the switch circuit 52. Here, the potential of the node N_2 may become a value obtained by subtracting the threshold voltage of the transistor 55_2 from the potential of the selection signal SEL_2, for example.

At Time T08, the potentials of the selection result write signal MEM and the selection signal SEL_2 are set to a low potential. Thus, the selection result is retained in the switch circuit 52, which is similar at Time T02.

At Time T09, the potential of the signal IN becomes a high potential. Thus, the potential of the signal OUT_2 becomes a high potential. Meanwhile, the potential of the signal OUT_1 remains a low potential. Accordingly, the signal IN is output as the signal OUT_2 on the basis of the selection result retained in the switch circuit 52. Here, the potential of the node N_2 increases owing to bootstrapping utilizing capacitive coupling of the capacitor 56_2. Note that even in the case where the capacitor 56_2 is not provided in the circuit 53_2, the potential of the node N_2 may increase owing to the gate capacitance of the transistor 54_2, for example.

At Time T10, the potential of the signal IN becomes a low potential. Thus, the potential of the signal OUT_2 becomes a low potential. Moreover, the potential of the node N_2 that has been increased by bootstrapping also decreases.

At Time T11, the potential of the signal IN becomes a high potential again, and at Time T12, the potential of the signal IN becomes a low potential. In synchronization with this, the potentials of the node N_2 and the signal OUT_2 change in the same manner as those from Time T09 to Time T10.

At Time T11 and Time T12, the selection result is retained in the switch circuit 52. Thus, the signal IN is output as the signal OUT_2 from the switch circuit 52 although the potential of the selection signal SEL_2 is a low potential.

The above is one example of the method for driving the switch circuit 52a, the switch circuit 52b, and the switch circuit 52c.

FIG. 4B is a timing chart showing an example of a method for driving the switch circuit 52d. FIG. 4B shows an example of changes over time in the potentials of the selection result write signal MEM, the selection signal SEL_1, the selection signal SEL_2, the node N_1, the node N_2, the signal IN_1, the signal IN_2, and the signal OUT from Time T21 to Time T32. Note that before Time T21, the potentials of the selection result write signal MEM, the selection signal SEL_1, the selection signal SEL_2, the node N_1, the node N_2, the signal IN_1, the signal IN_2, and the signal OUT are each set to a low potential.

The potentials of the selection result write signal MEM, the selection signal SEL, the node N, and the like at Time T21 and Time T22 can be the same as the potentials at Time T01 and Time T02. From Time T21 to Time T22, a selection result that the circuit 53_1 has been selected is written to the switch circuit 52d.

At Time T23, the potentials of the signal IN_1 and the signal IN_2 become a high potential. On the basis of the selection result retained in the switch circuit 52d, the potential of the signal OUT becomes a high potential corresponding to the potential of the signal IN_1. Thus, the signal IN_1 is output as the signal OUT. Here, the potential of the node N_1 increases owing to bootstrapping utilizing capacitive coupling of the capacitor 56_1. As described above, even in the case where the capacitor 56_1 is not provided in the circuit 53_1, the potential of the node N_1 may increase owing to the gate capacitance of the transistor 54_1, for example.

At Time T24, the potentials of the signal IN_1 and the signal IN_2 become a low potential. When the potential of the signal IN_1 becomes a low potential, the potential of the signal OUT becomes a low potential. Moreover, the potential of the node N_1 that has been increased by bootstrapping also decreases.

At Time T25, the potential of the signal IN_2 becomes a high potential. Meanwhile, the potential of the signal IN_1 remains a low potential. The potential of the signal OUT remains a low potential, which corresponds to the potential of the signal IN_1, on the basis of the selection result retained in the switch circuit 52d.

At Time T26, the potential of the signal IN_2 becomes a low potential.

The potentials of the selection result write signal MEM, the selection signal SEL, the node N, and the like at Time T27 and Time T28 can be the same as the potentials at Time T07 and Time T08. From Time T27 to Time T28, a selection result that the circuit 53_2 has been selected is written to the switch circuit 52d.

At Time T29, the potential of the signal IN_1 becomes a high potential. Meanwhile, the potential of the signal IN_2 remains a low potential. The potential of the signal OUT remains a low potential, which corresponds to the potential of the signal IN_2, on the basis of the selection result retained in the switch circuit 52d.

At Time T30, the potential of the signal IN_1 becomes a low potential.

At Time T31, the potential of the signal IN_2 becomes a high potential. Meanwhile, the potential of the signal IN_1 remains a low potential. On the basis of the selection result retained in the switch circuit 52d, the potential of the signal OUT becomes a high potential corresponding to the potential of the signal IN_2. Thus, the signal IN_2 is output as the signal OUT. Here, the potential of the node N_2 increases owing to bootstrapping utilizing capacitive coupling of the capacitor 56_2. As described above, even in the case where the capacitor 56_2 is not provided in the circuit 53_2, the potential of the node N_2 may increase owing to the gate capacitance of the transistor 54_2, for example.

At Time T32, the potential of the signal IN_2 becomes a low potential. When the potential of the signal IN_2 becomes a low potential, the potential of the signal OUT becomes a low potential. Moreover, the potential of the node N_2 that has been increased by bootstrapping also decreases.

The above is one example of the method for driving the switch circuit 52d.

As described above, the switch circuit 52 provided between the memory cell 42 and the driver circuit 22 has a function of retaining the selection result. In a period during which the selection result is retained in the switch circuit 52, the potentials of both the selection signal SEL_1 and the selection signal SEL_2, for example, can be a low potential, i.e., it is not necessary to supply either the selection signal SEL_1 or the selection signal SEL_2 to the switch circuit 52. Thus, the semiconductor device 10 can be a semiconductor device with low power consumption.

In particular, the use of an OS transistor as the transistor 55 enables the off-state current of the transistor 55 to be extremely low. Hence, the potential of the node N can be retained for a long time, as described above. Consequently, the selection result written to the switch circuit 52 can be retained for a long time. For example, the selection result of the memory cell array 41 to which data is written or the memory cell array 41 from which data is read can be retained in the switch circuit 52 for a long time. Thus, the frequency of supplying the selection signal SEL to the switch circuit 52 can be decreased while data is written to the memory cells 42 provided in one memory cell array 41 or data is read from the memory cells 42 provided in one memory cell array 41. Therefore, the semiconductor device 10 can be a semiconductor device with low power consumption.

As described above, power consumption of the semiconductor device 10 can be reduced more favorably as a period during which data is written to the memory cells 42 provided in one memory cell array 41 or a period during which data is read from the memory cells 42 provided in one memory cell array 41 is longer. Specifically, power consumption of the semiconductor device 10 can be reduced more favorably as the period after the selection result write signal MEM is set to a high potential until the selection result write signal MEM is again set to a high potential is longer. Thus, for example, the memory cells 42 provided in one memory cell array 41 preferably retain data of the same type.

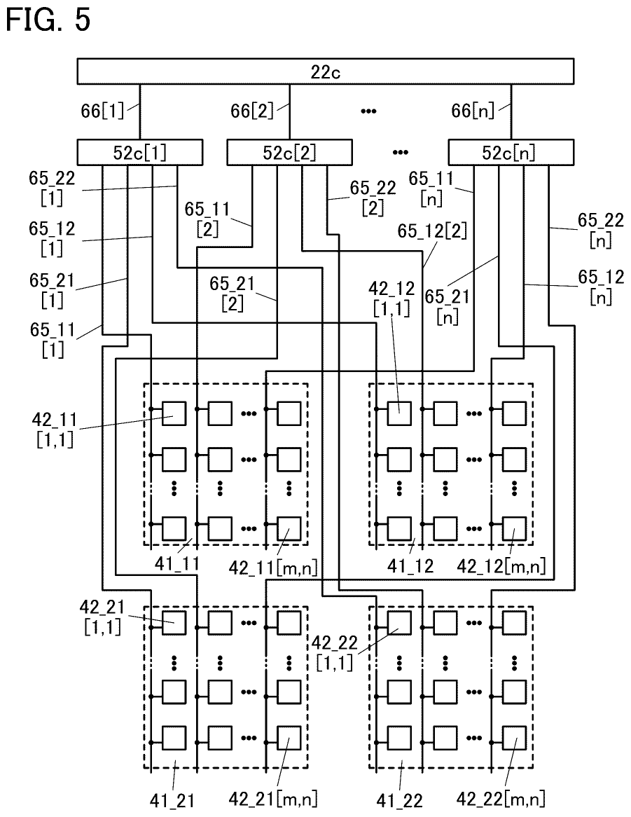

Although FIG. 1 and FIG. 2 illustrate an example in which the semiconductor device 10 includes two memory cell arrays 41, the semiconductor device 10 may include three or more memory cell arrays 41. FIG. 5 illustrates a variation example of the structure illustrated in FIG. 2, in which memory cell arrays 41 of two rows and two columns are provided in the semiconductor device 10. FIG. 5 illustrates only the bit line driver circuit 22c as the driver circuit 22. FIG. 5 illustrates only the switch circuit 52c as the switch circuit 52.

In FIG. 5, the memory cell arrays 41 in the first row and the first column, the second row and the first column, the second row and the first column, and the second row and the second column are respectively referred to as a memory cell array 41_11, a memory cell array 41_21, a memory cell array 41_12, and a memory cell array 41_22. The memory cells 42 provided in the memory cell array 41_11, the memory cell array 41_21, the memory cell array 41_12, and the memory cell array 41_22 are respectively referred to as a memory cell 42_11, a memory cell 42_21, a memory cell 42_12, and a memory cell 42_22. The wirings 65 electrically connected to the memory cell 42_11, the memory cell 42_21, the memory cell 42_12, and the memory cell 42_22 are respectively referred to as a wiring 65_11, a wiring 65_21, a wiring 65_12, and a wiring 65_22.

As illustrated in FIG. 5, the wiring 65_11, the wiring 65_21, the wiring 65_12, and the wiring 65_22 are electrically connected as the wirings 65 to the switch circuit 52c. That is, four wirings 65 can be electrically connected to the switch circuit 52c. Although not illustrated in FIG. 5, four wirings 62 can be electrically connected to the switch circuit 52a, four wirings 64 can be electrically connected to the switch circuit 52b, and four wirings 67 can be electrically connected to the witch circuit 52d.

Accordingly, the wirings 61, the wirings 63, the wirings 65, and the wirings 67, which are the same in number as the memory cell arrays 41, can be electrically connected to the switch circuit 52a, the switch circuit 52b, the switch circuit 52c, and the switch circuit 52d, respectively. Note that the semiconductor device 10 may include three or more rows of memory cell arrays 41 and three or more columns of memory cell arrays 41. Even in such a case, the wirings 61, the wirings 63, the wirings 65, and the wirings 67, which are the same in number as the memory cell arrays 41, can be electrically connected to the switch circuit 52a, the switch circuit 52b, the switch circuit 52c, and the switch circuit 52d, respectively.

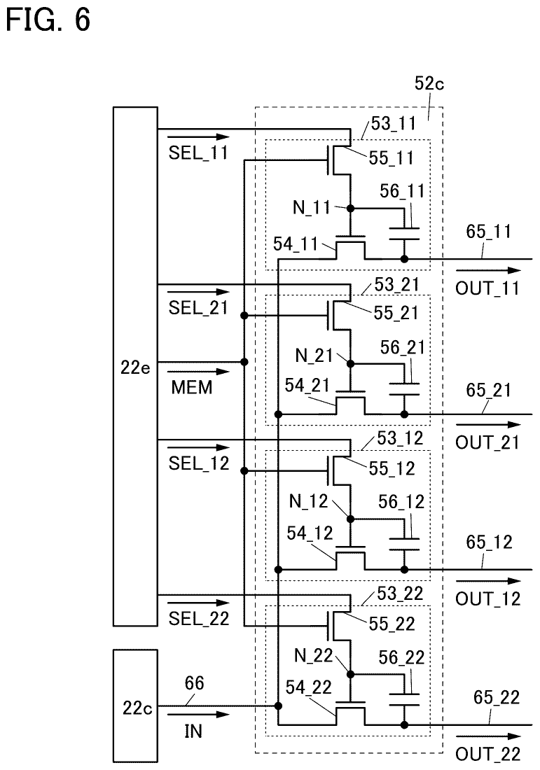

FIG. 6 is a circuit diagram illustrating a structure example of the switch circuit 52c illustrated in FIG. 5. The switch circuit 52c illustrated in FIG. 6 includes a circuit 53_11, a circuit 53_21, a circuit 53_12, and a circuit 53_22 as the circuits 53. Note that the switch circuit 52a and the switch circuit 52b can have a similar structure on the basis of FIG. 3A and FIG. 3B.

The circuit 53_11 includes a transistor 54_11, a transistor 55_11, and a capacitor 56_11. The circuit 53_21 includes a transistor 54_21, a transistor 55_21, and a capacitor 56_21. The circuit 53_12 includes a transistor 54_12, a transistor 55_12, and a capacitor 56_12. The circuit 53_22 includes a transistor 54_22, a transistor 55_22, and a capacitor 56_22.

One of a source and a drain of the transistor 54_11, one of a source and a drain of the transistor 54_21, one of a source and a drain of the transistor 54_12, and one of a source and a drain of the transistor 54_22 are electrically connected to the bit line driver circuit 22c through the wiring 66. Thus, either the sources or the drains of all the transistors 54 can be electrically connected to one wiring 66, for example.

A gate of the transistor 54_11 is electrically connected to one of a source and a drain of the transistor 55_11 and one electrode of the capacitor 56_11. A gate of the transistor 54_21 is electrically connected to one of a source and a drain of the transistor 55_21 and one electrode of the capacitor 56_21. A gate of the transistor 54_12 is electrically connected to one of a source and a drain of the transistor 55_12 and one electrode of the capacitor 56_12. A gate of the transistor 54_22 is electrically connected to one of a source and a drain of the transistor 55_22 and one electrode of the capacitor 56_22.

Here, a node where the gate of the transistor 54_11, the one of the source and the drain of the transistor 55_11, and the one electrode of the capacitor 56_11 are electrically connected to each other is referred to as a node N_11. A node where the gate of the transistor 54_21, the one of the source and the drain of the transistor 55_21, and the one electrode of the capacitor 56_21 are electrically connected to each other is referred to as a node N_21. A node where the gate of the transistor 54_12, the one of the source and the drain of the transistor 55_12, and the one electrode of the capacitor 56_12 are electrically connected to each other is referred to as a node N_12. A node where the gate of the transistor 54_22, the one of the source and the drain of the transistor 55_22, and the one electrode of the capacitor 56_22 are electrically connected to each other is referred to as a node N_22.

The other of the source and the drain of the transistor 55_11, the other of the source and the drain of the transistor 55_21, the other of the source and the drain of the transistor 55_12, and the other of the source and the drain of the transistor 55_22 are electrically connected to the switch driver circuit 22e. A gate of the transistor 55_11, a gate of the transistor 55_21, a gate of the transistor 55_12, and a gate of the transistor 55_22 are electrically connected to the switch driver circuit 22e.

The switch driver circuit 22e supplies a selection signal SEL_11 to the other of the source and the drain of the transistor 55_11. The switch driver circuit 22e supplies a selection signal SEL_21 to the other of the source and the drain of the transistor 55_21. The switch driver circuit 22e supplies a selection signal SEL_12 to the other of the source and the drain of the transistor 55_12. The switch driver circuit 22e supplies a selection signal SEL_22 to the other of the source and the drain of the transistor 55_22.

The switch driver circuit 22e supplies the selection result write signal MEM to the gate of the transistor 55_11, the gate of the transistor 55_21, the gate of the transistor 55_12, and the gate of the transistor 55_22. Thus, the switch driver circuit 22e can supply the same selection result write signal MEM to the gates of all the transistors 55, for example.

The other of the source and the drain of the transistor 54_11 and the other electrode of the capacitor 56_11 are electrically connected to the wiring 65_11. The other of the source and the drain of the transistor 54_21 and the other electrode of the capacitor 56_21 are electrically connected to the wiring 65_21. The other of the source and the drain of the transistor 54_12 and the other electrode of the capacitor 56_12 are electrically connected to the wiring 65_12. The other of the source and the drain of the transistor 54_22 and the other electrode of the capacitor 56_22 are electrically connected to the wiring 65_22.

A signal output from the other of the source and the drain of the transistor 54_11 is referred to as a signal OUT_11. A signal output from the other of the source and the drain of the transistor 54_21 is referred to as a signal OUT_21. A signal output from the other of the source and the drain of the transistor 54_12 is referred to as a signal OUT_12. A signal output from the other of the source and the drain of the transistor 54_22 is referred to as a signal OUT_22.

The switch circuit 52c illustrated in FIG. 6 outputs the signal OUT_11 when the potential of the node N_11 is a high potential and the potentials of the node N_21, the node N_12, and the node N_22 are each a low potential, for example. The switch circuit 52c illustrated in FIG. 6 outputs the signal OUT_21 when the potential of the node N_21 is a high potential and the potentials of the node N_11, the node N_12, and the node N_22 are each a low potential, for example. The switch circuit 52c illustrated in FIG. 6 outputs the signal OUT_12 when the potential of the node N_12 is a high potential and the potentials of the node N_11, the node N_21, and the node N_22 are each a low potential, for example. The switch circuit 52c illustrated in FIG. 6 outputs the signal OUT_22 when the potential of the node N_22 is a high potential and the potentials of the node N_11, the node N_21, and the node N_12 are each a low potential, for example.

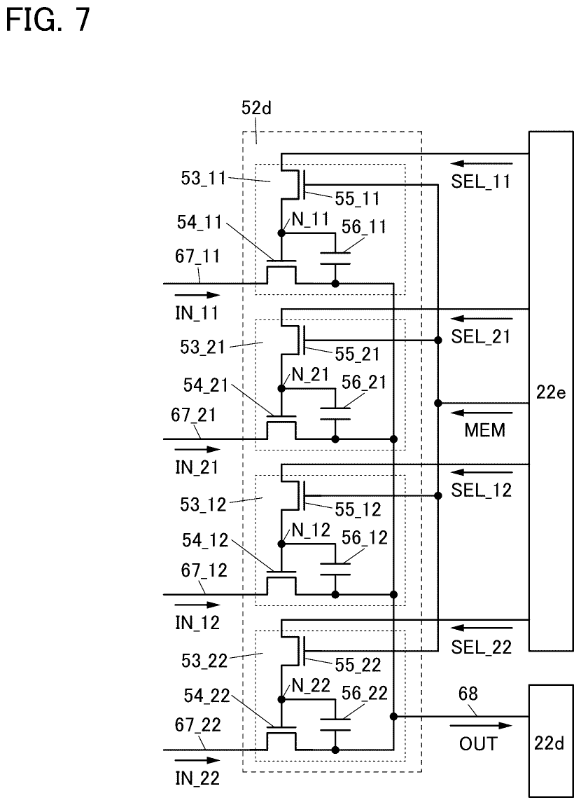

FIG. 7 is a circuit diagram illustrating a structure example of the switch circuit 52d in the case where the memory cell array 41_11, the memory cell array 41_21, the memory cell array 41_12, and the memory cell array 41_22 are provided in the semiconductor device 10. The switch circuit 52d illustrated in FIG. 7 includes the circuit 53_11, the circuit 53_21, the circuit 53_12, and the circuit 53_22 as the circuits 53. A structure different from that of the switch circuit 52c illustrated in FIG. 6 is mainly described below, and the description of a similar structure is omitted as appropriate.

One of the source and the drain of the transistor 54_11 is electrically connected to a wiring 67_11. One of the source and the drain of the transistor 54_21 is electrically connected to a wiring 67_21. One of the source and the drain of the transistor 54_12 is electrically connected to a wiring 67_12. One of the source and the drain of the transistor 54_22 is electrically connected to a wiring 67_22.

The other of the source and the drain of the transistor 54_11, the other of the source and the drain of the transistor 54_21, the other of the source and the drain of the transistor 54_12, and the other of the source and the drain of the transistor 54_22 are electrically connected to the bit line driver circuit 22d through the wiring 68. Thus, the others of the sources and the drains of all the transistors 54 can be electrically connected to one wiring 68, for example.

A signal supplied to the one of the source and the drain of the transistor 54_11 is referred to as a signal IN_11. A signal supplied to the one of the source and the drain the transistor 54_21 is referred to as a signal IN_21. A signal supplied to the one of the source and the drain the transistor 54_12 is referred to as a signal IN_12. A signal supplied to the one of the source and the drain the transistor 54_22 is referred to as a signal IN_22.

The switch circuit 52d illustrated in FIG. 7 outputs the signal IN_11 as the signal OUT when the potential of the node N_11 is a high potential and the potentials of the node N_21, the node N_12, and the node N_22 are each a low potential, for example. The switch circuit 52d illustrated in FIG. 7 outputs the signal IN_21 as the signal OUT when the potential of the node N_21 is a high potential and the potentials of the node N_11, the node N_12, and the node N_22 are each a low potential, for example. The switch circuit 52d illustrated in FIG. 7 outputs the signal IN_12 as the signal OUT when the potential of the node N_12 is a high potential and the potentials of the node N_11, the node N_21, and the node N_22 are each a low potential, for example. The switch circuit 52d illustrated in FIG. 7 outputs the signal IN_22 as the signal OUT when the potential of the node N_22 is a high potential and the potentials of the node N_11, the node N_21, and the node N_12 are each a low potential, for example.

As described above, the circuits 53 that are the same in number as the memory cell arrays 41 can be provided in the switch circuit 52c and the switch circuit 52d. The circuits 53 that are the same in number as the memory cell arrays 41 can also be provided in the switch circuit 52a and the switch circuit 52b.

### [Register Circuit]

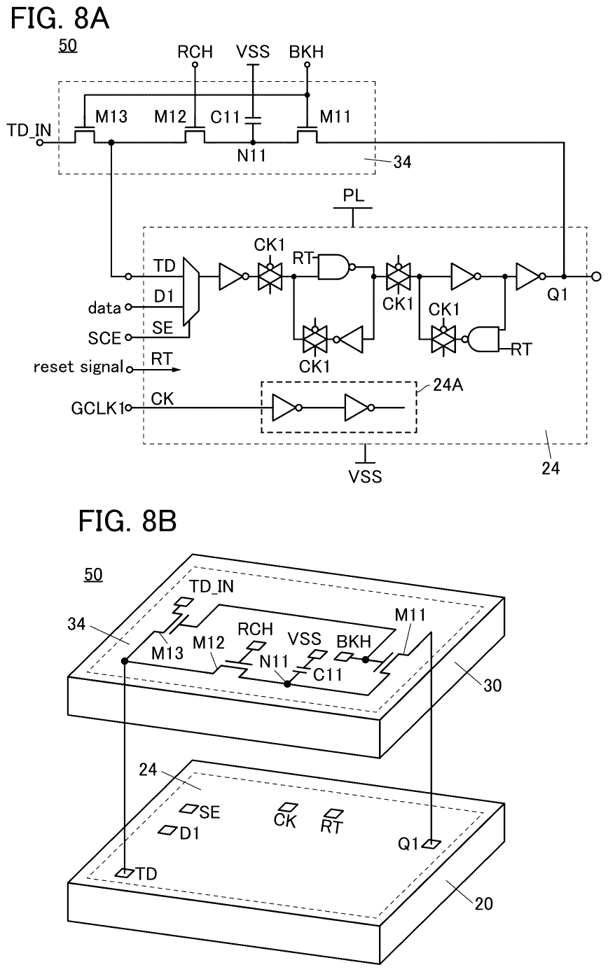

FIG. 8A is a circuit diagram illustrating a structure example of the register circuit 50. As described above, the register circuit 50 includes the flip-flop circuit 24 and the backup circuit 34. The flip-flop circuit 24 includes a node D1, a node Q1, a node TD, a node SE, a node RT, a node CK, and a clock buffer circuit 24A.

The node D1 is a data input node, the node Q1 is a data output node, and the node TD is a test data input node. The node SE is a signal SCE input node. The node CK is a clock signal GCLK1 input node. The clock signal GCLK1 is input to the clock buffer circuit 24A. The node RT is a reset signal input node.

The flip-flop circuit 24 is electrically connected to a power supply line PL. A power supply potential is supplied to the flip-flop circuit 24 through the power supply line PL. A high potential or a low potential, for example, is supplied to the power supply line PL. For example, data is retained at the node Q1 when a high potential is supplied to the power supply line PL, and the data retained at the node Q1 is lost when the potential of the power supply line PL becomes a low potential. Moreover, a potential VSS is supplied to the flip-flop circuit 24. The potential VSS can be a low potential, for example.

The circuit structure of the flip-flop circuit 24 is not limited to that in FIG. 8A. A flip-flop circuit prepared in a standard circuit library can be employed.

The backup circuit 34 includes a node TD_IN, a node N11, a transistor M11, a transistor M12, a transistor M13, and a capacitor C11.

The node TD_IN is a test data input node. The node N11 is a retention node of the backup circuit 34. The capacitor C11 is a storage capacitor for retaining the voltage of the node N11. One electrode of the capacitor C11 is electrically connected to the node N11. The potential VSS can be supplied to the other electrode of the capacitor C11.

The transistor M11 controls continuity between the node Q1 and the node N11. The transistor M12 controls continuity between the node N11 and the node TD. The transistor M13 controls continuity between the node TD_IN and the node TD. The on/off states of the transistor M11 and the transistor M13 are controlled by a signal BKH, and the on/off state of the transistor M12 is controlled by a signal RCH.

As described above, an OS transistor has an extremely low off-state current. Thus, when the transistor M11 and the transistor M12 are OS transistors, the potential of the node N11 can be retained for a long time. Accordingly, the backup circuit 34 can be nonvolatile. FIG. 8B is a circuit diagram illustrating the nodes shown in FIG. 8A and a structure example of the backup circuit 34, and illustrates layers where the nodes and the backup circuit 34 are provided. As illustrated in FIG. 8B, the transistor M11 to the transistor M13 are provided in the layer 30. Thus, in the case where the transistor M11 and the transistor M12 are OS transistors, the transistor M13 can also be an OS transistor.

The number of elements in the backup circuit 34 is much smaller than that in the flip-flop circuit 24. Thus, there is no need to change the circuit structure and layout of the flip-flop circuit 24 in order to stack the backup circuit 34. That is, the backup circuit 34 is highly versatile. The backup circuit 34 can be provided to overlap within the region where the flip-flop circuit 24 is formed; hence, even when the backup circuit 34 is incorporated, the area overhead of the register circuit 50 can be zero. Accordingly, providing the backup circuit 34 in the register circuit 50 enables power-gating of the CPU 21. Since less energy is required for the power-gating, the CPU 21 can be power-gated highly efficiently.

When the backup circuit 34 is provided, parasitic capacitance due to the transistor M11 is added to the node Q1; the parasitic capacitance is lower than parasitic capacitance due to a logic circuit connected to the node Q1, and thus does not adversely affect the operation of the flip-flop circuit 24. That is, providing the backup circuit 34 does not result in an actual decrease in performance of the register circuit 50.

As a low-power-consumption state (non-operating state) of the CPU 21, a clock-gated state, a power-gated state, and a rest state can be set, for example.

When the CPU 21 transitions from a normal operating state to a power-gated state, data in the flip-flop circuit 24 is backed up to the backup circuit 34. When the CPU 21 is returned from the power-gated state to the normal operating state, recovery operation of writing back the data in the backup circuit 34 to the flip-flop circuit 24 is performed.

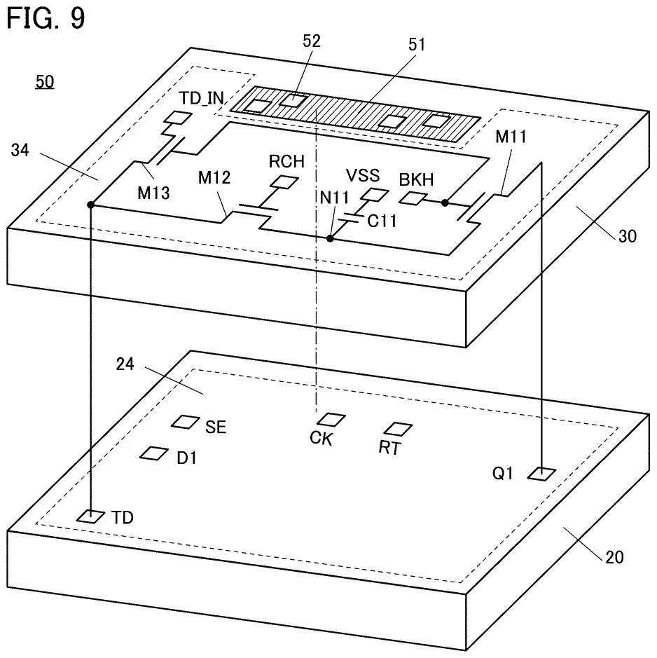

FIG. 9 illustrates a variation example of the structure illustrated in FIG. 8B, in which the switch circuit group 51 is provided to include a region overlapping the flip-flop circuit 24. For example, some of the switch circuits 52 provided in the layer 30 can be provided to overlap the flip-flop circuit 24. Although the switch circuit group 51 is regarded as being excluded from the backup circuit 34 in FIG. 9, the switch circuit group 51 may alternatively be included in the backup circuit 34.

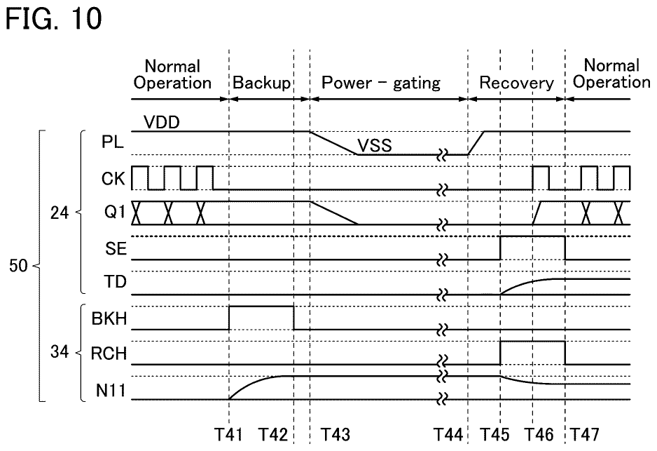

FIG. 10 is a timing chart showing an example of a method for driving the register circuit 50. FIG. 10 shows an example of changes over time in the potentials of the power supply line PL, the node CK, the node Q1, the node SE, the node TD, the signal BKH, the signal RCH, and the node N11 from Time T41 to Time T47. As described above, the power supply line PL is electrically connected to the flip-flop circuit 24. The node CK, the node Q1, the node SE, and the node TD are provided in the flip-flop circuit 24. The signal BKH, the signal RCH, and the node N11 are provided in the backup circuit 34.

Before Time T41, the register circuit 50 is in a normal operating state (Normal Operation). A potential VDD is input to the power supply line PL. The potential VDD can be a high potential. The flip-flop circuit 24 performs normal operation. At this time, the signal SCE, the signal BKH, and the signal RCH each have a low potential. Since the node SE has a low potential, the flip-flop circuit 24 retains data at the node D1. Note that at Time T41, the node N11 of the backup circuit 34 has a low potential.

Backup operation is described. At Time T41, the potential of the signal BKH is set to a high potential. Thus, the transistor M11 in the backup circuit 34 is turned on, and data at the node Q1 of the flip-flop circuit 24 is written to the node N11 of the backup circuit 34. When the node Q1 of the flip-flop circuit 24 has a low potential, the node N11 remains a low potential; when the node Q1 has a high potential, the node N11 becomes a high potential.

At Time T42, the potential of the signal BKH is set to a low potential. Thus, the transistor M11 is turned off, and the potential of the node N11 is retained. Consequently, data at the node Q1 of the flip-flop circuit 24 is retained at the node N11 of the backup circuit 34.

Power-gating operation is described. After Time T43, the potential of the power supply line PL decreases to the potential VSS. Thus, the data at the node Q1 is lost. The node N11 uninterruptedly retains the data that is stored at the node Q1 at Time T43.

Recovery operation is described. After Time T44, the potential of the power supply line PL increases to the potential VDD.

At Time T45, the potential of the signal RCH is set to a high potential. Thus, the transistor M12 is turned on, and electric charge in the capacitor C11 is distributed between the node N11 and the node TD. When the node N11 has a high potential, the voltage of the node TD increases. The node SE has a high potential, and thus, data at the node TD is written to a latch circuit on the input side of the flip-flop circuit 24.

At Time T46, the clock signal GCLK1 is input to the node CK. Thus, the data in the latch circuit on the input side is written to the node Q1. That is, data at the node N11 is written to the node Q1.

At Time T47, the potentials of the node SE and the signal RCH are each set to a low potential. Thus, the recovery operation is completed.

The backup circuit 34 using OS transistors is extremely suitable for normally-off computing because both dynamic power consumption and static power consumption are low. Mounting the register circuit 50 can hardly cause a decrease in performance and an increase in dynamic power of the CPU 21.

As described above, by providing the backup circuit 34 in the register circuit 50, data can be retained even when supply of power supply voltage to the register circuit 50 is stopped. Thus, power-gating of the CPU 21 is possible. Consequently, the semiconductor device 10 can have low power consumption. The backup circuit 34 can be provided to be stacked over a circuit including Si transistors, such as the flip-flop circuit 24. Thus, the backup circuit 34 can be provided without an increase in the circuit area.

### [Memory Cell]

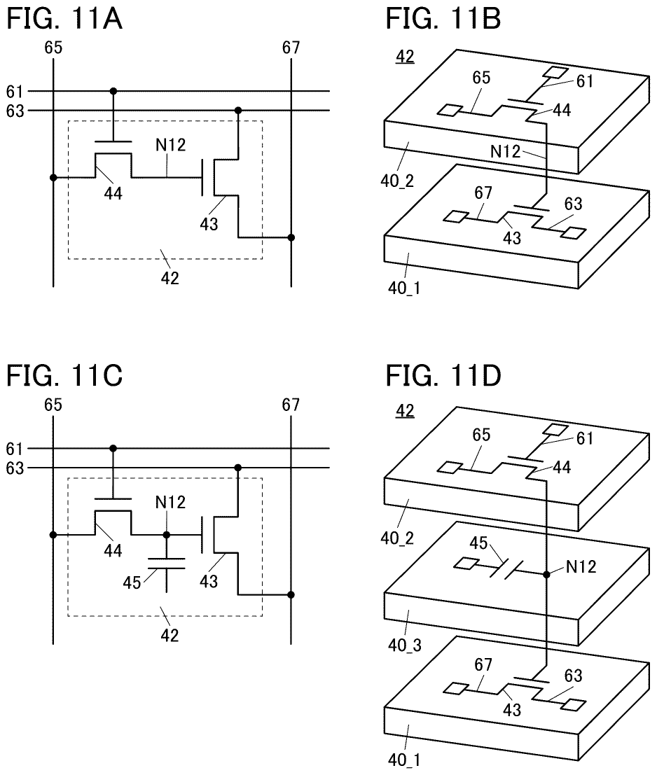

FIG. 11A is a circuit diagram illustrating a structure example of the memory cell 42. The memory cell 42 includes a transistor 43 and a transistor 44.

One of a source and a drain of the transistor 43 is electrically connected to the wiring 63. The other of the source and the drain of the transistor 43 is electrically connected to the wiring 67. A gate of the transistor 43 is electrically connected to one of a source and a drain of the transistor 44. The other of the source and the drain of the transistor 44 is electrically connected to the wiring 65. A gate of the transistor 44 is electrically connected to the wiring 61. Here, a node where the gate of the transistor 43 and the one of the source and the drain of the transistor 44 are electrically connected to each other is referred to as a node N12.

To write data to the memory cell 42, the transistor 44 is turned on and electric charge is supplied from the wiring 65 to the node N12. To retain data in the memory cell 42, the transistor 44 is turned off and the electric charge of the node N12 is retained. Here, when a transistor with a low off-state current is used as the transistor 44, leakage of electric charge of the node N12 can be reduced and the electric charge of the node N12 can be retained for a long time. As described above, an OS transistor can be given as an example of a transistor with a low off-state current.

Accordingly, the use of an OS transistor as the transistor 44 is preferable, in which case data can be retained in the memory cell 42 for a long time. In this case, the transistor 43 can also be an OS transistor.

FIG. 11B is a circuit diagram illustrating a structure example of the memory cell 42, and illustrates a layer where the transistor 43 is provided and a layer where the transistor 44 is provided. The transistor 43 can be provided in a layer 40_1. The transistor 44 can be provided in a layer 40_2 over the layer 40_1. Both the layer 40_1 and the layer 40_2 are included in the layer 40 illustrated in FIG. 1, for example. In other words, in the case where the memory cell 42 has the structure illustrated in FIG. 11B, the layer 40 can have a stacked-layer structure of two layers. Note that the layer 40_2 may be provided below the layer 40_1. In other words, the transistor 44 may be provided below the transistor 43.

Providing the transistor 43 and the transistor 44 in different layers allows the memory cell 42 to be reduced in size or highly integrated as compared with the case where the transistor 43 and the transistor 44 are provided in the same layer. Note that the transistor 43 and the transistor 44 may be provided in the same layer. In this case, the transistor 43 and the transistor 44 can be formed in the same steps, whereby the number of manufacturing steps of the semiconductor device 10 can be reduced.

FIG. 11C is a circuit diagram illustrating a structure example of the memory cell 42, and illustrates an example in which a capacitor 45 is provided in the memory cell 42 illustrated in FIG. 11A. One electrode of the capacitor 45 is electrically connected to the node N12. The other electrode of the capacitor 45 shares a constant potential, for example.

Providing the capacitor 45 in the memory cell 42 can increase the amount of electric charge that can be retained at the node N12. This enables the memory cell 42 to retain data for a long time.

FIG. 11D is a circuit diagram illustrating a structure example of the memory cell 42, and illustrates a layer where the transistor 43 is provided, a layer where the transistor 44 is provided, and a layer where the capacitor 45 is provided. As in the example illustrated in FIG. 11B, the transistor 43 can be provided in the layer 40_1, and the transistor 44 can be provided in the layer 40_2.

The capacitor 45 can be provided in a layer 40_3 positioned between the layer 40_1 and the layer 40_2. The layer 40_1, the layer 40_2, and the layer 40_3 are each included in the layer 40 illustrated in FIG. 1, for example. In other words, in the case where the memory cell 42 has the structure illustrated in FIG. 11D, the layer 40 can have a stacked-layer structure of two layers. Note that the layer 40_3 may be provided below the layer 40_1 or over the layer 40_2. In other words, the capacitor 45 may be provided under the transistor 43 or over the transistor 44.

When the capacitor 45 is provided in a layer different from the layers of the transistor 43 and the transistor 44, the memory cell 42 can be reduced in size or highly integrated as compared with the case where the capacitor 45 is provided in the same layer as the transistor 43 or the transistor 44. Note that the capacitor 45 may be provided in the same layer as the transistor 43 or the transistor 44. Alternatively, all the transistor 43, the transistor 44, and the capacitor 45 may be provided in the same layer. In such cases, the capacitor 45 can be formed in the same steps as one or both of the transistor 43 and the transistor 44; hence, the number of manufacturing steps of the semiconductor device 10 can be reduced.

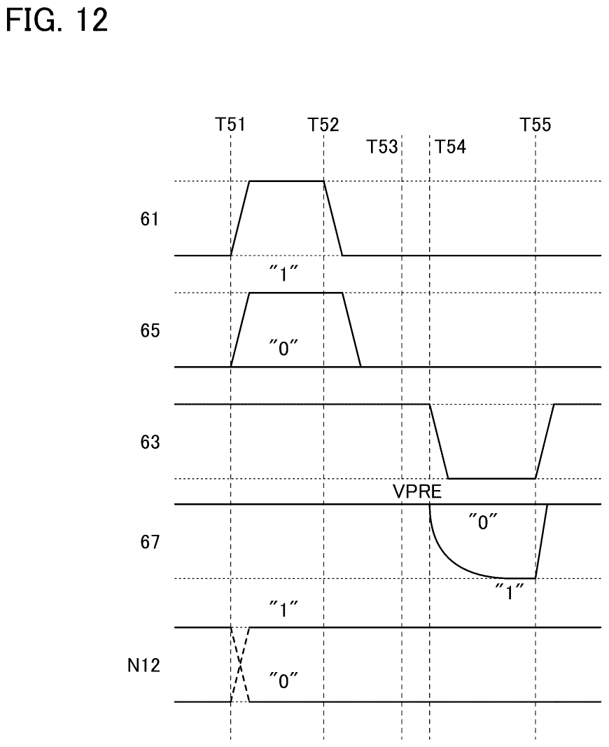

FIG. 12 is a timing chart showing an example of a method for driving the memory cell 42 illustrated in FIG. 11A to FIG. 11D. FIG. 12 shows an example of changes over time in the wiring 61, the wiring 65, the wiring 63, the wiring 67, and the node N12 from Time T51 to Time T55. Note that before Time T51, the potentials of the wiring 61 and the wiring 65 are each a low potential. The potentials of the wiring 63 and the wiring 67 are each a high potential.

At Time T51, the wiring 65 becomes a potential corresponding to data. Here, data written to the memory cell 42 is binary digital data, and the potential of the wiring 65 remains a low potential when data with a value “0” is written to the memory cell 42. The potential of the wiring 65 becomes a high potential when data with a value “1” is written to the memory cell 42.

Moreover, at Time T51, the transistor 44 is turned on by setting the potential of the wiring 61 to a high potential. Thus, the potential of the node N12 becomes a potential corresponding to the data. Consequently, the data is written to the memory cell 42. Since the potential of the wiring 63 and the potential of the wiring 67 are each a high potential, the drain potential and the source potential of the transistor 43 become substantially equal to each other. Thus, current does not flow between the drain and the source of the transistor 43 regardless of the potential of the node N12.

At Time T52, the transistor 44 is turned off by setting the potential of the wiring 61 to a low potential. Thus, the potential of the node N12 is retained, and the data is retained in the memory cell 42. Note that FIG. 12 illustrates an example in which the potential of the wiring 65 becomes a low potential after the potential of the wiring 61 becomes a low potential.

At Time T53, the wiring 67 is precharged to a potential VPRE. The potential VPRE can be a high potential, for example.

At Time T54, the potential of the wiring 63 is set to a low potential. Here, the wiring 67 has been precharged to a high potential, as described above. Thus, a potential difference is generated between the drain and the source of the transistor 43. Consequently, current flows between the drain and the source of the transistor 43 in accordance with the potential of the gate of the transistor 43, that is, the potential of the node N12. In the case where the value of the data retained in the memory cell 42 is “1”, the amount of the current is larger than that in the case where the value is “0”; hence, the potential of the wiring 67 decreases to a low potential, for example. This change in the potential of the wiring 67 is amplified by a sense amplifier electrically connected to the wiring 67, whereby the data retained in the memory cell 42 is read.

In the case where the value of the data retained in the memory cell 42 is “0”, the amount of current flowing between the drain and the source of the transistor 43 is smaller than that in the case where the value is “1”. Thus, the potential of the wiring 67 becomes higher than that in the case where the value of the data retained in the memory cell 42 is “0”. In the case where the value of the data retained in the memory cell 42 is “0”, the potential of the wiring 67 hardly changes from the potential VPRE, for example.

Note that in the memory cell 42 in a non-selected row, the potential of the wiring 63 is kept at a high potential. Thus, in the memory cell 42 in the non-selected row, both the drain potential and the source potential of the transistor 43 become a high potential, so that the drain potential and the source potential of the transistor 43 become substantially equal to each other. Consequently, current does not flow between the drain and the source of the transistor 43 regardless of the potential of the node N12.

At Time T55, the potential of the wiring 63 is set to a high potential. Thus, the potential of the wiring 67 becomes a high potential regardless of the potential of the node N12. In the above manner, data reading from the memory cell 42 is completed.

The above is an example of the method for driving the memory cell 42.

Since an OS transistor has an extremely low off-state current as described above, the use of an OS transistor as the transistor 44 allows the potential of the node N12 to be retained for a long time. Accordingly, operation of rewriting data to the memory cell 42 (refresh operation) is unnecessary. Alternatively, the frequency of refresh operation can be extremely low. Thus, power consumption of the semiconductor device 10 can be reduced.

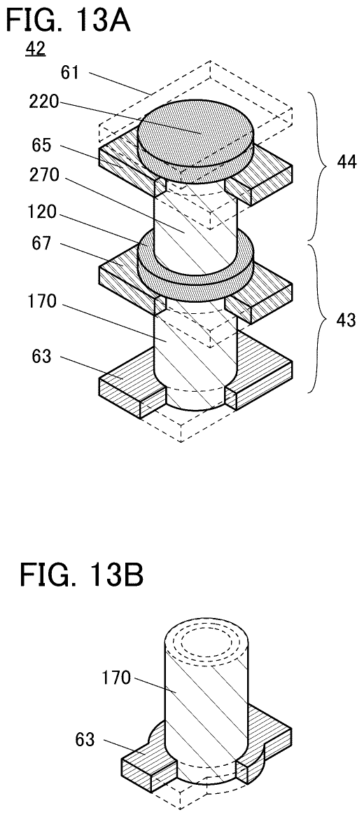

FIG. 13A is a perspective view illustrating a more specific structure example of the memory cell 42 illustrated in FIG. 11B. As described above, the memory cell 42 includes the transistor 43 and the transistor 44 over the transistor 43. FIG. 13A illustrates the wiring 61, the wiring 63, the wiring 65, and the wiring 67. FIG. 13A also illustrates a conductive layer 120, a conductive layer 220, a semiconductor layer 170, and a semiconductor layer 270. The conductive layer 120 and the semiconductor layer 170 are provided in the transistor 43, and the conductive layer 220 and the semiconductor layer 270 are provided in the transistor 44. Note that for clarity, insulating layers such as interlayer films are not illustrated, and the wiring 61 and parts of the wiring 63, the wiring 67, and the wiring 65 are shown by dashed lines.

The conductive layer 120 includes a region functioning as the gate electrode of the transistor 43 and a region functioning as one of the source electrode and the drain electrode of the transistor 44. In other words, the conductive layer 120 includes a region shared by the gate electrode of the transistor 43 and the one of the source electrode and the drain electrode of the transistor 44.

The conductive layer 220 includes a region functioning as the gate electrode of the transistor 44 and is electrically connected to the wiring 61 formed over the conductive layer 220. Note that the conductive layer 220 and the wiring 61 may be formed as one component.

Opening portions are provided in the wiring 63 and the wiring 67, and the semiconductor layer 170 is provided to include regions positioned in the opening portions. In these opening portions, the semiconductor layer 170 includes a region in contact with the wiring 63 and a region in contact with the wiring 67.

The semiconductor layer 270 is provided to include a region in contact with the top surface of the conductive layer 120. An opening portion is provided in the wiring 65, and the semiconductor layer 270 is provided to include a region positioned in the opening portion. In the opening portion, the semiconductor layer 270 includes a region in contact with the wiring 65.

Although FIG. 13A illustrates an example in which the width of the wiring 63 is constant in the longitudinal direction, the width of the wiring 63 in the vicinity of the opening portion may be made larger as illustrated in FIG. 13B. A similar structure can apply also to the wiring 67 and the wiring 65.

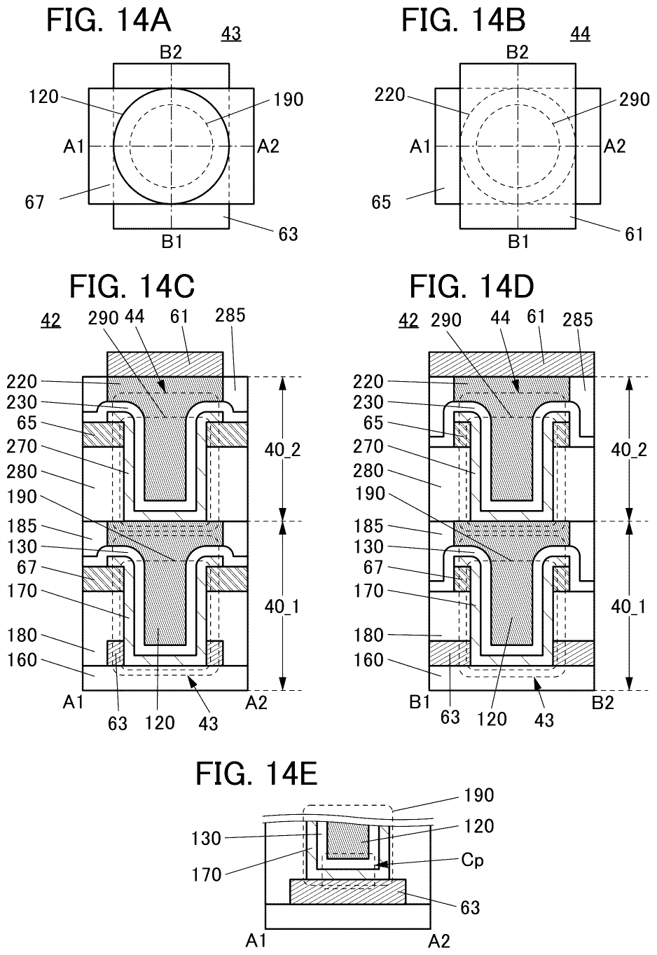

FIG. 14A is a plan view illustrating a structure example of the transistor 43, and FIG. 14B is a plan view illustrating a structure example of the transistor 44. Note that for clarity, some components are not illustrated in the plan views. The plan views illustrated in FIG. 14A and FIG. 14B are common to other structure examples of the memory cell 42 described in this embodiment.

FIG. 14C is a diagram corresponding to the cross section along the line A1-A2 in FIG. 14A and FIG. 14B. FIG. 14D is a diagram corresponding to the cross section along the line B1-B2 in FIG. 14A and FIG. 14B.

The memory cell 42 includes an insulating layer 160, the transistor 43 provided over the insulating layer 160, and the transistor 44 provided over the transistor 43. Between the transistors and wirings, an insulating layer 180, an insulating layer 185, an insulating layer 280, an insulating layer 285, and the like functioning as interlayer films can be provided.

The insulating layer 160, the insulating layer 180, the insulating layer 185, and the transistor 43 are provided in the layer 40_1. The insulating layer 280, the insulating layer 285, and the transistor 44 are provided in the layer 40_2. Note that the insulating layer 160 is not necessarily provided in the layer 40_1. The wiring 61 provided over the transistor 44 may be included in the layer 40_2.

The transistor 43 includes the semiconductor layer 170, an insulating layer 130, and the conductive layer 120. The semiconductor layer 170 functions as a semiconductor layer, the insulating layer 130 functions as a gate insulating layer, and the conductive layer 120 functions as the gate electrode. The wiring 63 includes a region functioning as one of the source electrode and the drain electrode of the transistor 43. The wiring 67 includes a region functioning as the other of the source electrode and the drain electrode of the transistor 43.

An opening portion 190 reaching the insulating layer 160 is provided to penetrate the wiring 67, the insulating layer 180, and the wiring 63. The opening portion 190 has a pillar shape with a substantially circular top-view shape. With such a structure, the memory cell can be reduced in size or highly integrated. Note that the side surface of the opening portion 190 is preferably perpendicular to the top surface of the insulating layer 160.

At least part of the semiconductor layer 170 is provided in the opening portion 190. In the opening portion 190, the semiconductor layer 170 includes a region in contact with the side surface of the wiring 63, a region in contact with the side surface of the wiring 67, a region in contact with the top surface of the insulating layer 160, and a region in contact with the side surface of the insulating layer 180.

The insulating layer 130 is provided to at least partly cover the opening portion 190. The conductive layer 120 is provided to be at least partly positioned in the opening portion 190. The conductive layer 120 is preferably provided to be embedded in the opening portion 190, and preferably has a substantially circular planar shape for a higher degree of integration.

With such a structure, parasitic capacitance between the conductive layer 120 and the wiring 63 can be reduced.

As illustrated in FIG. 14E, if the opening portion 190 is not formed in the wiring 63, the top surface of the wiring 63 is exposed at the bottom portion of the opening portion 190. Accordingly, a parasitic capacitor Cp in which one region of the conductive layer 120 serves as one electrode, one region of the insulating layer 130 serves as a dielectric, and one region of the wiring 63 facing the bottom surface of the conductive layer 120 serves the other electrode is generated in the vicinity of the bottom portion of the opening portion 190. In this case, the semiconductor layer 170 functions as one or both of the dielectric and the other electrode.

The opening portion 190 is provided to cut out the wiring 63 in one embodiment of the present invention; this enables a state without the one region of the wiring 63 facing the bottom surface of the conductive layer 120. This corresponds to a reduction in C by reducing the value of an electrode area S (to 0) in the capacitance C=ϵ×S/d (e: permittivity, S: electrode area, and d: thickness of the dielectric).

The value of the thickness d of the dielectric is small in the region where the parasitic capacitor Cp is formed in FIG. 14E, so that the parasitic capacitor Cp has a relatively high capacitance. The parasitic capacitor Cp is part of the parasitic capacitance between the conductive layer 120 and the wiring 63. Thus, the structure in which the parasitic capacitor Cp is not formed can reduce the parasitic capacitance between the conductive layer 120 and the wiring 63.

Since one region of the semiconductor layer 170 facing the bottom surface of the conductive layer 120 is not in contact with a component that makes the semiconductor layer 170 have n-type conductivity (e.g., the wiring 63), the region is of i-type (intrinsic) and has high resistance. Thus, it can be said that the one region of the semiconductor layer 170 facing the bottom surface of the conductive layer 120 is less likely to be a component (the other electrode) of the parasitic capacitor.

The transistor 44 includes the semiconductor layer 270, an insulating layer 230, and the conductive layer 220. The insulating layer 230 functions as a gate insulating layer, and the conductive layer 220 functions as the gate electrode. The conductive layer 120 includes a region functioning as one of the source electrode and the drain electrode of the transistor 44. The wiring 65 includes a region functioning as the other of the source electrode and the drain electrode of the transistor 44.

An opening portion 290 reaching the conductive layer 120 is provided to penetrate the wiring 65 and the insulating layer 280. The opening portion 290 has a pillar shape with a substantially circular top-view shape. With such a structure, the memory cell can be reduced in size or highly integrated. Note that the side surface of the opening portion 290 is preferably perpendicular to the top surface of the conductive layer 120.

At least part of the semiconductor layer 270 is provided in the opening portion 290. In the opening portion 290, the semiconductor layer 270 includes a region in contact with the top surface of the conductive layer 120, a region in contact with the side surface of the wiring 65, and a region in contact with the side surface of the insulating layer 280.

The insulating layer 230 is provided to at least partly cover the opening portion 290. The conductive layer 220 is provided to be at least partly positioned in the opening portion 290. The conductive layer 220 is preferably provided to be embedded in the opening portion 290, and its planar surface shape is preferably substantially circular for a higher degree of integration. The wiring 61 is provided over the conductive layer 220 and the insulating layer 285. Note that the conductive layer 220 and the wiring 61 may be formed as one component.

It is preferable that the diameter of the opening portion 190 and the diameter of the opening portion 290 be substantially the same and the opening portion 190 and the opening portion 290 be provided to overlap each other. Furthermore, in the memory cell 42, it is preferable that the width of the wiring 63 and the width of the wiring 61 be substantially the same and the wiring 63 and the wiring 61 be provided to overlap each other. In the memory cell 42, it is preferable that the width of the wiring 67 and the width of the wiring 65 be substantially the same and the wiring 67 and the wiring 65 be provided to overlap each other.

With such a structure, two transistors can be provided in the cell without a significant increase in the cell area. Thus, the memory cells 42 can be arranged densely, and the memory capacity of the semiconductor device 10 can be increased. In other words, the memory cells 42 provided in the semiconductor device 10 can be highly integrated.

The one of the source electrode and the drain electrode of the transistor 44 and the gate electrode of the transistor 43 share the same region; in other words, the transistor 44 and the transistor 43 are directly connected without a wiring or the like therebetween. Accordingly, electric resistance between the transistors can be minimum, and data writing, for example, can be performed quickly.

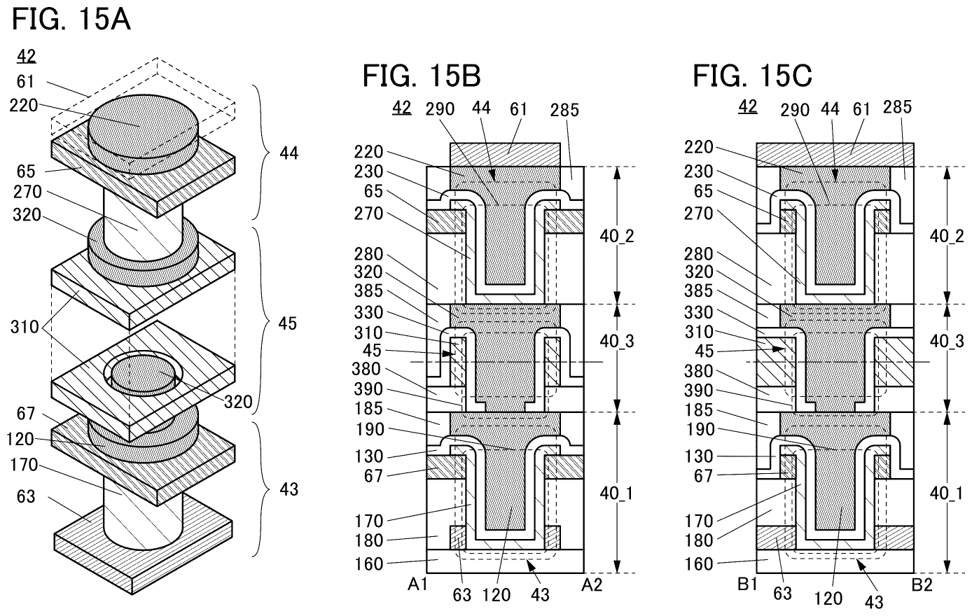

FIG. 15A is a perspective view illustrating a more specific structure example of the memory cell 42 illustrated in FIG. 11D. Note that for clarity, insulating layers such as interlayer films are not illustrated, and the wiring 61 is illustrated by dashed lines. The capacitor 45 is partly illustrated by dashed lines so that its cross section is shown.

FIG. 15B is a diagram corresponding to the cross section along the line A1-A2 in FIG. 14A and FIG. 14B. FIG. 15C is a diagram corresponding to the cross section along the line B1-B2 in FIG. 14A and FIG. 14B. In FIG. 15B and FIG. 15C, the dividing position of the capacitor 45 illustrated in FIG. 15A is indicated by a dashed-dotted line. Note that the description of components common to those in the structures illustrated in FIG. 13A, FIG. 14C, FIG. 14D, and the like is omitted as appropriate.

The memory cell 42 illustrated in FIG. 15A, FIG. 15B, and FIG. 15C includes the capacitor 45 in addition to the transistor 43 and the transistor 44. The capacitor 45 includes a conductive layer 320, an insulating layer 330, and a wiring 310. The conductive layer 320 functions as one electrode, the insulating layer 330 functions as a dielectric, and the wiring 310 functions as the other electrode.

An insulating layer 380 is provided over the transistor 43, and the wiring 310 is provided over the insulating layer 380. An opening portion 390 is provided to penetrate the wiring 310 and the insulating layer 380, and the insulating layer 330 is provided to cover the opening portion 390. At the bottom portion of the opening portion 390, an opening portion reaching the conductive layer 120 is provided in the insulating layer 330. The conductive layer 320 is provided to fill the opening portion 390 and is in contact with the conductive layer 120 at the bottom portion of the opening portion 390. An insulating layer 385 functioning as an interlayer film is provided over the insulating layer 330 outside the opening portion 390. Here, the insulating layer 380, the insulating layer 385, and the capacitor 45 are provided in the layer 40_3.

The transistor 44 is provided over the insulating layer 385 and the conductive layer 320. The semiconductor layer 270 of the transistor 44 includes a region in contact with the conductive layer 320 at the bottom portion of the opening portion 290. That is, it can be said that the conductive layer 320 also includes a region functioning as one of the source electrode and the drain electrode of the transistor 44. In other words, the conductive layer 320 has a function of a wiring that connects the one of the source electrode and the drain electrode of the transistor 44 and the gate electrode (the conductive layer 120) of the transistor 43.

### [Transistor_1]

Next, the details of the transistor 43 and the transistor 44 are described. The transistor 43 and the transistor 44, which differ in the wiring connection mode and the like as described above, can be regarded as having basically the same structure in terms of operation; hence, the transistor 44 is described here.

As illustrated in FIG. 14C, FIG. 14D, and the like, the transistor 44 can have a structure including the conductive layer 120; the wiring 65 over the insulating layer 280; the semiconductor layer 270 provided in contact with the top surface of the conductive layer 120, which is exposed in the opening portion 290, the side surface of the insulating layer 280 in the opening portion 290, the side surface of the wiring 65 in the opening portion 290, and at least part of the top surface of the wiring 65; the insulating layer 230 provided in contact with the top surface of the semiconductor layer 270; and the conductive layer 220 provided in contact with the top surface of the insulating layer 230.

At least some of the components of the transistor 44 are provided in the opening portion 290. Here, the bottom portion of the opening portion 290 is also the top surface of the conductive layer 120, and the side surface of the opening portion 290 is also the side surface of the insulating layer 280 and the side surface of the wiring 65.

The opening portion 290 has a pillar shape with a substantially circular top-view shape. With such a structure, the semiconductor device can be reduced in size or highly integrated. Note that the side surface of the opening portion 290 is preferably perpendicular to the top surface of the wiring 63.

In order to increase the area where the transistor 44 and the transistor 43 overlap each other, the planar shape of the opening portion 290 is preferably the same as or similar to the planar shape of the opening portion 190 where the transistor 43 is formed.

Portions of the semiconductor layer 270, the insulating layer 230, and the conductive layer 220 that are provided in the opening portion 290 reflect the shape of the opening portion 290. Thus, the semiconductor layer 270 is provided to cover the bottom portion and the side surface of the opening portion 290, the insulating layer 230 is provided to cover the semiconductor layer 270, and the conductive layer 220 is provided to be embedded in a concave portion that is defined by the insulating layer 230 and reflects the shape of the opening portion 290.

Although an example in which the opening portion 290 and the conductive layer 220 are substantially circular in the plan view is described in this embodiment, the present invention is not limited thereto. For example, the opening portion 290 and the conductive layer 220 may each have an elliptical shape, a polygonal shape such as a square shape, or a polygonal shape such as a square shape with rounded corners in the plan view. In such a case, the maximum width of the opening portion 290 is preferably calculated as appropriate in accordance with the shape of the opening portion 290 in the plan view. The maximum width of the conductive layer 220 is preferably calculated as appropriate in accordance with the shape of the conductive layer 220 in the plan view.

For example, in the case where the opening portion 290 is a square in the plan view, the maximum width of the opening portion 290 is preferably the length of a diagonal line of the square. In the case where the conductive layer 220 is a square in the plan view, the maximum width of the conductive layer 220 is preferably the length of a diagonal line of the square. As another example, in the case where the opening portion 290 and the conductive layer 220 each have an elliptical shape, a polygonal shape, a polygonal shape with rounded corners, or the like in the plan view, the maximum width of each of the opening portion 290 and the conductive layer 220 is preferably the diameter of the smallest circle including the planar shape of the opening portion 290 (i.e., the minimum bounding circle).

The description of the shape of the opening portion 290 can apply also to the opening portion 190. The description of the shape of the conductive layer 220 can apply also to the conductive layer 120.

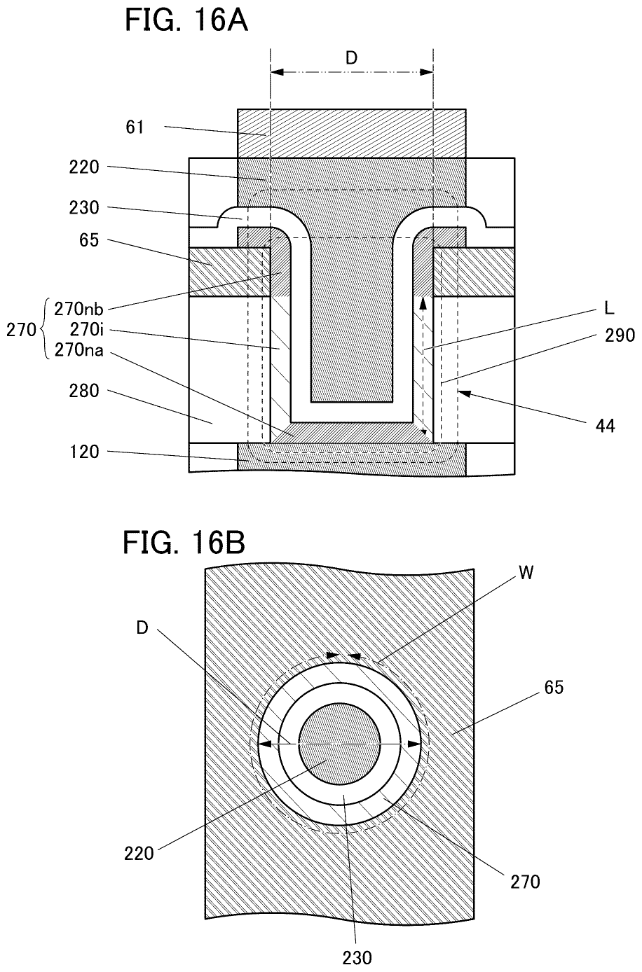

FIG. 16A is an enlarged view of the semiconductor layer 270 and its vicinity in FIG. 14C, FIG. 14D, and the like. FIG. 16B is a plan view including the wiring 65.

As illustrated in FIG. 16A, the semiconductor layer 270 includes a region 270i and a region 270na and a region 270nb provided such that the region 270i is positioned therebetween.

The region 270na is a region of the semiconductor layer 270 in contact with the conductive layer 120. At least part of the region 270na functions as one of a source region and a drain region of the transistor 44. The region 270nb is a region of the semiconductor layer 270 in contact with the wiring 65. At least part of the region 270nb functions as the other of the source region and the drain region of the transistor 44. As illustrated in FIG. 16B, the wiring 65 is in contact with all the perimeter of the semiconductor layer 270. Thus, the other of the source region and the drain region of the transistor 44 can be formed in all the outer periphery of a portion of the semiconductor layer 270 that is formed in the same layer as the wiring 65.

The region 270i is a region positioned between the region 270na and the region 270nb in the semiconductor layer 270. The region 270i includes a region along the side surface of the opening portion 290. At least part of the region 270i functions as a channel formation region of the transistor 44. That is, the channel formation region of the transistor 44 is formed in part of the semiconductor layer 270 that is positioned in a region between the conductive layer 120 and the wiring 65. It can be said that the channel formation region of the transistor 44 is positioned in a region of the semiconductor layer 270 that is in contact with the insulating layer 280 or its neighboring region. It can also be said that the channel formation region of the transistor 44 includes a region along the side surface of the opening portion 290.

Similarly, a channel formation region of the transistor 43 is formed in part of the semiconductor layer 170 that is positioned in a region between the wiring 63 and the wiring 67. It can be said that the channel formation region of the transistor 43 is positioned in a region of the semiconductor layer 170 that is in contact with the insulating layer 180 or its neighboring region. It can also be said that the channel formation region of the transistor 43 includes a region along the side surface of the opening portion 190.

The channel length of the transistor 44 is the distance between the source region and the drain region. In other words, the channel length of the transistor 44 is determined by the thickness of the insulating layer 280 over the conductive layer 120. In FIG. 16A, a channel length L of the transistor 44 is indicated by a dashed double-headed arrow. The channel length L is a distance between an end portion of a region where the semiconductor layer 270 and the conductive layer 120 are in contact with each other and an end portion of a region where the semiconductor layer 270 and the wiring 65 are in contact with each other in a cross-sectional view. That is, the channel length L corresponds to the length of the side surface of the insulating layer 280 on the opening portion 290 side in the cross-sectional view.

In a conventional transistor, the channel length is set by the light exposure limit of photolithography; meanwhile, in the present invention, the channel length can be set by the thickness of the insulating layer 280. Thus, the transistor 44 can have an extremely small channel length less than or equal to the light exposure limit of photolithography (e.g., less than or equal to 60 nm, less than or equal to 50 nm, less than or equal to 40 nm, less than or equal to 30 nm, less than or equal to 20 nm, or less than or equal to 10 nm, and greater than or equal to 1 nm or greater than or equal to 5 nm). Accordingly, the transistor 44 can have a higher on-state current and improved frequency characteristics. Thus, a semiconductor device with high operating speed can be provided.

In addition, as described above, the channel formation region, the source region, and the drain region can be formed in the opening portion 290. Thus, the area occupied by the transistor 44 can be reduced as compared with that occupied by a conventional transistor in which the channel formation region, the source region, and the drain region are provided separately in the plan view. This allows high integration of the semiconductor device; thus, the memory capacity per unit area can be increased.

A transistor including a channel formation region along the side surface of the insulating layer 280 in the opening portion 290 as described above can be referred to as a vertical transistor or a VFET (Vertical Field Effect Transistor).

In this specification and the like, a vertical transistor including a metal oxide in a channel formation region is referred to as a vertical OS transistor.

Also in the plane including the channel formation region of the semiconductor layer 270, the semiconductor layer 270, the insulating layer 230, and the conductive layer 220 are provided concentrically as in FIG. 16B. Thus, the side surface of the conductive layer 220 provided at the center faces the side surface of the semiconductor layer 270 with the insulating layer 230 therebetween. That is, in the plan view, all the circumference of the semiconductor layer 270 serves as the channel formation region. In this case, for example, the channel width of the transistor 44 is determined by the length of the outer periphery of the semiconductor layer 270. In other words, the channel width of the transistor 44 is determined by the maximum width of the opening portion 290 (the maximum diameter in the case where the opening portion 290 is circular in the plan view). In FIG. 16A and FIG. 16B, a maximum width D of the opening portion 290 is indicated by a dashed double-dotted double-headed arrow. In FIG. 16B, a channel width W of the transistor 44 is indicated by a dashed-dotted double-headed arrow. By increasing the maximum width D of the opening portion 290, the channel width per unit area can be increased and the on-state current can be increased.

In the case where the opening portion 290 is formed by a photolithography method, the maximum width D of the opening portion 290 is set by the light exposure limit of photolithography. In addition, the maximum width D of the opening portion 290 is set by the thicknesses of the semiconductor layer 270, the insulating layer 230, and the conductive layer 220 that are provided in the opening portion 290. The maximum width D of the opening portion 290 is preferably, for example, greater than or equal to 5 nm, greater than or equal to 10 nm, or greater than or equal to 20 nm and less than or equal to 100 nm, less than or equal to 60 nm, less than or equal to 50 nm, less than or equal to 40 nm, or less than or equal to 30 nm. In the case where the opening portion 290 is circular in the plan view, the maximum width D of the opening portion 290 corresponds to the diameter of the opening portion 290, and the channel width W can be “D×π”.

In the semiconductor device of one embodiment of the present invention, the channel length L of the transistor 44 is preferably smaller than at least the channel width W of the transistor 44. The channel length L of the transistor 44 is greater than or equal to 0.1 times and less than or equal to 0.99 times, preferably greater than or equal to 0.5 times and less than or equal to 0.8 times the channel width W of the transistor 44. Such a structure enables a transistor with favorable electrical characteristics and high reliability.

When the opening portion 290 is formed to be substantially circular in the plan view, the semiconductor layer 270, the insulating layer 230, and the conductive layer 220 are provided concentrically. This makes the distance between the conductive layer 220 and the semiconductor layer 270 substantially uniform, so that a gate electric field can be substantially uniformly applied to the semiconductor layer 270.

It is preferable that the channel formation region of the transistor including a metal oxide in a semiconductor layer contain fewer oxygen vacancies or have a lower concentration of impurities such as hydrogen, nitrogen, and a metal element than the source region and the drain region. In some cases, hydrogen in the vicinity of an oxygen vacancy forms a defect where hydrogen enters the oxygen vacancy (hereinafter sometimes referred to as VoH), which generates an electron serving as a carrier. Therefore, it is preferable that VoH be also reduced in the channel formation region. Thus, the channel formation region of the transistor is a high-resistance region having a low carrier concentration. Accordingly, the channel formation region of the transistor can be regarded as being i-type (intrinsic) or substantially i-type.

Meanwhile, the source region and the drain region of the transistor including the metal oxide in the semiconductor layer include more oxygen vacancies, include more VoH, or have a higher concentration of impurities such as hydrogen, nitrogen, and a metal element than the channel formation region, and thus are low-resistance regions with high carrier concentrations. In other words, the source region and the drain region of the transistor are n-type regions that have a higher carrier concentration and a lower resistance than the channel formation region.

Although the opening portion 290 is provided such that the side surface of the opening portion 290 is perpendicular to the top surface of the wiring 63 in FIG. 16A, for example, the present invention is not limited thereto. The side surface of the opening portion 290 may be tapered, for example.

The band gap of the metal oxide used for the semiconductor layer 270 is preferably greater than or equal to 2 eV, further preferably greater than or equal to 2.5 eV. With the use of a metal oxide having a wide band gap for the semiconductor layer 270, the off-state current of the transistor can be reduced. The use of the transistor having a low off-state current in the memory cell enables long-period retention of stored contents. That is, refresh operation is not required or the frequency of the refresh operation is extremely low; thus, power consumption of the semiconductor device can be adequately reduced. The frequency of refresh operation in a general DRAM (Dynamic Random Access Memory) is approximately once per 60 msec, whereas the frequency of refresh operation in the semiconductor device of one embodiment of the present invention can be approximately once per 10 sec, which is greater than or equal to 10 times or greater than or equal to 100 times that of the general DRAM. In the semiconductor device of one embodiment of the present invention, the frequency of refresh operation can be once per period of 1 sec to 100 sec, preferably once per period of 5 sec to 50 sec.

As the semiconductor layer 270, a single layer or stacked layers of any of metal oxides described in the section [Metal oxide] below can be used.

For the semiconductor layer 270, a metal oxide with a composition of In:M:Zn=1:3:2 [atomic ratio] or in the neighborhood thereof, a composition of In:M:Zn=1:3:4 [atomic ratio] or in the neighborhood thereof, a composition of In:M:Zn=1:1:0.5 [atomic ratio] or in the neighborhood thereof, a composition of In:M:Zn=1:1:1 [atomic ratio] or in the neighborhood thereof, a composition of In M:Zn=1:1:1.2 [atomic ratio] or in the neighborhood thereof, a composition of In M:Zn=1:1:2 [atomic ratio] or in the neighborhood thereof, or a composition of In M:Zn=4:2:3 [atomic ratio] or in the neighborhood thereof is specifically used. Note that the neighborhood of the atomic ratio includes ±30 % of an intended atomic ratio. Gallium is preferably used as the element M.

When the metal oxide is deposited by a sputtering method, the above atomic ratio is not limited to the atomic ratio of the deposited of the metal oxide and may be the atomic ratio of a sputtering target used for depositing the metal oxide.

For analysis of the composition of the metal oxide used for the semiconductor layer 270, energy dispersive X-ray spectroscopy (EDX), X-ray photoelectron spectrometry (XPS), inductively coupled plasma-mass spectrometry (ICP-MS), or inductively coupled plasma-atomic emission spectrometry (ICP-AES) can be used, for example. Alternatively, a combination of those methods may be used for the analysis. Note that as for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage.

A sputtering method or an atomic layer deposition (ALD) method can be suitably used to form the metal oxide. Note that in the case where the metal oxide is formed by a sputtering method, the composition of the formed metal oxide may be different from the composition of a sputtering target. In particular, the content percentage of zinc in the formed metal oxide may be reduced to approximately 50% of that of the sputtering target.

The semiconductor layer 270 preferably has crystallinity. Examples of an oxide semiconductor having crystallinity include a CAAC-OS (c-axis aligned crystalline oxide semiconductor), an nc-OS (nanocrystalline oxide semiconductor), a polycrystalline oxide semiconductor, and a single crystal oxide semiconductor. For the semiconductor layer 270, the CAAC-OS or the nc-OS is preferably used, and the CAAC-OS is particularly preferably used.

A CAAC-OS preferably includes a plurality of layered crystal regions and the c-axis is preferably aligned in a normal direction of a surface where the CAAC-OS is formed. For example, the semiconductor layer 270 preferably includes a layered crystal that is substantially parallel to the side surface of the opening portion 290, particularly the side surface of the insulating layer 280. With such a structure, the layered crystals of the semiconductor layer 270 are formed substantially in parallel with the channel length direction of the transistor 44, so that the on-state current of the transistor can be increased.

A CAAC-OS is a metal oxide having a dense structure with high crystallinity and a small amount of impurities and defects (e.g., oxygen vacancies). In particular, after the formation of a metal oxide, heat treatment is performed at a temperature at which the metal oxide does not become a polycrystal (e.g., higher than or equal to 400° C. and lower than or equal to 600° C.), whereby a CAAC-OS having a dense structure with higher crystallinity can be obtained. As the density of the CAAC-OS is increased in such a manner, diffusion of impurities or oxygen in the CAAC-OS can be further reduced.

A clear grain boundary is difficult to observe in a CAAC-OS; thus, it can be said that a reduction in electron mobility due to the grain boundary is less likely to occur. Thus, a metal oxide including a CAAC-OS is physically stable. Therefore, the metal oxide including the CAAC-OS is resistant to heat and has high reliability.

When an oxide having crystallinity, such as a CAAC-OS, is used for the semiconductor layer 270, oxygen extraction from the semiconductor layer 270 by the source electrode or the drain electrode can be inhibited. This can inhibit oxygen extraction from the semiconductor layer 270 even when heat treatment is performed; thus, the transistor 44 is stable with respect to high temperatures in a manufacturing process (what is called thermal budget).

The crystallinity of the semiconductor layer 270 can be analyzed with an X-ray diffraction (XRD) pattern, a transmission electron microscope (TEM) image, or an electron diffraction (ED) pattern, for example. Alternatively, a combination of those methods may be used for the analysis.

Although the semiconductor layer 270 being a single layer is illustrated in FIG. 14C, FIG. 14D, and the like, the present invention is not limited thereto. The semiconductor layer 270 may have a stacked-layer structure of a plurality of oxide layers with different chemical compositions. For example, a structure may be employed in which a plurality of kinds of metal oxides selected from the above-described metal oxides are stacked as appropriate.

In the case where the semiconductor layer 270 has a stacked-layer structure of three layers, for example, the semiconductor layer 270 may have a structure in which a metal oxide with a composition of In:Ga:Zn=1:1:1 [atomic ratio] or in the neighborhood thereof, a metal oxide with a composition of In:Zn=1:1 [atomic ratio] or in the neighborhood thereof or with a composition of In:Zn=4:1 [atomic ratio] or in the neighborhood thereof, and a metal oxide with a composition of In:Ga:Zn=1:1:1 [atomic ratio] or in the neighborhood thereof are provided in this order from the conductive layer 120 side. With this structure, the on-state current of the transistor 44 can be increased, and the transistor can have high reliability with small variations.

As the insulating layer 230, a single layer or stacked layers of any of insulators described in the section [Insulator] below can be used. For the insulating layer 230, silicon oxide or silicon oxynitride can be used, for example. Silicon oxide and silicon oxynitride are preferable because of their thermal stability.

For the insulating layer 230, any of materials with a relative permittivity, that is, high-k materials, described in the section [Insulator] below may be used. For example, hafnium oxide, aluminum oxide, or the like may be used.

The thickness of the insulating layer 230 is preferably larger than or equal to 0.5 nm and smaller than or equal to 15 nm, further preferably larger than or equal to 0.5 nm and smaller than or equal to 12 nm, still further preferably larger than or equal to 0.5 nm and smaller than or equal to 10 nm. At least part of the insulating layer 230 has a region with the above-described thickness.

The concentration of impurities such as water and hydrogen in the insulating layer 230 is preferably reduced. This can inhibit entry of impurities such as water and hydrogen into the channel formation region of the semiconductor layer 270.

As illustrated in FIG. 14C, FIG. 14D, and the like, part of the insulating layer 230 is positioned outside the opening portion 290, that is, over the wiring 65 and the insulating layer 280. In this case, the insulating layer 230 preferably covers the side end portion of the semiconductor layer 270. This can prevent a short circuit between the conductive layer 220 and the semiconductor layer 270. The insulating layer 230 preferably covers the side end portion of the wiring 65. This can prevent a short circuit between the conductive layer 220 and the wiring 65.

Although the insulating layer 230 being a single layer is illustrated in FIG. 14C, FIG. 14D, and the like, the present invention is not limited thereto. The insulating layer 230 may have a stacked-layer structure.

As the conductive layer 220, a single layer or stacked layers of any of conductors described in the section [Conductor] below can be used. For example, a conductive material with high conductivity, such as tungsten, can be used for the conductive layer 220.

A conductive material that is less likely to be oxidized, a conductive material having a function of inhibiting diffusion of oxygen, or the like is preferably used for the conductive layer 220. Examples of such conductive materials include a conductive material containing nitrogen (e.g., titanium nitride and tantalum nitride) and a conductive material containing oxygen (e.g., ruthenium oxide). This can inhibit a decrease in the conductivity of the conductive layer 220.

Although the conductive layer 220 being a single layer is illustrated in FIG. 14C, FIG. 14D, and the like, the present invention is not limited thereto. The conductive layer 220 may have a stacked-layer structure.

As the wiring 65, a single layer or stacked layers of any of the conductors described in the section [Conductor] below can be used. For example, a conductive material with high conductivity, such as tungsten, can be used for the wiring 65.

A conductive material that is less likely to be oxidized, a conductive material having a function of inhibiting diffusion of oxygen, or the like is preferably used for the wiring 65, as in the case of the conductive layer 220. For example, titanium nitride, tantalum nitride, or the like can be used. This structure can inhibit excessive oxidation of the wiring 65 due to the semiconductor layer 270.

A structure in which tungsten is stacked over titanium nitride may be used, for example. When tungsten is stacked in this manner, the conductivity of the wiring 65 can be increased.

In the case where the wiring 65 has a structure where a first conductive layer and a second conductive layer are stacked, the first conductive layer may be formed using a conductive material with high conductivity and the second conductive layer may be formed using a conductive material containing oxygen, for example. When a conductive material containing oxygen is used for the second conductive layer of the wiring 65 that is in contact with the insulating layer 230, oxygen in the insulating layer 230 can be inhibited from diffusing into the first conductive layer of the wiring 65. For example, tungsten is preferably used for the first conductive layer of the wiring 65, and indium tin oxide to which silicon is added is preferably used for the second conductive layer of the wiring 65.

When the semiconductor layer 270 and the conductive layer 120 are in contact with each other, a metal compound or oxygen vacancies are formed, so that the resistance of the region 270na in the semiconductor layer 270 is reduced. The reduction in the resistance of the semiconductor layer 270 in contact with the conductive layer 120 can reduce the contact resistance between the semiconductor layer 270 and the conductive layer 120. Similarly, when the semiconductor layer 270 and the wiring 65 are in contact with each other, the resistance of the region 270nb in the semiconductor layer 270 is reduced. Accordingly, the contact resistance between the semiconductor layer 270 and the wiring 65 can be reduced.

The insulating layer 280 functions as an interlayer film and thus preferably has a low relative permittivity. When a material with a low relative permittivity is used for the interlayer film, parasitic capacitance generated between wirings can be reduced. As the insulating layer 280, a single layer or stacked layers of any of insulators each containing a material with a low relative permittivity described in the section [Insulator] below can be used. Silicon oxide and silicon oxynitride are preferable because of their thermal stability

The concentration of impurities such as water and hydrogen in the insulating layer 280 is preferably reduced. This can inhibit entry of impurities such as water and hydrogen into the channel formation region of the semiconductor layer 270.

For the insulating layer 280, an insulator containing oxygen that is released by heating (hereinafter sometimes referred to as excess oxygen) is preferably used. By performing heat treatment on the insulating layer 280 containing excess oxygen, oxygen can be supplied from the insulating layer 280 to the channel formation region of the semiconductor layer 270 and oxygen vacancies and VoH can be reduced. Accordingly, the transistor 44 can have stable electrical characteristics and higher reliability.

For the insulating layer 280, any of insulators having a function of capturing or fixing hydrogen described in the section [Insulator] below may be used. With this structure, hydrogen in the semiconductor layer 270 can be captured or fixed, so that the concentration of hydrogen in the semiconductor layer 270 can be reduced. For the insulating layer 280, magnesium oxide, aluminum oxide, or the like can be used.

Although insulating layer 280 being a single layer is illustrated in FIG. 14C, FIG. 14D, and the like, the present invention is not limited thereto. The insulating layer 280 may have a stacked-layer structure.

### [Transistor_2]

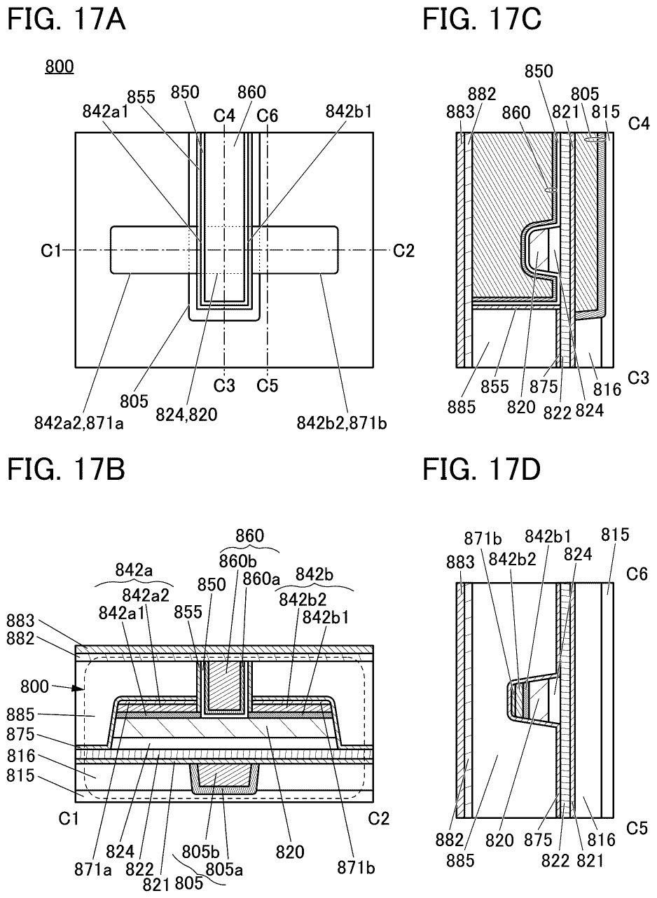

FIG. 17A is a plan view of a transistor 800 that is a transistor having a structure different from the above structure example. FIG. 17B is a cross-sectional view along the dashed-dotted line C1-C2 in FIG. 17A. FIG. 17B is also a cross-sectional view of the transistor 800 in the channel length direction. FIG. 17C is a cross-sectional view along the dashed-dotted line C3-C4 in FIG. 17A. FIG. 17C is also a cross-sectional view of the transistor 800 in the channel width direction. FIG. 17D is a cross-sectional view along the dashed-dotted line C5-C6 in FIG. 17A. FIG. 17D is also a cross-sectional view of the transistor 800 in the channel width direction. Note that some components are omitted in the plan view of FIG. 17A for clarity of the drawing.

The transistor 800 includes a conductive layer 805 (a conductive layer 805a and a conductive layer 805b) provided to be embedded in an insulating layer 816; an insulating layer 821 over the insulating layer 816 and the conductive layer 805; an insulating layer 822 over the insulating layer 821; an insulating layer 824 over the insulating layer 822; a semiconductor layer 820 over the insulating layer 824; a conductive layer 842a (a conductive layer 842a1 and a conductive layer 842a2) and a conductive layer 842b (a conductive layer 842b1 and a conductive layer 842b2) over the semiconductor layer 820; an insulating layer 871a over the conductive layer 842a; an insulating layer 871b over the conductive layer 842b; an insulating layer 850 over the semiconductor layer 820; and a conductive layer 860 (a conductive layer 860a and a conductive layer 860b) over the insulating layer 850.

An insulating layer 875 is provided over the insulating layer 871a and the insulating layer 871b, and an insulating layer 885 is provided over the insulating layer 875. An insulating layer 855, the insulating layer 850, and the conductive layer 860 are provided in an opening provided in the insulating layer 885 and the insulating layer 875. An insulating layer 882 is provided over the insulating layer 885 and the conductive layer 860. An insulating layer 883 is provided over the insulating layer 882. An insulating layer 815 is provided below the insulating layer 816 and the conductive layer 805. The insulating layer 855 is provided between the insulating layer 850 and the conductive layer 842a2, the conductive layer 842b2, the insulating layer 871a, the insulating layer 871b, the insulating layer 875, and the insulating layer 885.

Note that the insulating layer 815, the insulating layer 816, the conductive layer 805, the insulating layer 821, the insulating layer 822, the insulating layer 824, the semiconductor layer 820, the conductive layer 842a, the conductive layer 842b, the insulating layer 871a, the insulating layer 871b, the insulating layer 875, the insulating layer 885, the insulating layer 855, the insulating layer 850, the conductive layer 860, the insulating layer 882, and the insulating layer 883 may each have a single-layer structure or a stacked-layer structure.

The semiconductor layer 820 includes a region functioning as a channel formation region of the transistor 800. The conductive layer 860 includes a region functioning as a first gate electrode (an upper gate electrode) of the transistor 800. The insulating layer 850 includes a region functioning as a first gate insulating layer of the transistor 800. The conductive layer 805 includes a region functioning as a second gate electrode (a lower gate electrode) of the transistor 800. The insulating layer 824, the insulating layer 822, and the insulating layer 821 each include a region functioning as a second gate insulating layer of the transistor 800.

The conductive layer 842a includes a region functioning as one of a source electrode and a drain electrode of the transistor 800. The conductive layer 842b includes a region functioning as the other of the source electrode and the drain electrode of the transistor 800.

In the semiconductor layer 820, the channel formation region of the transistor 800 and a source region and a drain region provided such that the channel formation region is positioned therebetween are formed. At least part of the channel formation region is overlapped by the conductive layer 860. The source region is overlapped by the conductive layer 842a, and the drain region is overlapped by the conductive layer 842b. Note that the source region and the drain region can be interchanged with each other.

A metal oxide can be used for the semiconductor layer 820. For the semiconductor layer 820, a material similar to the above-described materials that can be used for the semiconductor layer 170 and the semiconductor layer 270 can be used, for example.

The conductive layer 842a has a stacked structure of the conductive layer 842a1 and the conductive layer 842a2 over the conductive layer 842a1, and the conductive layer 842b has a stacked structure of the conductive layer 842b1 and the conductive layer 842b2 over the conductive layer 842b1. The conductive layer 842a1 and the conductive layer 842b1 that are in contact with the semiconductor layer 820 are preferably conductive layers of metal nitride or the like that are not easily oxidized. In that case, the conductive layer 842a and the conductive layer 842b can be prevented from being oxidized excessively by oxygen contained in the semiconductor layer 820. The conductive layer 842a2 and the conductive layer 842b2 are preferably conductive layers having higher conductivity than the conductive layer 842a1 and the conductive layer 842b1, such as metal layers. In that case, the conductive layer 842a and the conductive layer 842b can function as high-conductivity wirings or electrodes.

For example, tantalum nitride or titanium nitride can be used for the conductive layer 842a1 and the conductive layer 842b1, and tungsten can be used for the conductive layer 842a2 and the conductive layer 842b2.

The opening portion provided in the insulating layer 885 and the insulating layer 875 overlaps a region between the conductive layer 842a2 and the conductive layer 842b2. In the plan view, the side surface of the opening portion in the insulating layer 885 is aligned or substantially aligned with the side surface of the conductive layer 842a2 and the side surface of the conductive layer 842b2. The conductive layer 842a1 and the conductive layer 842b1 are formed to partly extend toward the inside of the opening portion. Here, part of the top surface of the conductive layer 842a1 is in contact with the conductive layer 842a2, and part of the top surface of the conductive layer 842b1 is in contact with the conductive layer 842b2. Thus, in the opening portion, the insulating layer 855 is in contact with another part of the top surface of the conductive layer 842a1, another part of the top surface of the conductive layer 842b1, the side surface of the conductive layer 842a2, and the side surface of the conductive layer 842b2. The insulating layer 850 is in contact with the top surface of the semiconductor layer 820, the side surface of the conductive layer 842al, the side surface of the conductive layer 842b1, and the side surface of the insulating layer 855.

The insulating layer 855 is preferably an insulating layer of nitride or the like that is not easily oxidized. By anisotropic etching, the insulating layer 855 is formed in the shape of a side wall to be in contact with the sidewall of the opening portion provided in the insulating layer 885, for example (here, the sidewall of the opening portion corresponds to, for example, the side surface of the insulating layer 885). The insulating layer 855 is formed in contact with the side surface of the conductive layer 842a2 and the side surface of the conductive layer 842b2 and has a function of protecting the conductive layer 842a2 and the conductive layer 842b2. In order to supply oxygen to the semiconductor layer 820, heat treatment in an atmosphere containing oxygen is preferably performed after the separation into the conductive layer 842a1 and the conductive layer 842b1 and before the formation of the insulating layer 850. At this time, since the insulating layer 855 is formed in contact with the side surface of the conductive layer 842a2 and the side surface of the conductive layer 842b2, excessive oxidation of the conductive layer 842a2 and the conductive layer 842b2 can be prevented. For the insulating layer 855, silicon nitride can be used, for example.

The insulating layer 850 in contact with the channel formation region of the semiconductor layer 820 preferably has a function of capturing or fixing hydrogen. In that case, the hydrogen concentration in the channel formation region of the semiconductor layer 820 can be reduced. Accordingly, VoH in the channel formation region can be reduced, so that the channel formation region can be an i-type or substantially i-type region.

The insulating layer 850 functions as a gate insulating layer. The insulating layer 850 is provided in the opening portion formed in the insulating layer 885, together with the insulating layer 855 and the conductive layer 860. The thickness of the insulating layer 850 is preferably small for miniaturization of the transistor 800. The thickness of each layer included in the insulating layer 850 is preferably greater than or equal to 0.1 nm and less than or equal to 10 nm, further preferably greater than or equal to 0.1 nm and less than or equal to 5.0 nm, still further preferably greater than or equal to 0.5 nm and less than or equal to 5.0 nm, yet further preferably greater than or equal to 1.0 nm and less than 5.0 nm, yet still further preferably greater than or equal to 1.0 nm and less than or equal to 3.0 nm. Each of the layers included in the insulating layer 850 at least partly includes a region with the above-described thickness.

To form the insulating layer 850 having a small thickness, an ALD method is preferably used for the deposition. In the case where the insulating layer 850 and the insulating layer 855 are provided in the opening portion in the insulating layer 885, for example, an ALD method is preferably used for the deposition. Examples of an ALD method include a thermal ALD method, in which a precursor and a reactant react with each other only by a thermal energy, and a PEALD (Plasma Enhanced ALD) method, in which a reactant excited by plasma is used. A PEALD method utilizing plasma is sometimes preferable because deposition at lower temperatures is possible.

The thickness of the insulating layer 855 is preferably greater than or equal to 0.5 nm and less than or equal to 20 nm, further preferably greater than or equal to 0.5 nm and less than or equal to 10 nm, still further preferably greater than or equal to 0.5 nm and less than or equal to 3 nm. When the insulating layer 855 has the above-described thickness, excessive oxidation of the conductive layer 842a2 and the conductive layer 842b2 can be inhibited. In this case, at least part of the insulating layer 855 may have a region with the above-described thickness. When the thickness of the insulating layer 855 is set excessively large, the time for forming the insulating layer 855 by an ALD method is long, which decreases the productivity; for this reason, the thickness of the insulating layer 855 is preferably in the above range.

For example, the semiconductor device illustrated in FIG. 17A preferably has a structure in which hydrogen is inhibited from entering the transistor 800. For example, an insulator having a function of inhibiting diffusion of hydrogen is preferably provided to cover one or both of the top and bottom of the transistor 800. Accordingly, each of the insulating layer 815, the insulating layer 821, the insulating layer 822, the insulating layer 882, and the insulating layer 883 preferably includes an insulator having a function of inhibiting diffusion of oxygen and impurities such as water and hydrogen. It is possible to use, for example, aluminum oxide, magnesium oxide, hafnium oxide, zirconium oxide, oxide containing aluminum and hafnium (hafnium aluminate), oxide containing hafnium and zirconium (hafnium zirconium oxide), gallium oxide, indium gallium zinc oxide, silicon nitride, or silicon nitride oxide. For example, silicon nitride, which has a higher hydrogen barrier property, is preferably used for the insulating layer 883 and the insulating layer 821. For example, aluminum oxide, which has high capability of capturing or fixing hydrogen, is preferably used for the insulating layer 882. For example, hafnium oxide, which has high capability of capturing or fixing hydrogen and is a high-permittivity (high-k) material, is preferably used for the insulating layer 822. With such a structure where the transistor 800 is surrounded by upper and lower insulating layers having a function of inhibiting diffusion of oxygen and impurities such as water and hydrogen, excess oxygen and hydrogen can be inhibited from diffusing into the metal oxide. Thus, the semiconductor device can have improved electrical characteristics and reliability.

Here, it is preferable that a region of the insulating layer 875 that is not overlapped by the semiconductor layer 820 be in contact with the insulating layer 822, a side end portion of the insulating layer 875 be in contact with the insulating layer 855, and an upper end portion of the insulating layer 855 and an upper end portion of the insulating layer 850 be in contact with the insulating layer 882. With the above structure, in a region positioned between the insulating layer 883 and the insulating layer 821, the insulating layer 885 is isolated from the semiconductor layer 820 by the insulating layer 875, and the insulating layer 885 is isolated from the insulating layer 850 by the insulating layer 855. Accordingly, diffusion of impurities contained in the insulating layer 885, such as water and hydrogen, into the semiconductor layer 820 and the insulating layer 850 can be inhibited. Moreover, hydrogen contained in the insulating layer 850 can be captured and fixed in the insulating layer 882. With such a structure, diffusion of hydrogen into the metal oxide can be further inhibited. Thus, the semiconductor device can have improved electrical characteristics and reliability.

In the transistor 800, the conductive layer 805 is placed to be overlapped by the semiconductor layer 820 and the conductive layer 860. Here, the conductive layer 805 is preferably provided to be embedded in an opening portion formed in the insulating layer 816. The conductive layer 805 is preferably provided to extend in the channel width direction as illustrated in FIG. 17A and FIG. 17C. With such a structure, the conductive layer 805 functions as a wiring when a plurality of transistors are provided.

As illustrated in FIG. 17B and FIG. 17C, the conductive layer 805 preferably includes the conductive layer 805a and the conductive layer 805b. The conductive layer 805a is provided in contact with the bottom surface and the sidewall of the opening portion. The conductive layer 805b is provided to fill a concave portion that is defined by the conductive layer 805a and formed along the opening portion. Here, the top surface of the conductive layer 805 is level or substantially level with the top surface of the insulating layer 816.

When a conductive material having a function of inhibiting diffusion of hydrogen is used for the conductive layer 805a, impurities such as hydrogen contained in the conductive layer 805b can be prevented from diffusing into the semiconductor layer 820 through the insulating layer 816, for example. When a conductive material having a function of inhibiting diffusion of oxygen is used for the conductive layer 805a, the conductivity of the conductive layer 805b can be inhibited from being lowered because of oxidation. Examples of the conductive material having a function of inhibiting diffusion of oxygen include titanium, titanium nitride, tantalum, tantalum nitride, ruthenium, and ruthenium oxide. The conductive layer 805a can have a single-layer structure or a stacked-layer structure of the above conductive material(s). For example, the conductive layer 805a preferably includes titanium nitride.

For the conductive layer 805b, a conductive material containing tungsten, copper, or aluminum as its main component is preferably used. For example, the conductive layer 805b preferably includes tungsten.

The conductive layer 805 can function as the second gate electrode. In this case, by changing a potential applied to the conductive layer 805 not in conjunction with but independently from a potential applied to the conductive layer 860, the threshold voltage (Vth) of the transistor 800 can be controlled. In particular, by applying a negative potential to the conductive layer 805, Vth of the transistor 800 can be higher, and its off-state current can be reduced. Thus, a drain current at the time when a potential applied to the conductive layer 860 is 0 V can be lower in the case where a negative potential is applied to the conductive layer 805 than in the case where the negative potential is not applied to the conductive layer 805.

The electrical resistivity of the conductive layer 805 is designed in consideration of the potential applied to the conductive layer 805, and the thickness of the conductive layer 805 is set in accordance with the electrical resistivity. The thickness of the insulating layer 816 is substantially equal to the thickness of the conductive layer 805. Here, the conductive layer 805 and the insulating layer 816 are preferably as thin as possible in the allowable range of the design of the conductive layer 805. When the thickness of the insulating layer 816 is reduced, the absolute amount of impurities such as hydrogen contained in the insulating layer 816 can be reduced, thereby inhibiting diffusion of the impurities into the semiconductor layer 820.

The insulating layer 824 that is in contact with the semiconductor layer 820 preferably includes silicon oxide or silicon oxynitride, for example. Accordingly, oxygen can be supplied from the insulating layer 824 to the semiconductor layer 820, so that oxygen vacancies can be reduced.

The insulating layer 824 is preferably processed into an island shape in the same manner as the semiconductor layer 820. Thus, in the case where a plurality of the transistors 800 are provided, the transistors 800 each include the insulating layer 824 of substantially the same size. Accordingly, substantially the same amount of oxygen is supplied from the insulating layer 824 to the semiconductor layer 820 in the transistors 800. This can reduce variations in electrical characteristics of the transistors 800 in the substrate plane. Note that the structure is not limited to this, and it is possible not to pattern the insulating layer 824 as in the case of the insulating layer 822.

In this specification and the like, an island shape refers to a state where two or more layers formed using the same material in the same step are physically separated from each other. For example, the term “island-shaped light-emitting layer” refers to a state where the light-emitting layer and its adjacent light-emitting layer are physically separated from each other.

A conductive material that is less likely to be oxidized or a conductive material having a function of inhibiting diffusion of oxygen is preferably used for each of the conductive layer 842a, the conductive layer 842b, and the conductive layer 860. Examples of such conductive materials include a conductive material containing nitrogen and a conductive material containing oxygen. Thus, a decrease in the conductivity of the conductive layer 842a, the conductive layer 842b, and the conductive layer 860 can be inhibited.

The insulating layer 871a and the insulating layer 871b are inorganic insulating layers that function as etching stoppers in the processing into the conductive layer 842a2 and the conductive layer 842b2 and protect the conductive layer 842a2 and the conductive layer 842b2. Since the insulating layer 871a and the insulating layer 871b are respectively in contact with the conductive layer 842a and the conductive layer 842b, the insulating layer 871a and the insulating layer 871b are preferably inorganic insulators that are less likely to oxidize the conductive layers 842a and 842b. The insulating layer 871a and the insulating layer 871b preferably have a stacked-layer structure of a nitride insulator and an oxide insulator, for example.

Note that in this specification and the like, a transistor structure where a channel formation region is electrically surrounded by at least the electric field of a first gate electrode is referred to as a surrounded channel (S-channel) structure. The S-channel structure disclosed in this specification and the like is different from a Fin-type structure or a planar structure. Meanwhile, the S-channel structure disclosed in this specification and the like can be regarded as a kind of the Fin-type structure. Note that in this specification and the like, the Fin-type structure refers to a structure where a gate electrode is provided to cover at least two or more surfaces (specifically, two surfaces, three surfaces, four surfaces, or the like) of a channel. With the Fin-type structure and the S-channel structure, resistance to a short-channel effect can be increased, that is, a transistor in which a short-channel effect does not easily occur can be provided.

When the transistor 800 has the above-described S-channel structure, the channel formation region can be electrically surrounded. Since the S-channel structure is a structure where the channel formation region is electrically surrounded, the S-channel structure can be regarded as being substantially equivalent to a GAA (Gate All Around) structure or an LGAA (Lateral Gate All Around) structure. When the transistor 800 has the S-channel structure, the GAA structure, or the LGAA structure, the channel formation region that is formed at the interface between the semiconductor layer 820 and the gate insulating layer or in the vicinity of the interface can be formed in the entire bulk of the semiconductor layer 820. Accordingly, the density of current flowing through the transistor can be increased, which can be expected to increase the on-state current of the transistor or increase the field-effect mobility of the transistor.

In this embodiment, the insulating layer 824 with an island shape is provided. Accordingly, as illustrated in FIG. 17C, at least part of the bottom surface of the conductive layer 860 can be positioned lower than the bottom surface of the semiconductor layer 820. Thus, the conductive layer 860 can be provided to face the top surface and the side surface of the semiconductor layer 820, so that an electric field of the conductive layer 860 can be applied to the top surface and the side surface of the semiconductor layer 820. When the insulating layer 824 with an island shape is provided in this manner, the transistor 800 can have the S-channel structure.

The conductive layer 860 preferably includes the conductive layer 860a and the conductive layer 860b provided over the conductive layer 860a. For example, the conductive layer 860a is preferably provided to cover the bottom surface and the side surface of the conductive layer 860b. In this case, a conductive material that is less likely to be oxidized or a conductive material having a function of inhibiting diffusion of oxygen is preferably used for the conductive layer 860a. When the conductive layer 860a has a function of inhibiting diffusion of oxygen, the conductivity of the conductive layer 860b can be inhibited from being lowered because of oxidation due to oxygen contained in the insulating layer 885, for example. Examples of the conductive material having a function of inhibiting diffusion of oxygen include titanium, titanium nitride, tantalum, tantalum nitride, ruthenium, and ruthenium oxide.

For the conductive layer 860b, a conductor having high conductivity is preferably used. For example, a conductive material containing tungsten, copper, or aluminum as its main component can be used for the conductive layer 860b. The conductive layer 860b may have a stacked-layer structure, for example, a stacked-layer structure of titanium or titanium nitride and the above conductive material.

The insulating layer 816 and the insulating layer 885 each preferably have a lower permittivity than the insulating layer 822. When a material with a low permittivity is used for the interlayer films, parasitic capacitance generated between wirings can be reduced.

The transistor 800 having the above structure can be used as a transistor provided in the layer 30, for example. Thus, the transistors included in the switch circuit 52, specifically, the transistor 54 and the transistor 55, can have the same structure as the transistor 800. The transistors included in the backup circuit 34, specifically, the transistor M11 to the transistor M13, can have the same structure as the transistor 800.

Note that the transistor provided in the layer 30 may have the same structure as the transistor 43 or the transistor 44. That is, the transistor provided in the layer 30 may be a vertical transistor. For example, the transistor 54, the transistor 55, and the transistor M11 to the transistor M13 may be vertical transistors. Note that the transistor 43 and the transistor 44 may have the same structure as the transistor 800. Alternatively, one of the transistor 43 and the transistor 44 may be a vertical transistor, and the other of the transistor 43 and the transistor 44 may be a transistor having the same structure as the transistor 800. For example, the transistor 43 may be a vertical transistor, and the transistor 44 may be a transistor having the same structure as the transistor 800.

### <Structure Example_2 of Semiconductor Device>

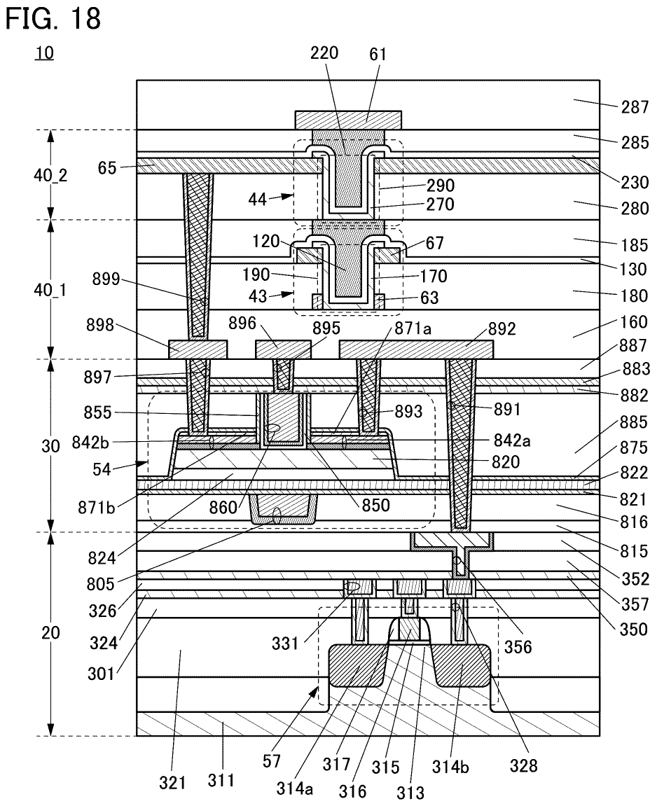

FIG. 18 is a cross-sectional view illustrating a structure example of the layer 20, the layer 30, the layer 40_1, and the layer 40_2 included in the semiconductor device 10. In FIG. 18, a transistor 57, the transistor 54, the transistor 43, and the transistor 44 are respectively illustrated as a transistor provided in the layer 20, a transistor provided in the layer 30, a transistor provided in the layer 40_1, and a transistor provided in the layer 40_2.

The transistor 57 is provided on a substrate 311 and includes a conductive layer 316 functioning as a gate electrode, an insulating layer 315 functioning as a gate insulating layer, an insulating layer 317 formed on a side surface of the conductive layer 316, a semiconductor region 313 including part of the substrate 311, a low-resistance region 314a functioning as one of a source region and a drain region, and a low-resistance region 314b functioning as the other of the source region and the drain region. The transistor 57 can be a p-channel transistor or an n-channel transistor. The transistor 57 can be, for example, the transistor included in the driver circuit 22 illustrated in FIG. 1. Note that a transistor included in the CPU 21 can have the same structure as the transistor 57, for example. As the substrate 311, a single crystal silicon substrate can be used, for example.

Here, in the transistor 57 illustrated in FIG. 18, the semiconductor region 313 (part of the substrate 311) where a channel is formed has a protruding shape. The conductive layer 316 is provided to cover a side surface and the top surface of the semiconductor region 313 with the insulating layer 315 therebetween. Note that a material adjusting the work function may be used for the conductive layer 316. Such a transistor 57 is also referred to as a FIN-type transistor because it utilizes a protruding portion of the semiconductor substrate. Note that an insulating layer functioning as a mask for forming the protruding portion may be provided in contact with an upper portion of the protruding portion. Although the case where the protruding portion is formed by processing part of the semiconductor substrate is described here, a semiconductor film having a protruding shape may be formed by processing an SOI (Silicon on Insulator) substrate.

Note that the transistor 57 illustrated in FIG. 18 is an example and is not limited to the structure illustrated therein; an appropriate transistor can be used in accordance with a circuit structure, a driving method, or the like.

A wiring layer provided with an interlayer film, a wiring and a plug may be provided between the components. A plurality of wiring layers can be provided in accordance with the design. Furthermore, in this specification and the like, a wiring and a plug electrically connected to the wiring may be a single component. That is, in some cases, part of a conductor functions as a wiring or part of a conductor functions as a plug.

For example, an insulating layer 321, an insulating layer 301, an insulating layer 324, and an insulating layer 326 are stacked in this order over the transistor 57 as interlayer films. A conductive layer 328, for example, is embedded in the insulating layer 321 and the insulating layer 301. A conductive layer 331, for example, is embedded in the insulating layer 324 and the insulating layer 326. Note that the conductive layer 328 and the conductive layer 331 each function as a plug or a wiring.

The insulating layers functioning as interlayer films may also function as planarization films that cover uneven shapes therebelow. For example, the top surface of the insulating layer 301 may be planarized by planarization treatment using a chemical mechanical polishing (CMP) method, for example, to improve planarity.

A wiring layer may be provided over the insulating layer 326 and the conductive layer 331. For example, in FIG. 18, an insulating layer 350, an insulating layer 357, and an insulating layer 352 are stacked in this order over the insulating layer 326 and the conductive layer 331. A conductive layer 356 is formed in the insulating layer 350, the insulating layer 357, and the insulating layer 352. The conductive layer 356 functions as a plug or a wiring.

FIG. 18 illustrates an example in which the transistor 54 provided in the layer 30 has the same structure as the transistor 800 illustrated in FIG. 17B. The insulating layer 815, the insulating layer 816, the insulating layer 821, the insulating layer 822, the insulating layer 875, the insulating layer 885, the insulating layer 882, the insulating layer 883, and an insulating layer 887 are stacked in this order in the layer 30. For the insulating layer 887, a material similar to any of the materials that can be used for the insulating layer 816 can be used, for example.

In the example illustrated in FIG. 18, an opening portion reaching the conductive layer 356 is provided in the insulating layer 815, the insulating layer 816, the insulating layer 821, the insulating layer 822, the insulating layer 875, the insulating layer 885, the insulating layer 882, the insulating layer 883, and the insulating layer 887, and a conductive layer 891 is provided to fill the opening portion. An opening portion reaching the conductive layer 842a is provided in the insulating layer 871a, the insulating layer 875, the insulating layer 885, the insulating layer 882, the insulating layer 883, and the insulating layer 887, and the conductive layer 891 is provided to fill the opening portion. An opening portion reaching the conductive layer 860 is provided in the insulating layer 882, the insulating layer 883, and the insulating layer 887, and a conductive layer 895 is provided to fill the opening portion. An opening portion reaching the conductive layer 842b is provided in the insulating layer 871b, the insulating layer 875, the insulating layer 885, the insulating layer 882, the insulating layer 883, and the insulating layer 887, and a conductive layer 897 is provided to fill the opening portion.

A conductive layer 892 is provided over the conductive layer 891, a conductive layer 893, and the insulating layer 887. A conductive layer 896 is provided over the conductive layer 895 and the insulating layer 887. A conductive layer 898 is provided over the conductive layer 897 and the insulating layer 887.

Accordingly, in the example illustrated in FIG. 18, the low-resistance region 314b and the conductive layer 842a are electrically connected to each other through the conductive layer 328, the conductive layer 356, the conductive layer 891, the conductive layer 892, and the conductive layer 893. The conductive layer 860 and the conductive layer 896 are electrically connected to each other through the conductive layer 895. The conductive layer 842b and the conductive layer 898 are electrically connected to each other through the conductive layer 897.

The conductive layer 891 to the conductive layer 898 each have a function of a plug or a wiring. The conductive layer 891, the conductive layer 893, the conductive layer 895, and the conductive layer 897 each preferably include a first conductive layer provided along the side surface and the bottom surface of the corresponding opening portion and a second conductive layer that is positioned more inward than the first conductive layer in the opening portion and provided to fill the opening portion.

For the first conductive layer, a conductive material in which hydrogen and oxygen are less likely to diffuse is preferably used. For example, tantalum, tantalum nitride, titanium, titanium nitride, ruthenium, ruthenium oxide, or the like is preferably used. A single layer or stacked layers of the conductive material(s) having a function of inhibiting passage of impurities such as water and hydrogen may be used. Such a structure can inhibit entry of impurities such as water and hydrogen into the semiconductor layer 820 through the conductive layer 891, the conductive layer 893, the conductive layer 895, the conductive layer 897, or the like.

For the second conductive layer, a conductive material with high conductivity is preferably used, in which case the electrical resistance of the conductive layer 891, the conductive layer 893, the conductive layer 895, the conductive layer 897, and the like can be low. For the second conductive layer, a conductive material containing tungsten, copper, or aluminum as its main component is used, for example.

For the conductive layer 892, the conductive layer 896, and the conductive layer 898, a conductive material with high conductivity is preferably used. For the conductive layer 892, the conductive layer 896, and the conductive layer 898, a conductive material containing tungsten, copper, or aluminum as its main component can be used, for example.

FIG. 18 illustrates an example in which the transistor 43 illustrated in FIG. 14C, for example, is provided in the layer 40_1 and the transistor 44 illustrated in FIG. 14C is provided in the layer 40_2. In the layer 40_1, the insulating layer 160, the insulating layer 180, the insulating layer 130, and the insulating layer 185 are stacked in this order. In the layer 40_2 illustrated in FIG. 18, the wiring 65 is provided over the insulating layer 280, and the insulating layer 230 and the insulating layer 285 are stacked in this order over the wiring 65.

As described above, the wiring 61 is provided over the conductive layer 220 and the insulating layer 285. FIG. 18 illustrates an example in which an insulating layer 287 is provided over the insulating layer 285 and the wiring 61. Although the wiring 61 and the insulating layer 287 are regarded as being excluded from the layer 40_2 in the example illustrated in FIG. 18, they may be included in the layer 40_2. Note that for the insulating layer 287, a material similar to the material that can be used for the insulating layer 160 can be used, for example.

In the example illustrated in FIG. 18, an opening portion reaching the conductive layer 898 is provided in the insulating layer 160, the insulating layer 180, the insulating layer 130, the insulating layer 185, and the insulating layer 280, and a conductive layer 899 is provided to fill the opening portion. The wiring 65 is provided over the conductive layer 899 and the insulating layer 280.

Accordingly, in the example illustrated in FIG. 18, the conductive layer 842b and the wiring 65 are electrically connected to each other through the conductive layer 897, the conductive layer 898, and the conductive layer 899. As described above, FIG. 18 illustrates an example in which the other of the source electrode and the drain electrode of the transistor 54 is electrically connected to the wiring 65. Thus, FIG. 18 illustrates a structure example of the transistor 54 provided in the switch circuit 52c illustrated in FIG. 3C, for example. In this case, at least some of the conductive layer 328, the conductive layer 356, the conductive layer 891, the conductive layer 892, the conductive layer 893, and the conductive layer 842a can function as the wiring 66.

The conductive layer 899 has a function of a plug or a wiring. The conductive layer 899 can have a structure similar to the structure that the conductive layer 891, the conductive layer 893, the conductive layer 895, and the conductive layer 897 can have. The conductive layer 899 can include, for example, a first conductive layer provided along the side surface and the bottom surface of the opening portion and a second conductive layer that is positioned more inward than the first conductive layer in the opening portion and provided to fill the opening portion.

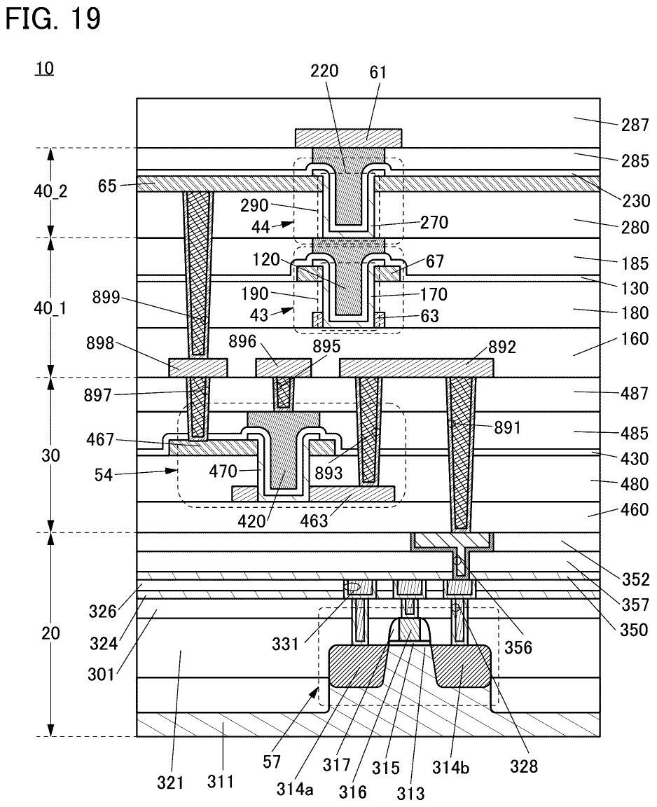

FIG. 19 is a cross-sectional view illustrating a structure example of the layer 20, the layer 30, the layer 40_1, and the layer 40_2 included in the semiconductor device 10. FIG. 19 illustrates an example in which the transistor 54 illustrated in FIG. 18 is a vertical transistor. FIG. 19 specifically illustrates an example in which the transistor 54 has a structure similar to that of the transistor 43.

The transistor 54 illustrated in FIG. 19 includes a conductive layer 463, a semiconductor layer 470, an insulating layer 430, a conductive layer 467, and a conductive layer 420. These correspond respectively to the wiring 63, the semiconductor layer 170, the insulating layer 130, the wiring 67, and the conductive layer 120 included in the transistor 43. In the layer 30 illustrated in FIG. 19, an insulating layer 460, an insulating layer 480, the insulating layer 430, and an insulating layer 485 are stacked in this order. For these insulating layers, materials similar to the materials that can be respectively used for the insulating layer 160, the insulating layer 180, the insulating layer 130, and the insulating layer 185 can be used. In the layer 30 illustrated in FIG. 19, an insulating layer 487 is provided over the insulating layer 485. The insulating layer 487 can have a structure in which the insulating layer 882, the insulating layer 883, and the insulating layer 887 illustrated in FIG. 18 are stacked in this order, for example.

In the example illustrated in FIG. 19, an opening portion reaching the conductive layer 356 is provided in the insulating layer 460, the insulating layer 480, the insulating layer 430, the insulating layer 485, and the insulating layer 487, and the conductive layer 891 is provided to fill the opening portion. An opening portion reaching the conductive layer 463 is provided in the insulating layer 480, the insulating layer 430, the insulating layer 485, and the insulating layer 487, and the conductive layer 893 is provided to fill the opening portion. An opening portion reaching the conductive layer 420 is provided in the insulating layer 487, and the conductive layer 895 is provided to fill the opening portion. An opening portion reaching the conductive layer 467 is provided in the insulating layer 430, the insulating layer 485, and the insulating layer 487, and the conductive layer 897 is provided to fill the opening portion.

The conductive layer 892 is provided over the conductive layer 891, the conductive layer 893, and the insulating layer 487. The conductive layer 896 is provided over the conductive layer 895 and the insulating layer 487. The conductive layer 898 is provided over the conductive layer 897 and the insulating layer 487.

Accordingly, in the example illustrated in FIG. 19, the low-resistance region 314b and the conductive layer 463 are electrically connected to each other through the conductive layer 328, the conductive layer 356, the conductive layer 891, the conductive layer 892, and the conductive layer 893. The conductive layer 420 and the conductive layer 896 are electrically connected to each other through the conductive layer 895.

The conductive layer 467 and the conductive layer 898 are electrically connected to each other through the conductive layer 897. Since the conductive layer 898 is electrically connected to the wiring 65 through the conductive layer 899 as described above, the conductive layer 467 and the wiring 65 are electrically connected to each other through the conductive layer 897, the conductive layer 898, and the conductive layer 899.

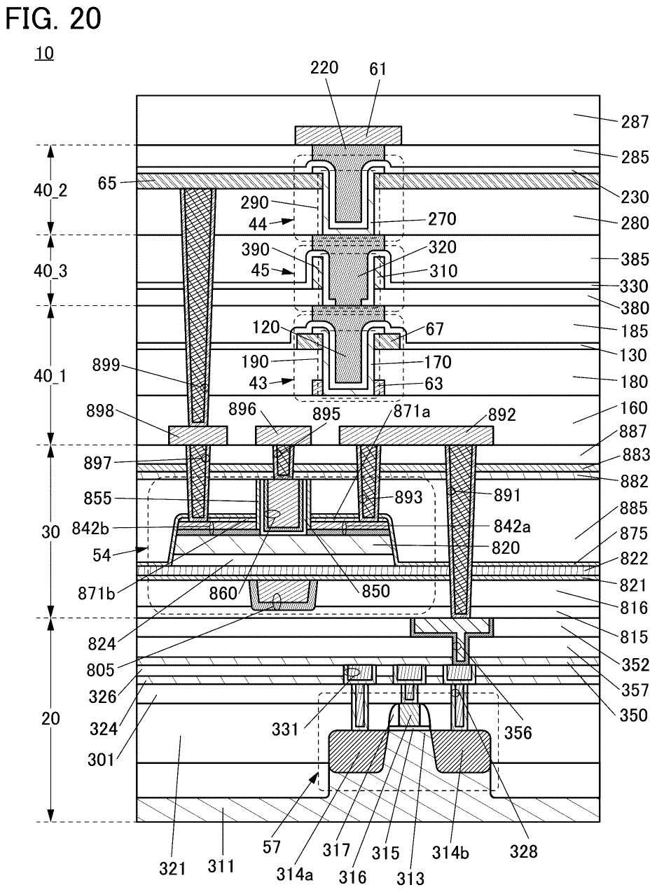

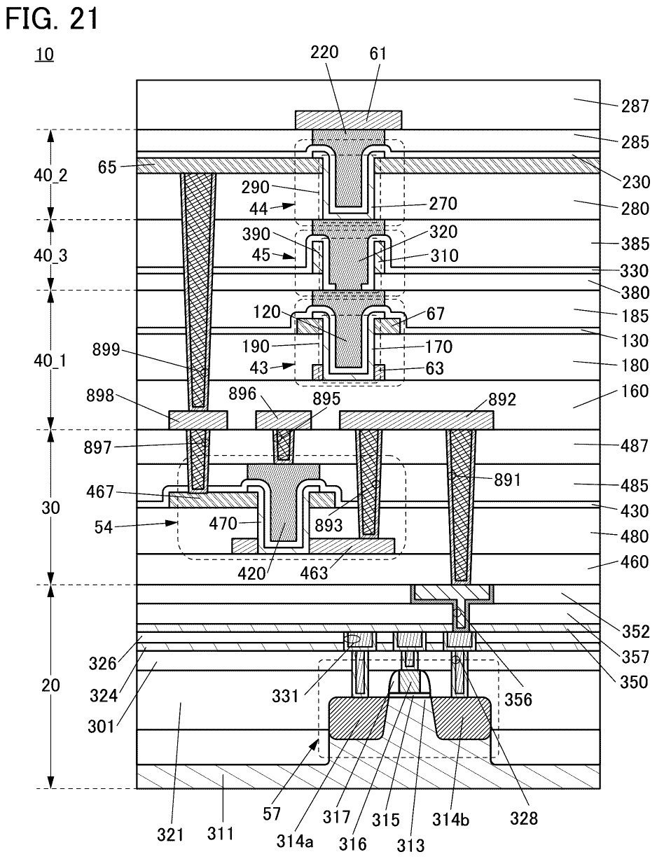

FIG. 20 is a cross-sectional view illustrating an example in which the semiconductor device 10 illustrated in FIG. 18 includes the layer 40_3 between the layer 40_1 and the layer 40_2. FIG. 21 is a cross-sectional view illustrating an example in which the semiconductor device 10 illustrated in FIG. 19 includes the layer 40_3. FIG. 20 and FIG. 21 each illustrate an example in which the capacitor 45 illustrated in FIG. 15B is provided in the layer 40_3. The insulating layer 380, the insulating layer 330, and the insulating layer 385 are stacked in this order in the layer 40_3.

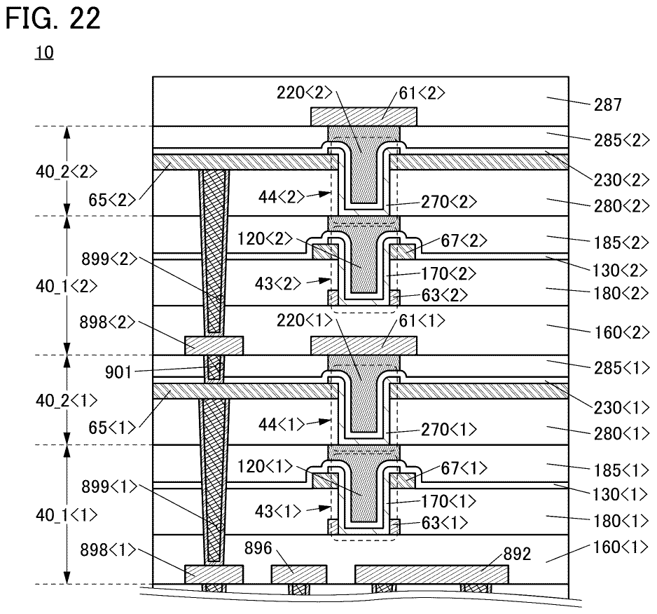

FIG. 22 is a cross-sectional view illustrating an example in which the semiconductor device 10 illustrated in FIG. 18, for example, includes two layers 40_1 and two layers 40_2. In the semiconductor device 10 illustrated in FIG. 22, a layer 40_1<1>, a layer 40_2<1>, a layer 40_1<2>, and a layer 40_2<2> are stacked in this order. Note that in FIG. 22, the layer 30 and the layer 20 provided below the layer 40_1 are not illustrated.

In FIG. 22, among the components provided in both the layer 40_1<1> and the layer 40_1<2>, “<1>” is added to the reference numerals representing the components provided in the layer 40_1<1> and “<2>” is added to the reference numerals representing the components provided in the layer 40_1<2> to make a distinction. The components provided in both the layer 40_2<1> and the layer 40_2<2> are distinguished from each other in the same manner.

In the semiconductor device 10 illustrated in FIG. 22, an opening portion reaching a wiring 65<1> is provided in an insulating layer 230<1> and an insulating layer 285<1>, and a conductive layer 901 is provided to fill the opening portion. The conductive layer 901 has a function of a plug or a wiring. The conductive layer 901 can have a structure similar to the structure that the conductive layer 891, the conductive layer 893, the conductive layer 895, the conductive layer 897, and the conductive layer 899 can have. The conductive layer 901 can include, for example, a first conductive layer provided along the side surface and the bottom surface of the opening portion and a second conductive layer that is positioned more inward than the first conductive layer in the opening portion and provided to fill the opening portion.

A conductive layer 898<2> is provided over the conductive layer 901 and the insulating layer 285<1>. The conductive layer 898<2> includes the same material as the wiring 61<1> and can be formed in the same step as the wiring 61<1>. Here, the wiring 61<1> can be provided in the layer 40_1<2>. An insulating layer 160<2> is provided over the insulating layer 285<1>, the conductive layer 898<2>, and the wiring 61<1>. The insulating layer 287 is provided over an insulating layer 285<2> and a wiring 61<2>.

The wiring 65<1> and a wiring 65<2> can be electrically connected to each other through the conductive layer 901, the conductive layer 898<2>, and a conductive layer 899<2>. Note that the semiconductor device 10 may omit the conductive layer 898<2> and the conductive layer 901. In that case, an opening portion reaching the wiring 65<1> is provided in the insulating layer 230<1>, the insulating layer 285<1>, the insulating layer 160<2>, an insulating layer 180<2>, an insulating layer 130<2>, an insulating layer 185<2>, and an insulating layer 280<2>, and the conductive layer 899<2> is provided to fill the opening portion, whereby the wiring 65<1> and the wiring 65<2> can be electrically connected to each other.

Note that three or more layers 40_1 and three or more layers 40_2 may be provided. For example, when a layer having the same structure as the layer 40_1<2> and a layer having the same structure as the layer 40_2<2> are provided to be stacked between the insulating layer 285<2> and the conductive layer 220<2> and the insulating layer 287 and the wiring 61<2>, three or more layers 40_1 and three or more layers 40_2 can be provided.

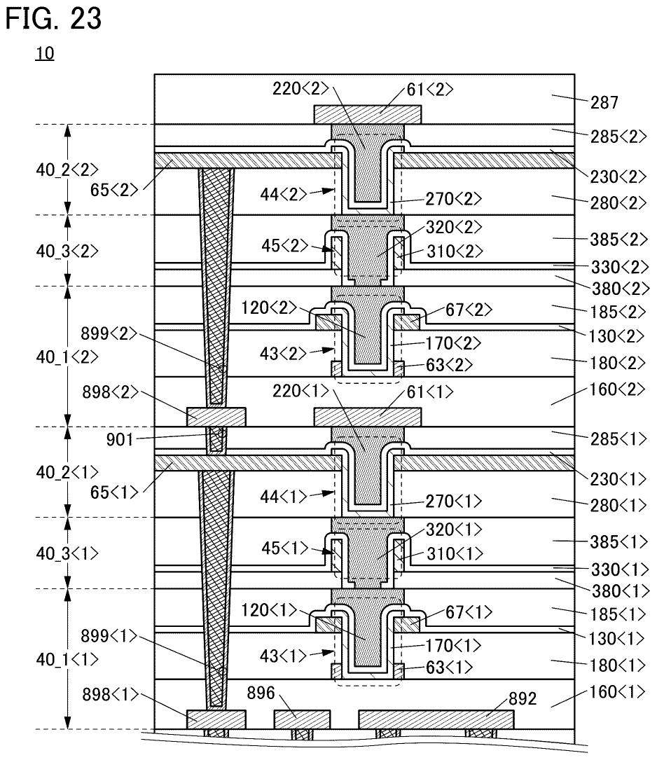

FIG. 23 is a cross-sectional view illustrating an example in which the semiconductor device 10 illustrated in FIG. 20, for example, includes two layers 40_1, two layers 40_2, and two layers 40_3. In the semiconductor device 10 illustrated in FIG. 23, the layer 40_1<1>, a layer 40_3<1>, the layer 40_2<1>, the layer 40_1<2>, a layer 40_3<2>, and the layer 40_2<2> are stacked in this order. Note that the layer 30 and the layer 20 provided below the layer 40_1<1> are not illustrated in FIG. 23.

In FIG. 23, a distinction is made between the components provided in both the layer 40_1<1> and the layer 40_1<2> and between the components provided in both the layer 40_2<1> and the layer 40_2<2> in the same manner as FIG. 22. A distinction is made also between the components provided in both the layer 40_3<1> and the layer 40_3<2> in the same manner.

Note that three or more layers 40_1, three or more layers 40_2, and three or more layers 40_3 may be provided. For example, when a layer having the same structure as the layer 40_1<2>, a layer having the same structure as the layer 40_3<2>, and a layer having the same structure as the layer 40_2<2> are provided to be stacked between the insulating layer 285<2> and the conductive layer 220<2> and the insulating layer 287 and the wiring 61<2>, three or more layers 40_1, three or more layers 40_2, and three or more layers 40_3 can be provided.

When a plurality of layers 40 are stacked as illustrated in FIG. 22 and FIG. 23, the number of memory cells 42 provided in the semiconductor device 10 can be increased without an increase in the area of the memory cell array 41 in the plan view. Thus, the memory capacity can be increased without an increase in the size of the semiconductor device 10. Accordingly, the semiconductor device 10 can be downsized and highly integrated.

### <Materials for Semiconductor Device>

Materials that can be used for the semiconductor device are described below.

### [Substrate]

An insulator substrate, a semiconductor substrate, or a conductor substrate is used as the substrate, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate including silicon carbide, silicon germanium, gallium arsenide, indium phosphide, zinc oxide, or gallium oxide. Another example is a semiconductor substrate in which an insulator region is included in the semiconductor substrate, e.g., an SOI (Silicon On Insulator) substrate. Examples of the conductor substrate include a graphite substrate, a metal substrate, an alloy substrate, and a conductive resin substrate. Other examples include a substrate including a metal nitride and a substrate including a metal oxide. Other examples include an insulator substrate provided with a conductive layer or a semiconductor layer, a semiconductor substrate provided with a conductive layer or an insulating layer, and a conductor substrate provided with a semiconductor layer or an insulating layer. Alternatively, these substrates provided with elements may be used. Examples of the elements provided for the substrates include a capacitor, a resistor, a switching element, a light-emitting element, and a memory element.

### [Insulator]

Examples of an insulator include an oxide, a nitride, an oxynitride, a nitride oxide, a metal oxide, a metal oxynitride, and a metal nitride oxide, each of which has an insulating property.

With further miniaturization and higher integration of transistors, for example, a problem such as generation of leakage current may arise because of a thinned gate insulating layer. When a high-k material is used for the insulating layer functioning as a gate insulating layer, the voltage at the time of operation of the transistor can be reduced while the physical thickness is maintained. In addition, the equivalent oxide thickness (EOT) of the insulating layer functioning as the gate insulating layer can be reduced. In contrast, when a material with a low relative permittivity is used for an insulating layer functioning as an interlayer film, parasitic capacitance generated between wirings can be reduced. Thus, a material is preferably selected depending on the function of an insulating layer. Note that the material with a low relative permittivity is a material with high dielectric strength.

Examples of a material with a high relative permittivity (high-k material) include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of a material with a low relative permittivity include inorganic insulating materials such as silicon oxide, silicon oxynitride, and silicon nitride oxide, and resins such as polyester, polyolefin, polyamide (e.g., nylon and aramid), polyimide, polycarbonate, and acrylic. Other examples of an inorganic insulating material with a low relative permittivity include silicon oxide to which fluorine is added, silicon oxide to which carbon is added, and silicon oxide to which carbon and nitrogen are added. Another example is porous silicon oxide. These silicon oxides may contain nitrogen.

When a transistor including a metal oxide is surrounded by an insulating layer having a function of inhibiting passage of impurities and oxygen, the transistor can have stable electrical characteristics. As the insulating layer having a function of inhibiting passage of impurities and oxygen, a single insulating layer including or a stack of insulating layers each including, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum can be used. Specifically, for the insulating layer having a function of inhibiting passage of impurities and oxygen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; or a metal nitride such as aluminum nitride, silicon nitride oxide, or silicon nitride can be used.

An insulating layer that is in contact with a semiconductor layer or provided in the vicinity of the semiconductor layer, such as a gate insulating layer, preferably includes a region including excess oxygen. For example, when an insulating layer having a region including excess oxygen is in contact with a semiconductor layer or provided in the vicinity of the semiconductor layer, oxygen vacancies in the semiconductor layer can be reduced. For an insulating layer in which a region including excess oxygen is easily formed, silicon oxide, silicon oxynitride, porous silicon oxide, or the like can be used.

For an insulating layer having a barrier property against oxygen, an oxide containing one or both of aluminum and hafnium, an oxide containing hafnium and silicon (hafnium silicate), magnesium oxide, gallium oxide, silicon nitride, silicon nitride oxide, or the like can be used. Examples of the oxide containing one or both of aluminum and hafnium include aluminum oxide, hafnium oxide, and an oxide containing aluminum and hafnium (hafnium aluminate).

For an insulating layer having a barrier property against hydrogen, aluminum oxide, magnesium oxide, hafnium oxide, gallium oxide, silicon nitride, silicon nitride oxide, or the like can be used.

An insulating layer having a barrier property against oxygen and an insulating layer having a barrier property against hydrogen can each be regarded as an insulating layer having a barrier property against one or both of oxygen and hydrogen.

For an insulating layer having a function of capturing or fixing hydrogen, an oxide containing magnesium or an oxide containing one or both of aluminum and hafnium can be used. These oxides preferably have an amorphous structure. In an oxide having an amorphous structure, an oxygen atom has a dangling bond, and the oxide has a property of capturing or fixing hydrogen with the dangling bond in some cases. Note that these metal oxides preferably have an amorphous structure, but a crystal region may be partly formed.

In this specification and the like, a barrier insulating film refers to an insulating film having a barrier property. The barrier property refers to a property that does not easily allow diffusion of a target substance (also referred to as a property that does not easily allow passage of a target substance, a property with low permeability to a target substance, or a function of inhibiting diffusion of a target substance). A function of capturing or fixing (also referred to as gettering) a target substance can be rephrased as a barrier property. Note that hydrogen described as a target substance refers to, for example, at least one of a hydrogen atom, a hydrogen molecule, and a substance obtained by bonding with hydrogen, such as a water molecule or OH⁻. Unless otherwise specified, an impurity described as a target substance refers to an impurity in a channel formation region or a semiconductor layer and refers to, for example, at least one of a hydrogen atom, a hydrogen molecule, a water molecule, a nitrogen atom, a nitrogen molecule, a nitrogen oxide molecule (e.g., NO, NO, and NO₂), and a copper atom. Oxygen described as a target substance refers to, for example, at least one of an oxygen atom, an oxygen molecule, and the like. Specifically, a barrier property against oxygen refers to a property that does not easily allow diffusion of at least one of an oxygen atom, an oxygen molecule, and the like.

### [Conductor]

As a conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. As the alloy containing any of the above metal elements, a nitride of the alloy or an oxide of the alloy may be used. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. A semiconductor having high electrical conductivity, typified by polycrystalline silicon containing an impurity element such as phosphorus, or silicide such as nickel silicide may be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; and a material containing a metal element such as titanium, tantalum, or ruthenium are preferable because they are a conductive material that is not easily oxidized, a conductive material having a function of inhibiting oxygen diffusion, or a material maintaining its conductivity even after absorbing oxygen. Examples of the conductive material containing oxygen include indium oxide containing tungsten oxide, indium oxide containing titanium oxide, indium tin oxide, indium tin oxide containing titanium oxide, indium tin oxide to which silicon is added, indium zinc oxide, and indium zinc oxide containing tungsten oxide. In this specification and the like, a conductive film formed using the conductive material containing oxygen may be referred to as an oxide conductive film.

In addition, a conductive material containing tungsten, copper, or aluminum as its main component is preferable because it has high conductivity.

A stack of a plurality of conductive layers formed of the above-described materials may be used. For example, a stacked-layer structure using a combination of a material containing the above-described metal element and a conductive material containing oxygen may be employed. In addition, a stacked-layer structure using a combination of a material containing the above-described metal element and a conductive material containing nitrogen may be employed. Furthermore, a stacked-layer structure using a combination of a material containing the above-described metal element, a conductive material containing oxygen, and a conductive material containing nitrogen may be employed.

In the case where a metal oxide is used for the channel formation region of the transistor, the conductive layer functioning as the gate electrode preferably employs a stacked-layer structure using a combination of a material containing the above metal element and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductive layer functioning as the gate electrode, a conductive material containing oxygen and a metal element contained in the metal oxide where the channel is formed. A conductive material containing the above metal element and nitrogen may be used. For example, a conductive material containing nitrogen, such as titanium nitride or tantalum nitride, may be used. One or more of indium tin oxide, indium oxide containing tungsten oxide, indium zinc oxide containing tungsten oxide, indium oxide containing titanium oxide, indium tin oxide containing titanium oxide, indium zinc oxide, and indium tin oxide to which silicon is added may be used. Indium gallium zinc oxide containing nitrogen may be used. With the use of such a material, hydrogen contained in the metal oxide where the channel is formed can be trapped in some cases. Alternatively, hydrogen entering from a surrounding insulating layer or the like can be captured in some cases.

### [Metal Oxide]

A metal oxide has a lattice defect in some cases. Examples of a lattice defect include point defects such as an atomic vacancy and an exotic atom, linear defects such as transition, plane defects such as a grain boundary, and volume defects such as a cavity. Examples of a factor in generating a lattice defect include the deviation of the proportion of the number of atoms in constituent elements (excess or deficiency of constituent atoms) and an impurity.

When a metal oxide is used for a semiconductor layer of a transistor, a lattice defect in the metal oxide might cause generation, capture, or the like of a carrier. Thus, the use of a metal oxide with many lattice defects in a semiconductor layer of a transistor may cause unstable electrical characteristics of the transistor. Hence, a metal oxide used in a semiconductor layer of a transistor preferably has a small number of lattice defects.

A transistor using a metal oxide is likely to change its electrical characteristics especially in the case where oxygen vacancies (Vo) and impurities are present in a region of the metal oxide where a channel is formed, which may degrade the reliability in some cases. In some cases, hydrogen in the vicinity of an oxygen vacancy forms a defect where hydrogen enters the oxygen vacancy (hereinafter, such defect is sometimes referred to as VoH), which generates an electron serving as a carrier. Thus, when the channel formation region in the metal oxide includes oxygen vacancies, the transistor is likely to have normally-on characteristics. Therefore, oxygen vacancies and impurities are preferably reduced as much as possible in the channel formation region in the metal oxide. In other words, it is preferable that the channel formation region in the metal oxide have a reduced carrier concentration and be of an i-type (intrinsic) or be substantially of an i-type.

The kind of a lattice defect that is likely to be present in a metal oxide and the amount of lattice defects that are present there depend on the structure of the metal oxide, a method for depositing the metal oxide, or the like.

The structure of a metal oxide is classified into a single crystal structure and other structures (non-single-crystal structures). Examples of non-single-crystal structures include a CAAC structure, a polycrystalline structure, an nc structure, an amorphous-like (a-like) structure, and an amorphous structure. The a-like structure has a structure between the nc structure and the amorphous structure. Note that the classification of crystal structures will be described later.

A metal oxide having the a-like structure and a metal oxide having the amorphous structure each include a void or a low-density region. That is, the metal oxide having the a-like structure and the metal oxide having the amorphous structure have low crystallinity as compared with a metal oxide having the nc structure and a metal oxide having the CAAC structure. Moreover, the metal oxide having the a-like structure has a higher hydrogen concentration in the metal oxide than the metal oxide having the nc structure and the metal oxide having the CAAC structure. Thus, a lattice defect is easily formed in the metal oxide having the a-like structure and the metal oxide having the amorphous structure.

Accordingly, a metal oxide with high crystallinity is preferably used in a semiconductor layer of a transistor. For example, it is preferable to use a metal oxide having the CAAC structure or a metal oxide having the single crystal structure. The use of such a metal oxide for a transistor enables the transistor to have favorable electrical characteristics. In addition, the transistor can have high reliability.

For the channel formation region of a transistor, a metal oxide that increases the on-state current of the transistor is preferably used. To increase the on-state current of the transistor, the mobility of the metal oxide used for the transistor is increased. To increase the mobility of the metal oxide, the transfer of carriers (electrons in the case of an n-channel transistor) needs to be facilitated or scattering factors that affect the carrier transfer need to be reduced. The carriers flow from the source to the drain through the channel formation region. Hence, the on-state current of the transistor can be increased by providing a channel formation region through which carriers can easily flow in the channel length direction.

Here, it is preferable to use a metal oxide with high crystallinity for a metal oxide including a channel formation region. The crystal preferably has a crystal structure in which a plurality of layers (e.g., a first layer, a second layer, and a third layer) are stacked. That is, the crystal has a layered crystal structure (also referred to as a layered crystal or a layered structure). At this time, the direction of the c-axis of the crystal is the direction in which the plurality of layers are stacked. Examples of a metal oxide including the crystal include a single crystal oxide semiconductor and a CAAC-OS.

The c-axis of the above crystal is preferably aligned in the normal direction with respect to the surface over which the metal oxide is formed or the film surface of the metal oxide. This enables the plurality of layers to be provided parallel or substantially parallel to the surface over which the metal oxide is formed or the film surface of the metal oxide. In other words, the plurality of layers extend in the channel length direction.

The above layered crystal structure including three layers is as follows, for example. The first layer has a coordination geometry of atoms that has an octahedral structure of oxygen in which a metal included in the first layer is positioned at the center. The second layer has a coordination geometry of atoms that has a trigonal bipyramidal or tetrahedral structure of oxygen in which a metal included in the second layer is positioned at the center. The third layer has a coordination geometry of atoms that has a trigonal bipyramidal or tetrahedral structure of oxygen in which a metal included in the third layer is positioned at the center.

Examples of the crystal structure of the above crystal include a YbFe₂O₄ type structure, a Yb₂Fe₃O₇ type structure, and their deformed structures.

Preferably, each of the first layer to the third layer is composed of one metal element or a plurality of metal elements with the same valence and oxygen. The valences of the one or plurality of metal elements included in the first layer are preferably equal to the valences of the one or plurality of metal elements included in the second layer. The first layer and the second layer may include the same metal element. The valences of the one or plurality of metal elements included in the first layer are preferably different from the valences of the one or plurality of metal elements included in the third layer.

The above structure can increase the crystallinity of the metal oxide, which leads to an increase in the mobility of the metal oxide. Thus, the use of the metal oxide for the channel formation region of the transistor increases the on-state current of the transistor, leading to an improvement in the electrical characteristics of the transistor.

Examples of the metal oxide of one embodiment of the present invention include indium oxide, gallium oxide, and zinc oxide. The metal oxide of one embodiment of the present invention preferably contains at least indium (In) or zinc (Zn). The metal oxide preferably contains two or three selected from indium, an element M, and zinc. Note that the element M is a metal element or a metalloid element that has a high binding energy with oxygen, such as a metal element or a metalloid element whose binding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M included in the metal oxide is preferably any one or more of the above elements, further preferably one or more selected from aluminum, gallium, tin, and yttrium, still further preferably gallium. When the element M included in the metal oxide is gallium, the metal oxide of one embodiment of the present invention preferably includes one or more selected from indium, gallium, and zinc. In this specification and the like, a metal element and a metalloid element may be collectively referred to as a “metal element”, and a “metal element” in this specification and the like may include a metalloid element.

As the metal oxide of one embodiment of the present invention, indium zinc oxide (In—Zn oxide), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (In—Ga—Sn oxide, also referred to as IGTO), gallium zinc oxide (Ga—Zn oxide, also referred to as GZO), aluminum zinc oxide (Al—Zn oxide, also referred to as AZO), indium aluminum zinc oxide (In—Al—Zn oxide, also referred to as IAZO), indium tin zinc oxide (In—Sn—Zn oxide), indium titanium zinc oxide (In—Ti—Zn oxide), indium gallium zinc oxide (In—Ga—Zn oxide, also referred to as IGZO), indium gallium tin zinc oxide (In—Ga—Sn—Zn oxide, also referred to as IGZTO), indium gallium aluminum zinc oxide (In—Ga—Al—Zn oxide, also referred to as IGAZO or IAGZO), or the like can be used, for example. Alternatively, indium tin oxide containing silicon, gallium tin oxide (Ga—Sn oxide), aluminum tin oxide (Al—Sn oxide), or the like can be used. Alternatively, the above-described oxide having an amorphous structure can be used. For example, indium oxide having an amorphous structure, indium tin oxide having an amorphous structure, or the like can be used.

When the proportion of the number of indium atoms in the total number of atoms of all the metal elements included in the metal oxide is increased, the field-effect mobility of the transistor can be increased.

Note that the metal oxide may contain, instead of indium, one or more kinds of metal elements with large period numbers. Alternatively, the metal oxide may contain, in addition to indium, one or more kinds of metal elements with large period numbers. The larger the overlap between orbits of metal elements is, the more likely it is that the metal oxide will have high carrier conductivity. Thus, a transistor containing a metal element with a large period number can have high field-effect mobility in some cases. Examples of the metal element with a large period number include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements included in the metal oxide, the metal oxide has high crystallinity, so that diffusion of impurities in the metal oxide can be inhibited. Consequently, a change in electrical characteristics of the transistor can be inhibited, and the reliability of the transistor can be increased.

By increasing the proportion of the number of element M atoms in the total number of atoms of all the metal elements included in the metal oxide, oxygen vacancies can be inhibited from being formed in the metal oxide. Accordingly, generation of carriers due to oxygen vacancies is inhibited, which makes the off-state current of the transistor low. Furthermore, a change in electrical characteristics of the transistor can be inhibited, and the reliability of the transistor can be increased.

By increasing the proportion of the number of In atoms in the total number of atoms of all the metal elements included in the metal oxide, a high on-state current and excellent frequency characteristics of the transistor can be achieved.

In the description of this embodiment, In—Ga—Zn oxide is sometimes taken as an example of the metal oxide.

For the formation of a metal oxide having the layered crystal structure, atomic layers are preferably deposited one by one. Since an ALD method is employed as the deposition method of the metal oxide in one embodiment of the present invention, a metal oxide having the layered crystal structure is easily formed.

Examples of an ALD method include a thermal ALD method, in which a precursor and a reactant react with each other only by a thermal energy, and a plasma ALD (PEALD: Plasma Enhanced ALD) method, in which a reactant excited by plasma is used.

An ALD method, which enables atomic layers to be deposited one by one, has advantages such as formation of an extremely thin film, film formation on a component with a high aspect ratio, formation of a film with a small number of defects such as pinholes, film formation with excellent coverage, and low-temperature film formation. The use of plasma in a PEALD method is sometimes preferable because it enables deposition at a lower temperature. Note that a precursor used in an ALD method sometimes contains an element such as carbon or chlorine. Thus, in some cases, a film provided by an ALD method includes a larger amount of an element such as carbon or chlorine than a film provided by another formation method. Note that these elements can be quantified by XPS or SIMS. The deposition method of the metal oxide of one embodiment of the present invention, which employs an ALD method and one or both of a deposition condition with a high substrate temperature and impurity removal treatment, can sometimes form a film with smaller amounts of carbon and chlorine than a method employing an ALD method without the deposition condition with a high substrate temperature or the impurity removal treatment.

Unlike a formation method in which particles ejected from a target or the like are deposited, an ALD method is a formation method in which a film is formed by reaction at a surface of an object. Thus, an ALD method is a formation method that enables favorable step coverage almost regardless of the shape of an object. In particular, an ALD method enables excellent step coverage and excellent thickness uniformity and thus is suitable for covering a surface of an opening portion with a high aspect ratio, for example. On the other hand, an ALD method has a relatively low deposition rate, and thus is preferably used in combination with another formation method with a high deposition, such as a sputtering method or a CVD method, in some cases. A method in which a sputtering method is used to deposit a first metal oxide and an ALD method is used to deposit a second metal oxide over the first metal oxide is given as an example. For example, in the case where the first metal oxide has a crystal part, crystal growth occurs in the second metal oxide with the use of the crystal part as a nucleus.

When an ALD method is employed, the composition of a film to be formed can be controlled with the amount of introduced source gases. For example, a film with a certain composition can be formed by an ALD method by adjusting at least one of the amount of introduced source gases, the number of times of introduction (also referred to as the number of pulses), the time required for one pulse (also referred to as the pulse time), and the like. Moreover, for example, when the source gas is changed during the deposition by an ALD method, a film having a continuously changed composition can be formed. In the case where a film is formed while the source gas is changed, the time taken for transfer and pressure adjustment is saved, and thus, the time taken for the deposition can be shortened as compared to the case where a film is formed using a plurality of deposition chambers. Thus, the productivity of the semiconductor device can be increased in some cases.

### [[Transistor Including Metal Oxide]]

Next, the case where a metal oxide (oxide semiconductor) is used for a transistor will be described.

When the metal oxide (oxide semiconductor) of one embodiment of the present invention is used for a transistor, a transistor with high field-effect mobility can be achieved. In addition, a transistor with high reliability can be achieved. Furthermore, a miniaturized or highly integrated transistor can be achieved. For example, a transistor with a channel length greater than or equal to 2 nm and less than or equal to 30 nm can be fabricated.

An oxide semiconductor having a low carrier concentration is preferably used for a channel formation region of a transistor. For example, the carrier concentration in the channel formation region of the oxide semiconductor is lower than or equal to 1×10¹⁸ cm⁻³, preferably lower than or equal to 1×10¹⁷ cm⁻³, further preferably lower than or equal to 1×10¹⁵ cm⁻³, further preferably lower than or equal to 1×10¹³ cm⁻³, still further preferably lower than or equal to 1×10¹¹ cm⁻³, yet further preferably lower than 1×10¹⁰ cm⁻³, and higher than or equal to 1×10⁻⁹ cm⁻³. In order to reduce the carrier concentration in the oxide semiconductor, the impurity concentration in the oxide semiconductor is reduced so that the density of defect states is reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Charge trapped by the trap states in the oxide semiconductor takes a long time to disappear and might behave like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of impurities include hydrogen, carbon, and nitrogen. Note that an impurity in an oxide semiconductor refers to, for example, an element other than the main components of the oxide semiconductor. For example, an element with a concentration lower than 0.1 atomic % can be regarded as an impurity.

The band gap of the oxide semiconductor is preferably larger than the band gap of silicon (typically 1.1 eV), further preferably larger than or equal to 2 eV, still further preferably larger than or equal to 2.5 eV, yet further preferably larger than or equal to 3.0 eV. With use of an oxide semiconductor having a larger band gap than silicon, the off-state current (also referred to as Ioff) of the transistor can be reduced.

In a Si transistor, a short-channel effect (also referred to as SCE) appears as miniaturization of the transistor proceeds. This hinders miniaturization of a Si transistor. One factor that causes the short-channel effect is a small band gap of silicon. By contrast, an OS transistor includes an oxide semiconductor that is a semiconductor material having a large band gap, and thus can suppress the short-channel effect. In other words, a short-channel effect does not appear or hardly appears in an OS transistor.

Note that the short-channel effect refers to degradation of electrical characteristics which becomes obvious along with miniaturization of a transistor (a decrease in channel length). Specific examples of the short-channel effect include a decrease in threshold voltage, an increase in a subthreshold swing value (sometimes referred to as an S value), and an increase in leakage current. Here, the S value means the amount of change in gate voltage in the subthreshold region by which the drain current is changed by one order of magnitude at a constant drain voltage.

The characteristic length is widely used as an indicator of resistance to the short-channel effect. The characteristic length is an indicator of curving of potential in a channel formation region. When the characteristic length is shorter, the potential rises more sharply, which means that the resistance to the short-channel effect is high.

The OS transistor is an accumulation-type transistor, and the Si transistor is an inversion-type transistor. Accordingly, the OS transistor has a shorter characteristic length between a source region and a channel formation region and a shorter characteristic length between a drain region and the channel formation region than the Si transistor. Thus, the OS transistor has higher resistance to the short-channel effect than the Si transistor. That is, in the case where a transistor with a short channel length is to be manufactured, the OS transistor is more suitable than the Si transistor.

Even in the case where the carrier concentration of the oxide semiconductor is reduced until the channel formation region becomes an i-type or substantially i-type region, the conduction band minimum of the channel formation region in a short-channel transistor decreases because of the Conduction-Band-Lowering (CBL) effect; thus, the energy difference between the conduction band minimum of the source region or the drain region and that of the channel formation region might decrease to greater than or equal to 0.1 eV and less than or equal to 0.2 eV. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n⁻-type region and the source region and the drain region become n⁺-type regions.

The OS transistor having the above structure enables a semiconductor device to have favorable electrical characteristics even when the semiconductor device is miniaturized or highly integrated. For example, favorable electrical characteristics can be obtained even when the OS transistor has a channel length or a gate length less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. In contrast, it is sometimes difficult for the Si transistor to have a gate length less than or equal to 20 nm or less than or equal to 15 nm due to appearance of the short-channel effect. Therefore, the OS transistor can be suitably used as a transistor having a short channel length as compared with the Si transistor. Note that the gate length refers to the length of a gate electrode in a direction in which carriers move inside a channel formation region during operation of the transistor.

Miniaturization of the OS transistor can improve the high frequency characteristics of the transistor. Specifically, the cutoff frequency of the transistor can be increased. When the gate length of the OS transistor falls within any of the above ranges, the cutoff frequency of the transistor can be greater than or equal to 50 GHz, preferably greater than or equal to 100 GHz, further preferably greater than or equal to 150 GHz in a room temperature environment, for example.

The above comparison of the OS transistor with the Si transistor demonstrates that the OS transistor is advantageous over the Si transistor in that the off-state current is low and a short-channel transistor can be formed.

### [Impurity in Metal Oxide]

Here, the influence of each impurity in the metal oxide (oxide semiconductor) will be described.

When silicon or carbon, which is one of Group 14 elements, is contained in the oxide semiconductor, defect states are formed in the oxide semiconductor. Thus, the carbon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, further preferably lower than or equal to 1×10¹⁹ atoms/cm³, still further preferably lower than or equal to 3×10¹⁸ atoms/cm³, yet still further preferably lower than or equal to 1×10¹⁸ atoms/cm³. The silicon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, further preferably lower than or equal to 1×10¹⁹ atoms/cm³, still further preferably lower than or equal to 3×10¹⁸ atoms/cm³, yet still further preferably lower than or equal to 1×10¹⁸ atoms/cm³.

When the oxide semiconductor contains nitrogen, the oxide semiconductor easily becomes n-type by generation of electrons serving as carriers and an increase in carrier concentration. As a result, a transistor using an oxide semiconductor that contains nitrogen as a semiconductor is likely to have normally-on characteristics. When the oxide semiconductor contains nitrogen, trap states are sometimes formed. This might make the electrical characteristics of the transistor unstable. Therefore, the nitrogen concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 1×10¹⁹ atoms/cm³, still further preferably lower than or equal to 5×10¹⁸ atoms/cm³, yet further preferably lower than or equal to 1×10¹⁸ atoms/cm³, yet still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor including an oxide semiconductor containing hydrogen is likely to have normally-on characteristics. For this reason, hydrogen in the channel formation region of the oxide semiconductor is preferably reduced as much as possible. Specifically, the hydrogen concentration in the channel formation region of the oxide semiconductor, which is measured by SIMS, is lower than 1×10²⁰ atoms/cm³, preferably lower than 5×10¹⁹ atoms/cm³, further preferably lower than 1×10¹⁹ atoms/cm³, still further preferably lower than 5×10¹⁸ atoms/cm³, yet still further preferably lower than 1×10¹⁸ atoms/cm³.

When the oxide semiconductor contains an alkali metal or an alkaline earth metal, defect states are formed and carriers are generated in some cases. Thus, a transistor including an oxide semiconductor that contains an alkali metal or an alkaline earth metal is likely to have normally-on characteristics. Thus, the concentration of an alkali metal or an alkaline earth metal in the channel formation region of the oxide semiconductor, which is measured by SIMS, is lower than or equal to 1×10¹⁸ atoms/cm³, preferably lower than or equal to 2×10¹⁶ atoms/cm³.

When an oxide semiconductor with sufficiently reduced impurities is used for a channel formation region of a transistor, the transistor can have stable electrical characteristics.

### [Other Semiconductor Materials]

The semiconductor layer 270 can be rephrased as a semiconductor layer including the channel formation region of the transistor. A semiconductor material that can be used for the semiconductor layer is not limited to the above metal oxides. The semiconductor material that has a band gap (a semiconductor material that is not a zero-gap semiconductor) may be used for the semiconductor layer. For example, a single-element semiconductor, a compound semiconductor, or a layered substance (also referred to as an atomic layer substance, a two-dimensional material, or the like) is preferably used as a semiconductor material.

Here, in this specification and the like, the layered substance generally refers to a group of materials having a layered crystal structure. In the layered crystal structure, layers formed by covalent bonding or ionic bonding are stacked with bonding such as the Van der Waals force, which is weaker than covalent bonding or ionic bonding. The layered substance has high electrical conductivity in a unit layer, that is, high two-dimensional electrical conductivity. When a material that functions as a semiconductor and has high two-dimensional electrical conductivity is used for a channel formation region, a transistor having a high on-state current can be provided.

Examples of the single-element semiconductor that can be used as the semiconductor material include silicon and germanium. Examples of silicon that can be used for the semiconductor layer include single crystal silicon, polycrystalline silicon, microcrystalline silicon, and amorphous silicon. An example of polycrystalline silicon is low-temperature polysilicon (LTPS).

Examples of the compound semiconductor that can be used as the semiconductor material include silicon carbide, silicon germanium, gallium arsenide, indium phosphide, boron nitride, and boron arsenide. Boron nitride that can be used for the semiconductor layer preferably includes an amorphous structure. Boron arsenide that can be used for the semiconductor layer preferably includes a crystal with a cubic structure.

Examples of the layered substance include graphene, silicene, boron carbonitride, and chalcogenide. Boron carbonitride serving as the layered substance contains carbon, nitrogen, and boron atoms arranged in a hexagonal lattice structure on a plane. Chalcogenide is a compound containing chalcogen. Chalcogen is a general term for elements belonging to Group 16 and includes oxygen, sulfur, selenium, tellurium, polonium, and livermorium. Examples of chalcogenide include transition metal chalcogenide and chalcogenide of Group 13 elements.

For the semiconductor layer, transition metal chalcogenide functioning as a semiconductor is preferably used, for example. Specific examples of the transition metal chalcogenide that can be used for the semiconductor layer include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂). The use of the transition metal chalcogenide for the semiconductor layer enables a semiconductor device with a high on-state current to be provided.

The configurations, structures, methods, and the like described in this embodiment can be used in combination as appropriate with the configurations, structures, methods, and the like described in the other embodiments.

### Embodiment 2

In this embodiment, structure examples of a semiconductor device that are different from those described in Embodiment 1 will be described with reference to drawings. Specifically, structure examples of a memory device that is one embodiment of the semiconductor device will be described with reference to drawings.

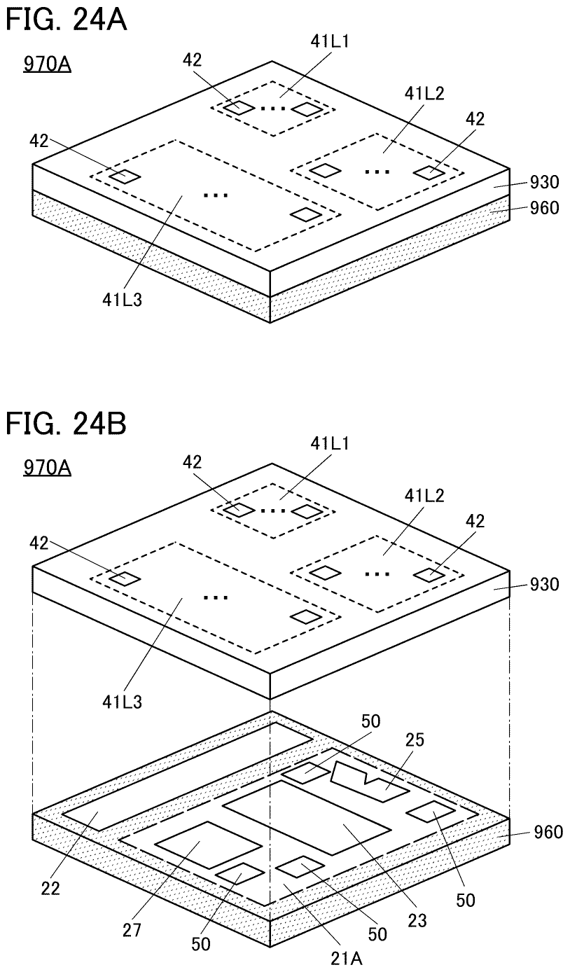

FIG. 24A and FIG. 24B are perspective views illustrating a structure example of a semiconductor device 970A. The semiconductor device 970A includes a layer 960 and a layer 930 over the layer 960.

A CPU 21A and the driver circuit 22 are provided in the layer 960. The CPU 21A includes the control circuit 23, the arithmetic circuit 25, the memory controller 27, the register circuit 50, and the like that are illustrated in FIG. 1. Note that the cache memory 26 illustrated in FIG. 1 is not provided in the CPU 21A. The layer 960 corresponds to the layer 20 and the layer 30 described in Embodiment 1.

In the layer 930, a memory cell array 41L1, a memory cell array 41L2, and a memory cell array 41L3 are provided as the memory cell arrays 41. The memory cells 42 are arranged in a matrix in each of the memory cell array 41L1, the memory cell array 41L2, and the memory cell array 41L3. The layer 930 corresponds to the layer 40 described in Embodiment 1. Note that at least one of the memory cell array 41L1, the memory cell array 41L2, and the memory cell array 41L3 may be split into a plurality of memory cell arrays.

The CPU 21A and each of the memory cell arrays 41 have an overlap region. For easy understanding of the structure of the semiconductor device 970A, the layer 960 and the layer 930 are separately illustrated in FIG. 24B.

Overlapping the layer 930 including the memory cell arrays 41 and the CPU 21A can shorten the connection distance therebetween. Accordingly, the communication speed therebetween can be increased. Moreover, since the connection distance is short, power consumption can be reduced.

As a method for stacking the layer 930 including the memory cell arrays 41 and the layer 960 including the CPU 21A, it is possible to employ a method in which the layer 930 is stacked directly on the layer 960 (which is also referred to as monolithic stacking); or a method in which the layer 960 and the layer 930 are formed over different substrates, the two substrates are bonded to each other, and the layer 960 and the layer 930 are electrically connected to each other with a through via or by a technique for bonding conductive films (e.g., Cu—Cu bonding). The former method does not require consideration of misalignment in bonding; thus, not only the chip size but also the manufacturing cost can be reduced.

Here, the memory cell array 41L1, the memory cell array 41L2, and the memory cell array 41L3 can each be used as a cache memory. In this case, for example, the memory cell array 41L1 can be used as an L1 cache memory (also referred to as a level 1 cache memory), the memory cell array 41L2 can be used as an L2 cache memory (also referred to as a level 2 cache memory), and the memory cell array 41L3 can be used as an L3 cache memory (also referred to as a level 3 cache memory). Among the three memory cell arrays 41, the memory cell array 41L3 has the largest capacity and the lowest access frequency. The memory cell array 41L1 has the smallest capacity and the highest access frequency.

Note that the cache memory 26 illustrated in FIG. 1 may be provided in the CPU 21A. In that case, the cache memory 26 can be used as an L1 cache memory, for example. In this case, each of the memory cell arrays 41 provided in the layer 930 can be used as a lower-level cache memory or a main memory. The main memory has larger capacity and lower access frequency than the cache memory.

Note that although the case where three memory cell arrays 41 functioning as cache memories are provided is described here, the number of such memory cell arrays 41 may be one or two or may be four or more.

Whether the memory cell array 41 functions as a cache memory or a main memory is determined by the memory controller 27. The memory controller 27 enables some of the plurality of memory cells 42 included in the semiconductor device 970A to function as RAM in accordance with a signal supplied from the CPU 21A.

In the semiconductor device 970A, some of the plurality of memory cells 42 can function as the cache memory and the others can function as the main memory. That is, the semiconductor device 970A can have both the function of the cache memory and the function of the main memory. The semiconductor device 970A can function as a universal memory, for example.

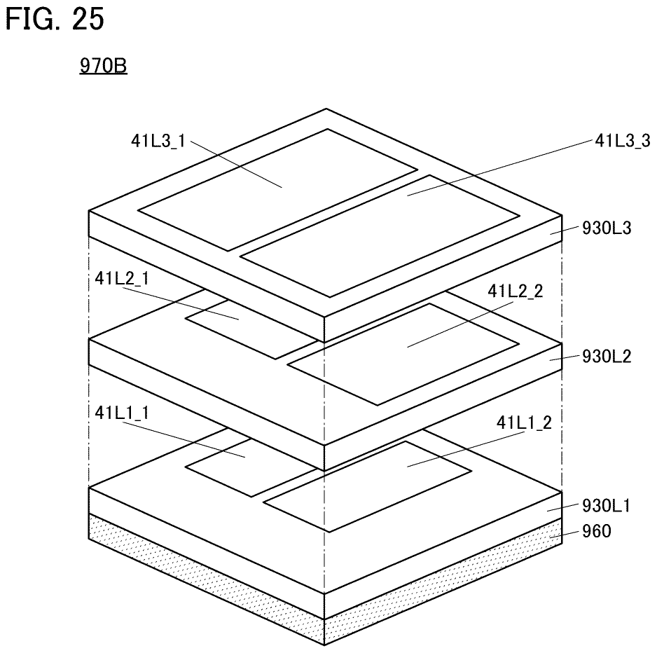

Alternatively, a plurality of memory cell arrays 41 may be stacked. FIG. 25 is a perspective view of a semiconductor device 970B.

The semiconductor device 970B includes a layer 930L1 over the layer 960, a layer 930L2 over the layer 930L1, and a layer 930L3 over the layer 930L2. In the layer 930L1, a memory cell array 41L1_1 and a memory cell array 41L1_2 are provided as the memory cell array 41L1. In the layer 930L2, a memory cell array 41L2_1 and a memory cell array 41L2_2 are provided as the memory cell array 41L2. In the layer 930L3, a memory cell array 41L3_1 and a memory cell array 41L3_2 are provided as the memory cell array 41L3. That is, FIG. 25 illustrates an example in which the memory cell array 41L1, the memory cell array 41L2, and the memory cell array 41L3 are each split into two memory cell arrays. Note that at least one of the memory cell array 41L1, the memory cell array 41L2, and the memory cell array 41L3 may be split into three or more memory cell arrays.

When the layer 930L1, the layer 930L2, and the layer 930L3 are provided to be stacked in this order over the layer 960, the memory cell array 41L1, which is physically closest to the CPU 21A, can be used as a higher-level cache memory. In addition, the memory cell array 41L3, which is the farthest from the CPU 21A, can be used as a lower-level cache memory or a main memory. When the memory cell array 41L1, the memory cell array 41L2, and the memory cell array 41L3 are stacked in this manner, the capacity of each memory cell array 41 can be increased. Thus, the semiconductor device 970B can have high throughput.

The configurations, structures, methods, and the like described in this embodiment can be used in combination as appropriate with the configurations, structures, methods, and the like described in the other embodiments.

### Embodiment 3

This embodiment will describe an electronic component, an electronic appliance, a large computer, space equipment, and a data center (also referred to as a DC) that can use the semiconductor device described in the above embodiment. An electronic component, an electronic appliance, a large computer, space equipment, and a data center each using the semiconductor device of one embodiment of the present invention are effective in achieving high performance, e.g., reducing power consumption.

### [Electronic Component]

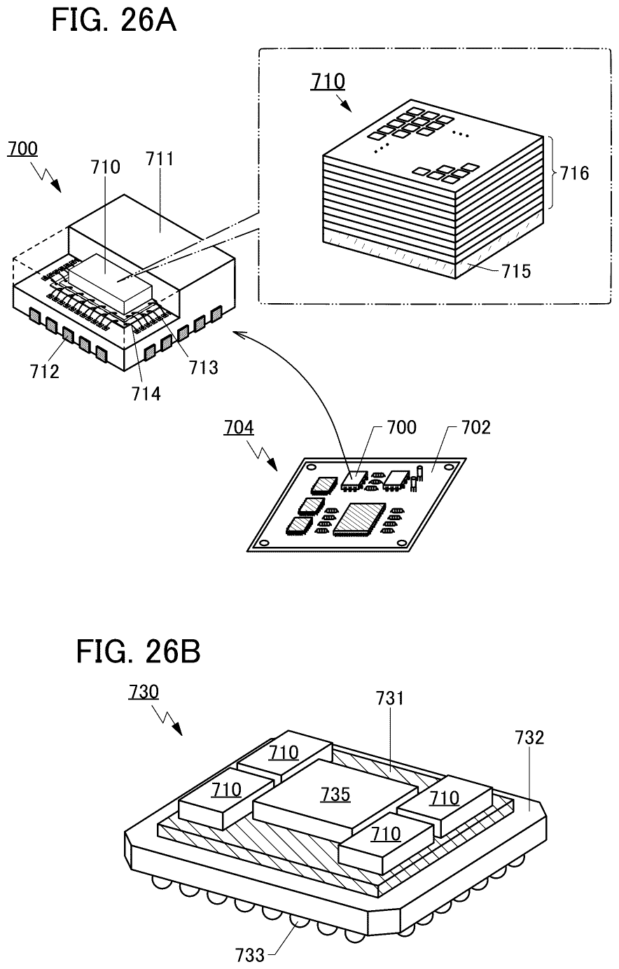

FIG. 26A is a perspective view of a substrate (a circuit board 704) on which an electronic component 700 is mounted. The electronic component 700 illustrated in FIG. 26A includes a semiconductor device 710 in a mold 711. FIG. 26A omits illustrations of some parts to show the inside of the electronic component 700. The electronic component 700 includes a land 712 outside the mold 711. The land 712 is electrically connected to an electrode pad 713, and the electrode pad 713 is electrically connected to the semiconductor device 710 via a wire 714. The electronic component 700 is mounted on a printed circuit board 702, for example. A plurality of such electronic components are combined and electrically connected on the printed circuit board 702, so that the mounting board 704 is completed.

The semiconductor device 710 includes a driver circuit layer 715 and a memory layer 716. Note that the memory layer 716 has a structure where a plurality of memory cell arrays are stacked. A stacked-layer structure of the driver circuit layer 715 and the memory layer 716 can be a monolithic stacking structure. In the monolithic stacking structure, layers can be connected without using a through electrode technique such as a TSV (Through Silicon Via) and a bonding technique such as Cu—Cu direct bonding. The monolithic stacking structure of the driver circuit layer 715 and the memory layer 716 enables, for example, what is called an on-chip memory structure where a memory is directly formed on a processor. The on-chip memory structure allows an interface portion between the processor and the memory to operate at high speed.

In addition, with the on-chip memory structure, the size of, for example, a connection wiring can be made smaller than that when the technique using through electrodes such as TSVs is employed; thus, the number of connection pins can be increased. The increase in the number of connection pins enables parallel operation, which can increase the bandwidth of the memory (also referred to as memory bandwidth).

It is preferable that the plurality of memory cell arrays included in the memory layer 716 be formed using OS transistors and be monolithically stacked. Monolithically stacking the plurality of memory cell arrays can increase one or both of the bandwidth of the memory and the access latency of the memory. Note that the bandwidth refers to the data transfer amount per unit time, and the access latency refers to time between data access and start of data transmission. Note that in the case where Si transistors are used for the memory layer 716, the monolithic stacking structure is difficult to form as compared with the case where OS transistors are used for the memory layer 716. Thus, in the monolithic stacking structure, an OS transistor can be regarded as being superior in structure to a Si transistor.

The semiconductor device 710 may be called a die. In this specification and the like, a die refers to each of chip pieces obtained by dividing a circuit pattern formed on a disc-like substrate (also referred to as a wafer), for example, into dice in the manufacturing process of a semiconductor chip. Note that examples of semiconductor materials that can be used for the die include silicon (Si), silicon carbide (SiC), and gallium nitride (GaN). For example, a die obtained from a silicon substrate (also referred to as a silicon wafer) is referred to as a silicon die in some cases.

FIG. 26B is a perspective view of an electronic component 730. The electronic component 730 is an example of a SiP (System in Package) or an MCM (Multi Chip Module). In the electronic component 730, an interposer 731 is provided over a package substrate 732 (printed circuit board), and a semiconductor device 735 and a plurality of the semiconductor devices 710 are provided over the interposer 731.

The electronic component 730 using the semiconductor devices 710 as high bandwidth memories (HBM) is illustrated as an example. The semiconductor device 735 can be used for an integrated circuit such as a CPU (Central Processing Unit), a GPU (Graphics Processing Unit), or an FPGA (Field Programmable Gate Array).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. The interposer 731 also has a function of electrically connecting an integrated circuit provided on the interposer 731 to an electrode provided on the package substrate 732. Accordingly, the interposer is referred to as a “redistribution substrate” or an “intermediate substrate” in some cases. In some cases, a through electrode is provided in the interposer 731 and used for electrically connecting the integrated circuit and the package substrate 732. In the case of using a silicon interposer, a TSV can also be used as the through electrode.

In an HBM, many wirings need to be connected to achieve a wide memory bandwidth. Therefore, an interposer on which an HBM is mounted requires minute and densely formed wirings. For this reason, a silicon interposer is preferably used as the interposer on which an HBM is mounted.

In a SiP or an MCM that includes a silicon interposer, a decrease in reliability due to a difference in the coefficient of expansion between an integrated circuit and the interposer is less likely to occur. Furthermore, a surface of a silicon interposer has high planarity; thus, poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected to each other using a silicon interposer and a TSV, a space for the width of the terminal pitches and the like is needed. Accordingly, in the case where the size of the electronic component 730 is to be reduced, the width of the terminal pitch becomes an issue, which sometimes makes it difficult to provide a large number of wirings for achieving a wide memory bandwidth. For this reason, the above-described monolithic stacking structure using OS transistors is suitable. A composite structure where memory cell arrays stacked using a TSV and monolithically stacked memory cell arrays are combined may be employed.

A heat sink (a radiator plate) may be provided to overlap the electronic component 730. In the case where a heat sink is provided, integrated circuits provided on the interposer 731 preferably have the same height. For example, in the electronic component 730 described in this embodiment, the semiconductor devices 710 and the semiconductor device 735 preferably have the same height.

Electrodes 733 may be provided on a bottom part of the package substrate 732 to mount the electronic component 730 on another substrate. FIG. 26B illustrates an example in which the electrodes 733 are formed of solder balls. When the solder balls are provided in a matrix on the bottom part of the package substrate 732, BGA (Ball Grid Array) mounting can be achieved. Alternatively, the electrodes 733 may be formed of conductive pins. When the conductive pins are provided in a matrix on the bottom part of the package substrate 732, PGA (Pin Grid Array) mounting can be achieved.

The electronic component 730 can be mounted on another substrate by a variety of mounting methods not limited to BGA and PGA. Examples of mounting methods include SPGA (Staggered Pin Grid Array), LGA (Land Grid Array), QFP (Quad Flat Package), QFJ (Quad Flat J-leaded package), and QFN (Quad Flat Non-leaded package).

### [Electronic Appliance]

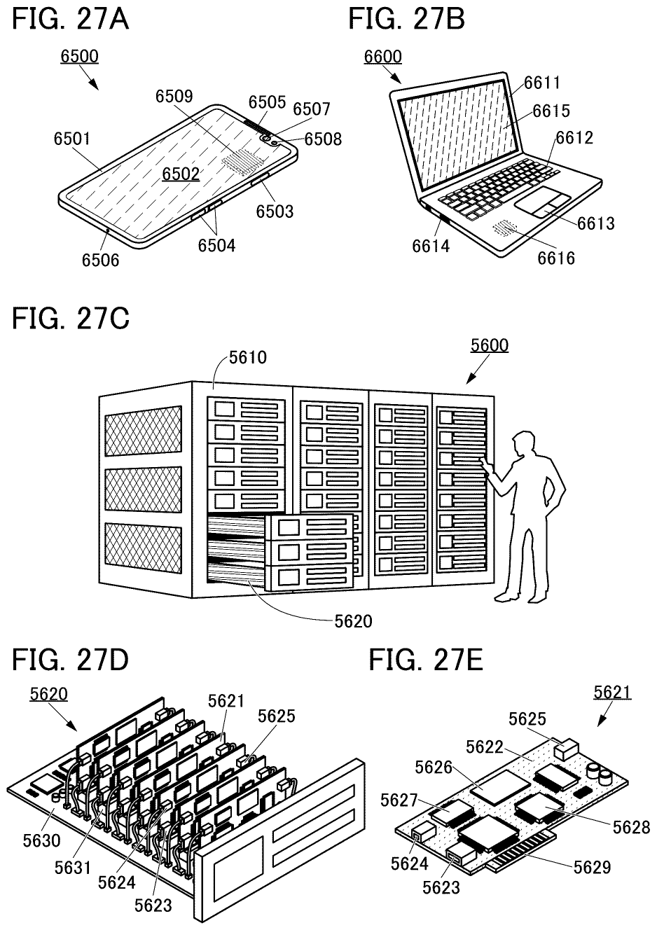

FIG. 27A is a perspective view of an electronic appliance 6500. The electronic appliance 6500 illustrated in FIG. 27A is a portable information terminal that can be used as a smartphone. The electronic appliance 6500 includes a housing 6501, a display portion 6502, a power button 6503, buttons 6504, a speaker 6505, a microphone 6506, a camera 6507, a light source 6508, and a control device 6509. One or more selected from a CPU, a GPU, and a memory device are provided as the control device 6509, for example. The semiconductor device of one embodiment of the present invention can be used for the control device 6509, for example. Thus, the size of the electronic appliance 6500 can be reduced.

An electronic appliance 6600 illustrated in FIG. 27B is an information terminal that can be used as a laptop personal computer. The electronic appliance 6600 includes a housing 6611, a keyboard 6612, a pointing device 6613, an external connection port 6614, a display portion 6615, and a control device 6616. One or more selected from a CPU, a GPU, and a memory device are provided as the control device 6616, for example. The semiconductor device of one embodiment of the present invention can be used for the control device 6616, for example. Thus, the size of the electronic appliance 6600 can be reduced.

### [Large Computer]

FIG. 27C is a perspective view of a large computer 5600. In the large computer 5600 illustrated in FIG. 27C, a plurality of rack mount computers 5620 are stored in a rack 5610. Note that the large computer 5600 may also be referred to as a supercomputer.

The computer 5620 can have a structure in a perspective view of FIG. 27D, for example. In FIG. 27D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 27E is an example of a processing board provided with a CPU, a GPU, a memory device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. Note that FIG. 27E also illustrates semiconductor devices other than the semiconductor device 5626, the semiconductor device 5627, and the semiconductor device 5628; the following description of the semiconductor device 5626, the semiconductor device 5627, and the semiconductor device 5628 is referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, or the like to the PC card 5621. As another example, they can serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device. As the semiconductor device 5628, the electronic component 700 can be used, for example.

The large computer 5600 can also function as a parallel computer. When the large computer 5600 is used as a parallel computer, large-scale computation necessary for artificial intelligence learning and inference can be performed, for example.

### [Space Equipment]

The semiconductor device of one embodiment of the present invention can be suitably used for space equipment (e.g., equipment having a function of processing and storing information).

The semiconductor device of one embodiment of the present invention can include an OS transistor. A change in electrical characteristics of the OS transistor due to exposure to radiation is small. That is, the OS transistor is highly resistant to radiation and thus can be suitably used in an environment where radiation can enter. For example, the OS transistor can be suitably used in the case of being used in outer space.

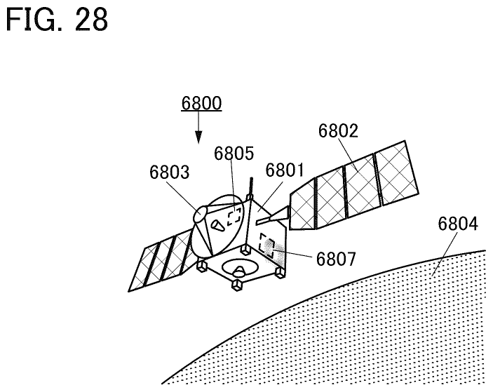

FIG. 28 illustrates an artificial satellite 6800 as an example of space equipment. The artificial satellite 6800 includes a body 6801, solar panels 6802, an antenna 6803, a secondary battery 6805, and a control device 6807. In FIG. 28, a planet 6804 in outer space is illustrated as an example. Note that outer space refers to, for example, space at an altitude greater than or equal to 100 km, and outer space in this specification may also include thermosphere, mesosphere, and stratosphere.

Although not illustrated in FIG. 28, the secondary battery 6805 may be provided with a battery management system (also referred to as a BMS) or a battery control circuit. An OS transistor is suitably used in the battery management system or the battery control circuit because low power consumption and high reliability even in outer space are achieved.

The amount of radiation in outer space is 100 or more times that on the ground. Note that examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for the operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, electric power required for the operation of the artificial satellite 6800 might not be generated. In order to operate the artificial satellite 6800 even in the situation where the amount of generated electric power is small, the artificial satellite 6800 is preferably provided with the secondary battery 6805. Note that the solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the semiconductor device of one embodiment of the present invention is suitably used for the control device 6807. A change in electrical characteristics due to exposure to radiation is smaller in an OS transistor than in a Si transistor. That is, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can function as an earth observing satellite, for example.

Although the artificial satellite is described as an example of space equipment in this embodiment, the present invention is not limited thereto. For example, the semiconductor device of one embodiment of the present invention can be suitably used for space equipment such as a spacecraft, a space capsule, and a space probe.

As described above, an OS transistor has excellent effects of achieving a wide memory bandwidth and being highly resistant to radiation as compared with a Si transistor.

### [Data Center]

The semiconductor device of one embodiment of the present invention can be suitably used for, for example, a storage system in a data center. The long-term data management needs increasing the scale of the data center, such as installing a storage and a server for storing an enormous amount of data, ensuring a stable power source for data retention, and ensuring cooling equipment required for data retention.

With use of the memory device of one embodiment of the present invention for the storage system used in the data center, electric power required for data retention can be reduced and a memory device retaining data can be downsized. Accordingly, downsizing of the storage system, downsizing of a power source for data retention, downscaling of cooling equipment, and the like can be achieved. Therefore, space saving of the data center can be achieved.

In addition, since the memory device of one embodiment of the present invention has low power consumption, heat generation from a circuit can be reduced. Accordingly, it is possible to reduce adverse effects of the heat generation on the circuit itself, a peripheral circuit, and a module. Furthermore, the use of the memory device of one embodiment of the present invention enables a data center that operates stably even in a high-temperature environment. Thus, the reliability of the data center can be increased.

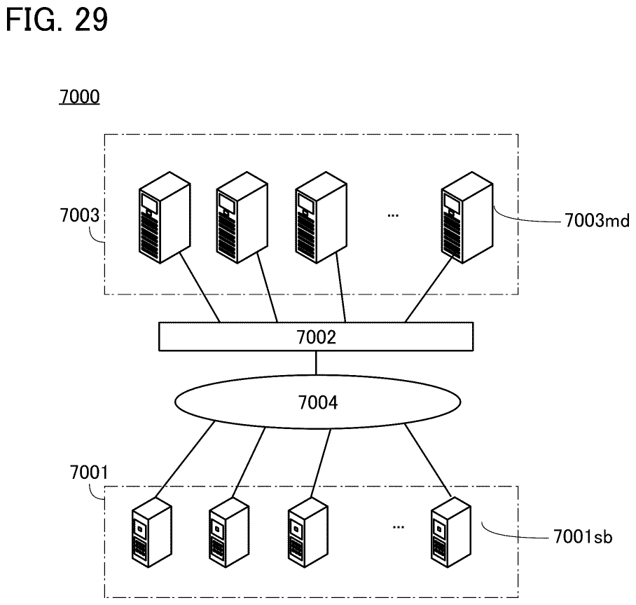

FIG. 29 illustrates a storage system that can be used in a data center. A storage system 7000 illustrated in FIG. 29 includes a plurality of servers 7001sb as a host 7001. The storage system 7000 also includes a plurality of memory devices 7003md as a storage 7003. In the illustrated mode, the host 7001 and the storage 7003 are connected through a storage area network 7004 and a storage control circuit 7002.

The host 7001 corresponds to a computer that accesses data stored in the storage 7003. The host 7001 may be connected to another host 7001 through a network.

The data access speed, i.e., the time taken for storing and outputting data, of the storage 7003 is shortened by using a flash memory, but is considerably longer than the data access speed of a DRAM that can be used as a cache memory in the storage. In the storage system, in order to solve the problem of low access speed of the storage 7003, a cache memory is normally provided in the storage to shorten the time taken for data storage and output.

The above-described cache memory is used in the storage control circuit 7002 and the storage 7003. The data transmitted between the host 7001 and the storage 7003 is stored in the cache memories in the storage control circuit 7002 and the storage 7003 and then output to the host 7001 or the storage 7003.

The use of an OS transistor as a transistor for storing data in the cache memory to retain a potential based on data can reduce the frequency of refreshing, so that power consumption can be reduced. Furthermore, downsizing is possible by stacking memory cell arrays.

The use of the semiconductor device of one embodiment of the present invention for one or more selected from an electronic component, an electronic appliance, a large computer, space equipment, and a data center can be expected to produce an effect of reducing power consumption. Although demand for energy will increase with increasing performance and integration degree of semiconductor devices, the use of the semiconductor device of one embodiment of the present invention can thus reduce the emission amount of greenhouse gas typified by carbon dioxide (CO₂). Furthermore, the semiconductor device of one embodiment of the present invention has low power consumption and thus is effective as a global warming countermeasure.

The configurations, structures, methods, and the like described in this embodiment can be used in combination as appropriate with the configurations, structures, methods, and the like described in the other embodiments.

### Embodiment 4

In this embodiment, application examples of the memory device of one embodiment of the present invention will be described.

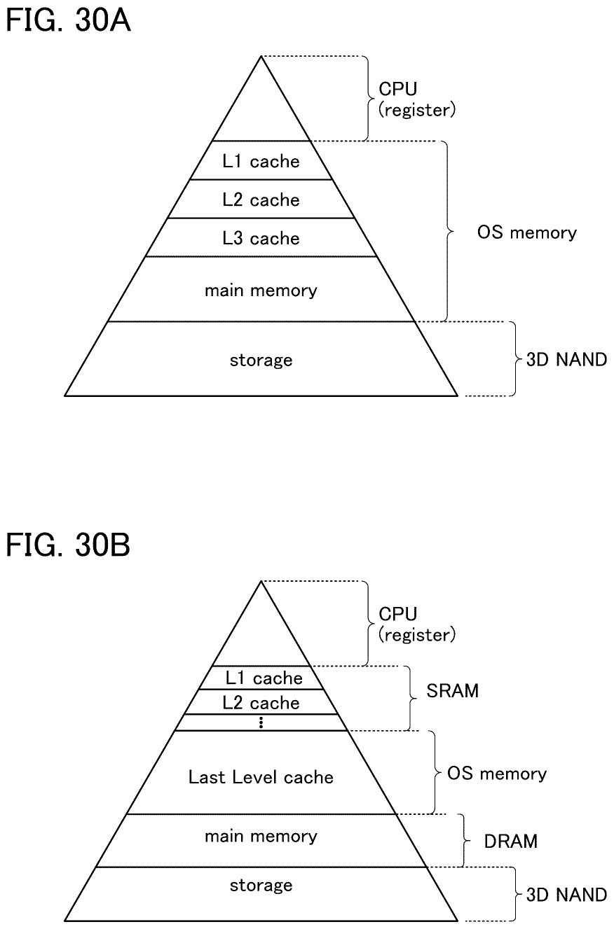

In general, a variety of memory devices are used in semiconductor devices such as computers in accordance with the intended use. FIG. 30A illustrates the hierarchy of various memory devices used in a semiconductor device. The memory devices at the upper levels require a higher operating speed, whereas the memory devices at the lower levels require a larger memory capacity and a higher memory density. FIG. 30A shows, sequentially from the top level, a memory included as a register circuit (register) in an arithmetic processing device such as a CPU, an L1 cache memory (L1 cache), an L2 cache memory (L2 cache), an L3 cache memory (L3 cache), a main memory, a storage, and the like. Although the cache memories to the L3 cache memory are included in this example, a lower-level cache memory may also be included.

A memory included as a register circuit in an arithmetic processing device such as a CPU is used for temporary storage of arithmetic operation results, for example, and thus is very frequently accessed by the arithmetic processing device. Accordingly, a high operating speed is required rather than a large memory capacity. The register circuit also has a function of retaining setting information of the arithmetic processing device, for example.

The cache memory has a function of duplicating part of data held in the main memory and retaining the duplicated data. Duplicating frequently used data and retaining the duplicated data in the cache memory facilitates rapid data access. The cache memory requires a smaller memory capacity than the main memory but a higher operating speed than the main memory. Data that is rewritten in the cache memory is duplicated, and the duplicated data is supplied to the main memory.

The main memory has a function of retaining a program, data, and the like that are read from the storage.

The storage has a function of retaining data that needs to be retained for a long time and a variety of programs used in an arithmetic processing device, for example. Therefore, the storage requires a large memory capacity and a high memory density rather than a high operating speed. For example, a large-capacity nonvolatile memory device, such as a 3D NAND, can be used.

A memory device using a metal oxide (an OS memory) according to one embodiment of the present invention has a high operating speed and enables long-term data retention. Thus, as illustrated in FIG. 30A, the memory device of one embodiment of the present invention can be suitably used at both the level where the cache memory is located and the level where the main memory is located. The memory device of one embodiment of the present invention can also be used at the level where the storage is located.

FIG. 30B illustrates an example in which an SRAM (Static RAM) is used as some of the cache memories and the OS memory of one embodiment of the present invention is used as the other cache memory.

The lowest-level cache memory can be referred to as an LCC (Last Level cache). The LLC does not require a higher operating speed than higher-level cache memories, but desirably has a large memory capacity. The OS memory of one embodiment of the present invention has a high operating speed and enables long-term data retention, and thus can be suitably used as the LLC. Note that the OS memory of one embodiment of the present invention can also be used as an FLC (Final Level cache).

For example, as illustrated in FIG. 30B, an SRAM can be used as higher-level cache memories (the L1 cache memory, the L2 cache memory, and the like), and the OS memory of one embodiment of the present invention can be used as the LLC. Moreover, not only the OS memory but also a DRAM can be used as the main memory, as illustrated in FIG. 30B.

The configurations, structures, methods, and the like described in this embodiment can be used in combination as appropriate with the configurations, structures, methods, and the like described in the other embodiments.

### (Supplementary Notes on the Description in This Specification and the Like)

The description of the above embodiments and each configuration in the embodiments are noted below.

One embodiment of the present invention can be constituted by appropriately combining the configuration described in each embodiment with the configurations described in the other embodiments. In addition, in the case where a plurality of configuration examples are described in one embodiment, the configuration examples can be combined as appropriate.

Note that content (or part of the content) described in one embodiment can be applied to, combined with, or replaced with another content (or part of the content) described in the embodiment and/or content (or part of the content) described in another embodiment or other embodiments, for example.

Note that in each embodiment, content described in the embodiment is content described using a variety of diagrams or content described with text disclosed in the specification.

Note that by combining a diagram (or part thereof) described in one embodiment with another part of the diagram, a different diagram (or part thereof) described in the embodiment, and/or a diagram (or part thereof) described in another embodiment or other embodiments, much more diagrams can be formed.

In this specification and the like, components are classified on the basis of the functions and shown as blocks independent of one another in block diagrams. However, for example, in an actual circuit, it is sometimes difficult to separate components on the basis of the functions, and there is such a case where one circuit is associated with a plurality of functions or a case where a plurality of circuits are associated with one function. Therefore, blocks in the block diagrams are not limited by the components described in this specification, and the description can be changed appropriately depending on the situation.

In the drawings, the size, the layer thickness, or the region is shown with given magnitude for description convenience. Therefore, the size, the layer thickness, or the region is not limited to the illustrated scale. Note that the drawings are schematically shown for clarity, and embodiments of the present invention are not limited to shapes, values, or the like shown in the drawings. For example, variation in signal, voltage, or current due to noise or variation in signal, voltage, or current due to difference in timing can be included.

In this specification and the like, expressions “one of a source and a drain” (or a first electrode or a first terminal) and “the other of the source and the drain” (or a second electrode or a second terminal) are used in the description of the connection relationship of a transistor. This is because the source and the drain of the transistor change depending on the structure, operating conditions, or the like of the transistor. Note that the source or the drain of the transistor can also be referred to as a source (drain) terminal, a source (drain) electrode, or the like as appropriate depending on the situation.

In this specification and the like, the term “electrode” or “wiring” does not limit the function of the component. For example, an “electrode” is used as part of a “wiring” in some cases, and vice versa. Furthermore, the term “electrode” or “wiring” also includes the case where a plurality of “electrodes” or “wirings” are formed in an integrated manner, for example.

In this specification and the like, “voltage” and “potential” can be interchanged with each other as appropriate. The term “voltage” refers to a potential difference from a reference potential, and when the reference potential is a ground voltage, for example, the voltage can be rephrased as the potential. The ground potential does not necessarily mean 0 V. Note that potentials are relative values, and a potential applied to a wiring, for example, is sometimes changed depending on the reference potential.

Note that in this specification and the like, the terms “film” and “layer” can be interchanged with each other depending on the case or according to circumstances. For example, the term “conductive layer” can be replaced with the term “conductive film” in some cases. For another example, the term “insulating film” can be replaced with the term “insulating layer” in some cases.

In this specification and the like, a switch has a function of controlling whether current flows or not by being in a conducting state (an on state) or a non-conducting state (an off state). Alternatively, a switch refers to an element having a function of selecting and changing a current path.

In this specification and the like, channel length refers to, for example, the distance between a source and a drain in a region where a semiconductor (or a portion where current flows in a semiconductor when a transistor is in an on state) and a gate overlap each other or a region where a channel is formed in a top view of the transistor.

In this specification and the like, channel width refers to, for example, the length of a portion where a source and a drain face each other in a region where a semiconductor (or a portion where current flows in a semiconductor when a transistor is in an on state) and a gate electrode overlap each other or a region where a channel is formed.

In this specification and the like, the expression “A and B are connected” means the case where A and B are electrically connected as well as the case where A and B are directly connected. Here, the expression “A and B are electrically connected” means the case where electric signals can be transmitted and received between A and B when an object having any electric action is present between A and B.

### EXAMPLE

In this example, evaluation results of a fabricated memory device will be described.

In the memory device fabricated in this example, memory cells employing the structures illustrated in FIG. 11A, FIG. 11B, and FIG. 14A to FIG. 14D were arranged in a matrix to form a memory cell array. Here, for example, the wiring 63 illustrated in FIG. 14A employed the structure illustrated in FIG. 14E. The transistor 43 and the transistor 44 included in the memory cell were OS transistors.

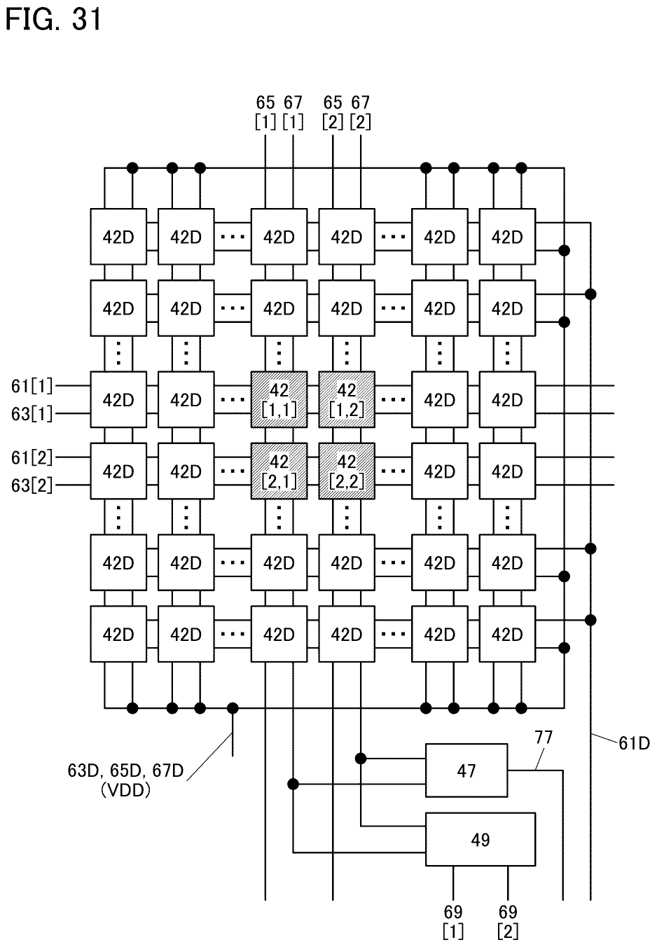

In this example, a TEG (Test Element Group) device including the above memory cell array was fabricated. FIG. 31 is a block diagram illustrating a structure of the TEG device. In the TEG device, 128 rows and 128 columns of memory cells were arranged in a matrix. Here, the memory cells in the 64th row and the 64th column, the 64th row and the 65th column, the 65th row and the 64th column, and the 65th row and the 65th column were respectively referred to as a memory cell 42[1,1], a memory cell 42[1,2], a memory cell 42[2,1], and a memory cell 42[2,2]. The other memory cells were referred to as memory cells 42D. The circuit structure illustrated in FIG. 11A and FIG. 11B was employed as the circuit structure of the memory cell 42[1,1], the memory cell 42[1,2], the memory cell 42[2,1], the memory cell 42[2,2], and the memory cells 42D. A precharge circuit 47 and a source follower circuit 49 were provided in the TEG device.

To the memory cell 42[1,1], the memory cell 42[1,2], and the memory cells 42D in the 64th row, a wiring 61[1] was electrically connected as the wiring 61, and a wiring 63[1] was electrically connected as the wiring 63. To the memory cell 42[2,1], the memory cell 42[2,2], and the memory cells 42D in the 65th row, a wiring 61[2] was electrically connected as the wiring 61, and a wiring 63[2] was electrically connected as the wiring 63. To the memory cells 42D in the first to 63th rows and the 66th to 128th rows, a wiring 61D was electrically connected as the wiring 61, and a wiring 63D was electrically connected as the wiring 63. The potential VDD was supplied as a high potential to the wiring 63D.

To the memory cell 42[1,1], the memory cell 42[2,1], and the memory cells 42D in the 64th column, a wiring 65[1] was electrically connected as the wiring 65, and a wiring 67[1] was electrically connected as the wiring 67. To the memory cell 42[1,2], the memory cell 42[2,2], and the memory cells 42D in the 65th column, a wiring 65[2] was electrically connected as the wiring 65, and a wiring 67[2] was electrically connected as the wiring 67. To the memory cells 42D in the first to 63th columns and the 66th to 128th columns, a wiring 65D was electrically connected as the wiring 65, and a wiring 67D was electrically connected as the wiring 67. The potential VDD was supplied to the wiring 65D and the wiring 67D as in the case of the wiring 63D.

The wiring 67[1] and the wiring 67[2] were electrically connected to the precharge circuit 47 and the source follower circuit 49. A wiring 77 was electrically connected to the precharge circuit 47. A wiring 29[1] and a wiring 29[2] were electrically connected to the source follower circuit 49.

The precharge circuit 47 has a function of controlling precharge to perform before data reading from the wiring 67[1] and the wiring 67[2]. Specifically, the precharge circuit 47 has a function of supplying the potential of the wiring 77 to the wiring 67[1] and the wiring 67[2] at the time of performing precharge. The source follower circuit 49 has a function of outputting, to the wiring 29[1], data input from the wiring 67[1] and outputting, to the wiring 29[2], data input from the wiring 67[2].

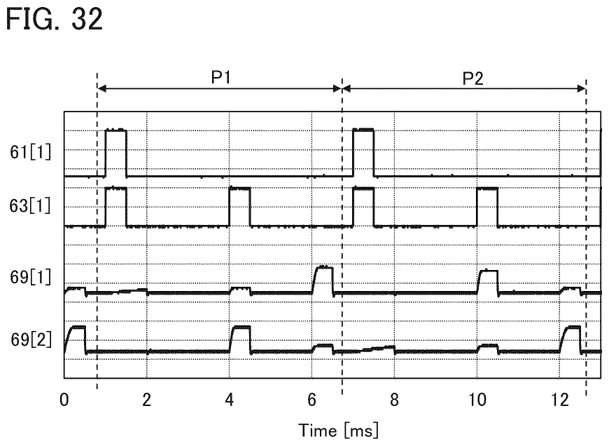

FIG. 32 is a timing chart showing changes over time in the potentials of the wiring 61[1], the wiring 63[1], the wiring 29[1], and the wiring 29[2]. In FIG. 32, the horizontal axis represents elapsed time [ms]. The vertical axis represents a potential with a scale of 1 V per mark. In this example, data was written to and read from the memory cell 42[1,1], the memory cell 42[1,2], the memory cell 42[2,1], and the memory cell 42[2,2] in a period P1, and then data was written and read in a similar manner in a period P2.

In the period P1, first, the potentials of the wiring 61[1] and the wiring 63[1] were each set to a high potential, and the potentials of the wiring 61[2] and the wiring 63[2] were each set to a low potential. The potential of the wiring 65[1] was set to a low potential, and the potential of the wiring 65[2] was set to a high potential. Accordingly, digital data with a value “0” was written to the memory cell 42[1,1], and digital data with a value “1” was written to the memory cell 42[1,2].

Next, the potentials of the wiring 61[1] and the wiring 63[1] were each set to a low potential, and then the potentials of the wiring 61[2] and the wiring 63[2] were each set to a high potential. The potential of the wiring 65[1] was set to a high potential, and the potential of the wiring 65[2] was set to a low potential. Accordingly, digital data with a value “1″ was written to the memory cell 42[2,1], and digital data with a value ”0″ was written to the memory cell 42[2,2].

Subsequently, the potentials of the wiring 61[2] and the wiring 63[2] were each set to a low potential, and then the potential of the wiring 63[1] was set to a high potential. Accordingly, the data written to the memory cell 42[1,1] and the data written to the memory cell 42[1,2] were read. The data read from the memory cell 42[1,1] was output to the wiring 29[1], and the data read from the memory cell 42[1,2] was output to the wiring 29[2].

Next, the potential of the wiring 63[1] was set to a low potential, and then the potential of the wiring 63[2] was set to a high potential. Accordingly, the data written to the memory cell 42[2,1] and the data written to the memory cell 42[2,2] were read. The data read from the memory cell 42[2,1] was output to the wiring 29[1], and the data read from the memory cell 42[2,2] was output to the wiring 29[2].

After that, the potential of the wiring 63[2] was set to a low potential. The above is the operation of the period P1.

In the period P2, changes in the potentials of the wiring 61[1], the wiring 61[2], the wiring 63[1], and the wiring 63[2] were similar to those in the period P1. Thus, in the period P2, data was written to and read from the memory cell 42[1,1], the memory cell 42[1,2], the memory cell 42[2,1], and the memory cell 42[2,2] as in the period P1. Here, in the period P2, digital data with a value “1″ was written to the memory cell 42[1,1] and the memory cell 42[2,2], and digital data with a value ”0″ was written to the memory cell 42[1,2] and the memory cell 42[2,1]. That is, the data written to the memory cell 42[1,1], the memory cell 42[1,2], the memory cell 42[2,1], and the memory cell 42[2,2] in the period P2 were digital data obtained by inverting the values of the data written respectively to the memory cell 42[1,1], the memory cell 42[1,2], the memory cell 42[2,1], and the memory cell 42[2,2] in the period P1.

As shown in FIG. 32, it was demonstrated that in all of the memory cell 42[1,1], the memory cell 42[1,2], the memory cell 42[2,1], and the memory cell 42[2,2], the potential of the wiring 69[1] or the wiring 69[2] became a low potential when the digital data with a value “O” was read, and the potential of the wiring 69[1] or the wiring 69[2] became a high potential when the digital data with a value “1” was read. This demonstrated that the TEG fabricated in this example operated normally. Specifically, it was demonstrated that data written to the memory cells can be read correctly.

In this example, a 32-kB memory device was fabricated. The probability of data with the written value being read out (the rate of correct bits) was evaluated by writing data to the memory cells included in the memory device and then reading the data every predetermined time. Here, in data writing, a high potential was applied to the wiring 61 and a low potential was applied to the wiring 63 in FIG. 11A and FIG. 11B, for example. In data reading, a low potential was applied to the wiring 61 and a high potential was applied to the wiring 63. Note that the data writing time and the data reading time were each 285 ns. The temperature was room temperature.

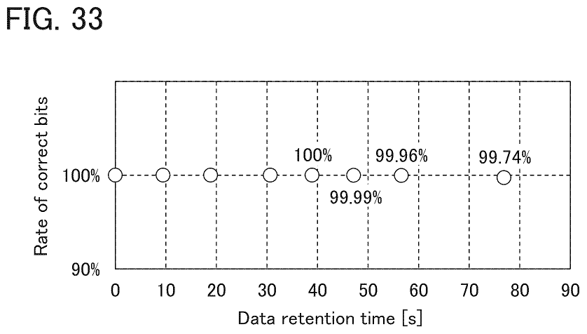

FIG. 33 is a graph showing the rate of correct bits against data retention time (time elapsed from the end of data writing). As shown in FIG. 33, it was demonstrated that the data retention time was 100% and no error bit occurred when the data retention time was 38 s or less. It was also demonstrated that a high rate of correct bits of 99.7% or more was maintained even when the data retention time exceeds 38 s.

In this example, a memory device including a CPU and memory cells over the CPU was fabricated as a chip. The CPU employed a structure including the transistor 57 and the transistor 54 over the transistor 57 illustrated in FIG. 18. The memory cells employed a structure including the transistor 43 and the transistor 44 over the transistor 54. The wiring 63 included in the transistor 43 employed the structure illustrated in FIG. 14E.

The transistor 57 was a Si transistor with a channel length of 130 nm. The transistor 54 was a planar OS transistor with a channel length of 200 nm. The transistor 43 and the transistor 44 were each a vertical OS transistor with a channel length of 95 nm. The planar shape of each of the opening portion 190 and the opening portion 290 is a circle with a diameter of 60 nm.

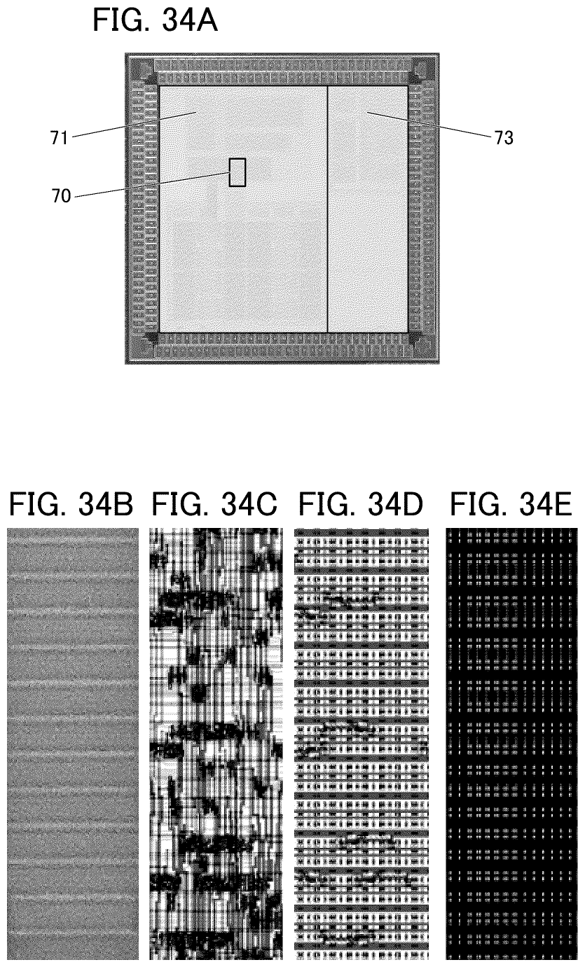

FIG. 34A is a photograph showing a planar layout of the chip. The chip fabricated in this example includes a region 71 including the CPU and the memory cells and a region 73 including a power supply circuit.

FIG. 34B is an enlarged photograph of a region 70 shown in FIG. 34A. As shown in FIG. 34A, the region 70 is included in the region 71.

FIG. 34C is a photograph that selectively shows a layer including the transistor 57, which is a Si transistor, from FIG. 34B. FIG. 34D is a photograph that selectively shows a layer including the transistor 54, which is a planar OS transistor, from FIG. 34B. FIG. 34E is a photograph that selectively shows a layer including the transistor 43, which is a vertical OS transistor, and a layer including the transistor 44, which is a vertical OS transistor, from FIG. 34B.

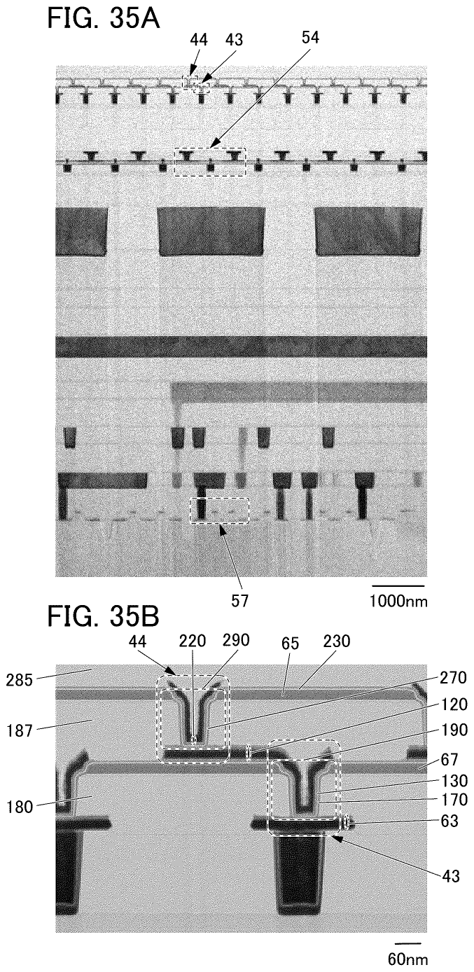

FIG. 35A is a scanning transmission electron microscopy (STEM) image of the chip. As shown in FIG. 35A, it was demonstrated that the transistor 57, which is a Si transistor, the transistor 54, which is a planar OS transistor, and the transistor 43 and the transistor 44, which are vertical OS transistors, can be formed in desired shapes.

FIG. 35B is an enlarged STEM image of a region including the transistor 43 and the transistor 44 shown in FIG. 35A. Note that an insulating layer 187 in FIG. 35B corresponds to the insulating layer 185 and the insulating layer 280 illustrated in FIG. 18.

As shown in FIG. 35B, it was demonstrated that in the transistor 43, the opening portion 190 reaching the wiring 63 was formed in the insulating layer 180 and the wiring 67, and the semiconductor layer 170, the insulating layer 130, and the conductive layer 120 were formed to include a region positioned in the opening portion 190. It was also demonstrated that in the transistor 44, the opening portion 290 reaching the conductive layer 120 was formed in the insulating layer 187 and the wiring 65, and the semiconductor layer 270, the insulating layer 230, and the conductive layer 220 were formed to include a region positioned in the opening portion 290. It was also demonstrated that the top surface of the conductive layer 120 and the bottom surface of the semiconductor layer 270 were in contact with each other in the opening portion 290.

### REFERENCE NUMERALS

10: semiconductor device, 20: layer, 21A: CPU, 21: CPU, 22a: word line driver circuit, 22b: word line driver circuit, 22c: bit line driver circuit, 22d: bit line driver circuit, 22e: switch driver circuit, 22: driver circuit, 23: control circuit, 24A: clock buffer circuit, 24: flip-flop circuit, 25: arithmetic circuit, 26: cache memory, 27: memory controller, 30: layer, 34: backup circuit, 40_1: layer, 40_2: layer, 40_3: layer, 40: layer, 41_1: memory cell array, 41_11: memory cell array, 41_12: memory cell array, 41_2: memory cell array, 41_21: memory cell array, 41_22: memory cell array, 41: memory cell array, 42[1,1]: memory cell, 42[1,2]: memory cell, 42[2,1]: memory cell, 42[2,2]: memory cell, 42_1: memory cell, 42_11: memory cell, 42_12: memory cell, 42_2: memory cell, 42_21: memory cell, 42_22: memory cell, 42D: memory cell, 42: memory cell, 43: transistor, 44: transistor, 45: capacitor, 47: precharge circuit, 49: source follower circuit, 50: register circuit, 51: switch circuit group, 52a: switch circuit, 52a[1]: switch circuit, 52a[i]: switch circuit, 52a[m]: switch circuit, 52b: switch circuit, 52b[1]: switch circuit, 52b[i]: switch circuit, 52b[m]: switch circuit, 52c: switch circuit, 52c[1]: switch circuit, 52c[j]: switch circuit, 52c[n]: switch circuit, 52d: switch circuit, 52d[1]: switch circuit, 52d[j]: switch circuit, 52d[n]: switch circuit, 52: switch circuit, 53_1: circuit, 53_11: circuit, 53_12: circuit, 53_2: circuit, 53_21: circuit, 53_22: circuit, 53: circuit, 54_1: transistor, 54_11: transistor, 54_12: transistor, 54_2: transistor, 54_21: transistor, 54_22: transistor, 54: transistor, 55_1: transistor, 55_11: transistor, 55_12: transistor, 55_2: transistor, 55_21: transistor, 55_22: transistor, 55: transistor, 56_1: capacitor, 56_11: capacitor, 56_12: capacitor, 56_2: capacitor, 56_21: capacitor, 56_22: capacitor, 56: capacitor, 57: transistor, 61[1]: wiring, 61[2]: wiring, 61_1: wiring, 61_2: wiring, 61D: wiring, 61: wiring, 62[i]: wiring, 62: wiring, 63[1]: wiring, 63[2]: wiring, 63_1: wiring, 63_2: wiring, 63D: wiring, 63: wiring, 64[i]: wiring, 64: wiring, 65[1]: wiring, 65[2]: wiring, 65_1: wiring, 65_11: wiring, 65_12: wiring, 65_2: wiring, 65_21: wiring, 65_22: wiring, 65D: wiring, 65: wiring, 66[j]: wiring, 66: wiring, 67[1]: wiring, 67[2]: wiring, 67_1: wiring, 67_11: wiring, 67_12: wiring, 67_2: wiring, 67_21: wiring, 67_22: wiring, 67D: wiring, 67: wiring, 68[j]: wiring, 68: wiring, 69[1]: wiring, 69[2]: wiring, 70: region, 71: region, 73: region, 77: wiring, 120: conductive layer, 130: insulating layer, 160: insulating layer, 170: semiconductor layer, 180: insulating layer, 185: insulating layer, 187: insulating layer, 190: opening portion, 220: conductive layer, 230: insulating layer, 270i: region, 270na: region, 270nb: region, 270: semiconductor layer, 280: insulating layer, 285: insulating layer, 287: insulating layer, 290: opening portion, 301: insulating layer, 310: wiring, 311: substrate, 313: semiconductor region, 314a: low-resistance region, 314b: low-resistance region, 315: insulating layer, 316: conductive layer, 317: insulating layer, 320: conductive layer, 321: insulating layer, 324: insulating layer, 326: insulating layer, 328: conductive layer, 330: insulating layer, 331: conductive layer, 350: insulating layer, 352: insulating layer, 356: conductive layer, 357: insulating layer, 380: insulating layer, 385: insulating layer, 390: opening portion, 420: conductive layer, 430: insulating layer, 460: insulating layer, 463: conductive layer, 467: conductive layer, 470: semiconductor layer, 480: insulating layer, 485: insulating layer, 487: insulating layer, 700: electronic component, 702: printed circuit board, 704: circuit board, 710: semiconductor device, 711: mold, 712: land, 713: electrode pad, 714: wire, 715: driver circuit layer, 716: memory layer, 730: electronic component, 731: interposer, 732: package substrate, 733: electrode, 735: semiconductor device, 800: transistor, 805a: conductive layer, 805b: conductive layer, 805: conductive layer, 815: insulating layer, 816: insulating layer, 820: semiconductor layer, 821: insulating layer, 822: insulating layer, 824: insulating layer, 842a: conductive layer, 842b: conductive layer, 850: insulating layer, 855: insulating layer, 860a: conductive layer, 860b: conductive layer, 860: conductive layer, 871a: insulating layer, 871b: insulating layer, 875: insulating layer, 882: insulating layer, 883: insulating layer, 885: insulating layer, 887: insulating layer, 891: conductive layer, 892: conductive layer, 893: conductive layer, 895: conductive layer, 896: conductive layer, 897: conductive layer, 898: conductive layer, 899: conductive layer, 901: conductive layer, 930: layer, 960: layer, 970A: semiconductor device, 970B: semiconductor device, 5600: large computer, 5610: rack, 5620: computer, 5621: PC card, 5622: board, 5623: connection terminal, 5624: connection terminal, 5625: connection terminal, 5626: semiconductor device, 5627: semiconductor device, 5628: semiconductor device, 5629: connection terminal, 5630: motherboard, 5631: slot, 6500: electronic appliance, 6501: housing, 6502: display portion, 6503: power button, 6504: button, 6505: speaker, 6506: microphone, 6507: camera, 6508: light source, 6509: control device, 6600: electronic appliance, 6611: housing, 6612: keyboard, 6613: pointing device, 6614: external connection port, 6615: display portion, 6616: control device, 6800: artificial satellite, 6801: body, 6802: solar panel, 6803: antenna, 6804: planet, 6805: secondary battery, 6807: control device, 7000: storage system, 7001sb: server, 7001: host, 7002: storage control circuit, 7003md: memory device, 7003: storage

1. A semiconductor device comprising:
a CPU;
a switch circuit;
a first memory cell array; and
a second memory cell array,
wherein the CPU comprises a control circuit and a register circuit,
wherein the register circuit comprises a flip-flop circuit and a backup circuit,
wherein first memory cells are arranged in a matrix in the first memory cell array,
wherein second memory cells are arranged in a matrix in the second memory cell array,
wherein the control circuit and the flip-flop circuit are provided in a first layer,
wherein the switch circuit and the backup circuit are provided in a second layer over the first layer,
wherein the first memory cell array and the second memory cell array are provided in a third layer over the second layer,
wherein the switch circuit is configured to supply a signal to one of the first memory cell and the second memory cell,
wherein the control circuit and the flip-flop circuit each comprise a transistor comprising silicon in a channel formation region, and
wherein the switch circuit and the backup circuit each comprise a transistor comprising a metal oxide in a channel formation region.

2. The semiconductor device according to claim 1,
the switch circuit further comprising:
a first transistor;
a second transistor;
a third transistor; and
a fourth transistor,
wherein the signal is supplied to one of a source and a drain of the first transistor and one of a source and a drain of the second transistor,
wherein a gate of the first transistor is electrically connected to one of a source and a drain of the third transistor,
wherein a gate of the second transistor is electrically connected to one of a source and a drain of the fourth transistor,
wherein a first selection signal is supplied to the other of the source and the drain of the third transistor,
wherein a second selection signal is supplied to the other of the source and the drain of the fourth transistor,
wherein the signal is output from the other of the source and the drain of the first transistor or the other of the source and the drain of the second transistor based on the first selection signal and the second selection signal,
wherein when the signal is output from the other of the source and the drain of the first transistor, the signal is supplied to the first memory cell, and
wherein when the signal is output from the other of the source and the drain of the second transistor, the signal is supplied to the second memory cell.

3. The semiconductor device according to claim 2,
the switch circuit further comprising:
a first capacitor; and
a second capacitor,
wherein one electrode of the first capacitor is electrically connected to the gate of the first transistor,
wherein the other electrode of the first capacitor is electrically connected to the other of the source and the drain of the first transistor,
wherein one electrode of the second capacitor is electrically connected to a gate of the third transistor, and
wherein the other electrode of the second capacitor is electrically connected to the other of the source and the drain of the third transistor.

4. The semiconductor device according to claim 1,
wherein the first memory cell comprises a fifth transistor,
wherein the second memory cell comprises a sixth transistor, and
wherein the fifth transistor and the sixth transistor each comprise a metal oxide in a channel formation region.

5. The semiconductor device according to claim 4,
wherein the third layer comprises an insulating layer,
wherein the insulating layer comprises a first opening portion and a second opening portion,
wherein the channel formation region of the fifth transistor comprises a region along a side surface of the first opening portion, and
wherein the channel formation region of the sixth transistor comprises a region along a side surface of the second opening portion.

6. A semiconductor device comprising:
a CPU;
a switch circuit;
a first memory cell array; and
a second memory cell array,
wherein the CPU comprises a control circuit and a register circuit,
wherein the register circuit comprises a flip-flop circuit and a backup circuit,
wherein first memory cells are arranged in a matrix in the first memory cell array,
wherein second memory cells are arranged in a matrix in the second memory cell array,
wherein the first memory cell comprises a first transistor and a second transistor,
wherein the second memory cell comprises a third transistor and a fourth transistor,
wherein the control circuit and the flip-flop circuit are provided in a first layer,
wherein the switch circuit and the backup circuit are provided in a second layer over the first layer,
wherein the first transistor and the third transistor are provided in a third layer over the second layer,
wherein the second transistor and the fourth transistor are provided in a fourth layer over the third layer,
wherein the switch circuit is configured to supply a signal to one of the first memory cell and the second memory cell,
wherein the control circuit and the flip-flop circuit each comprise a transistor comprising silicon in a channel formation region,
wherein the switch circuit and the backup circuit each comprise a transistor comprising a metal oxide in a channel formation region, and
wherein the first transistor, the second transistor, the third transistor, and the fourth transistor each comprise a metal oxide in a channel formation region.

7. The semiconductor device according to claim 6,
the switch circuit further comprising:
a fifth transistor;
a sixth transistor;
a seventh transistor; and
an eighth transistor,
wherein the signal is supplied to one of a source and a drain of the fifth transistor and one of a source and a drain of the sixth transistor,
wherein a gate of the fifth transistor is electrically connected to one of a source and a drain of the seventh transistor,
wherein a gate of the sixth transistor is electrically connected to one of a source and a drain of the eighth transistor,
wherein a first selection signal is supplied to the other of the source and the drain of the seventh transistor,
wherein a second selection signal is supplied to the other of the source and the drain of the eighth transistor,
wherein the signal is output from the other of the source and the drain of the fifth transistor or the other of the source and the drain of the sixth transistor based on the first selection signal and the second selection signal,
wherein when the signal is output from the other of the source and the drain of the fifth transistor, the signal is supplied to the first memory cell, and
wherein when the signal is output from the other of the source and the drain of the sixth transistor, the signal is supplied to the second memory cell.

8. The semiconductor device according to claim 7,
the switch circuit further comprising:
a first capacitor; and
a second capacitor,
wherein one electrode of the first capacitor is electrically connected to the gate of the fifth transistor,
wherein the other electrode of the first capacitor is electrically connected to the other of the source and the drain of the fifth transistor,
wherein one electrode of the second capacitor is electrically connected to a gate of the seventh transistor, and
wherein the other electrode of the second capacitor is electrically connected to the other of the source and the drain of the seventh transistor.

9. The semiconductor device according to claim 6,
wherein the third layer comprises a first insulating layer,
wherein the fourth layer comprises a second insulating layer,
wherein the first insulating layer comprises a first opening portion and a second opening portion,
wherein the second insulating layer comprises a third opening portion and a fourth opening portion,
wherein the channel formation region of the first transistor comprises a region along a side surface of the first opening portion,
wherein the channel formation region of the second transistor comprises a region along a side surface of the second opening portion,
wherein the channel formation region of the third transistor comprises a region along a side surface of the third opening portion, and
wherein the channel formation region of the fourth transistor comprises a region along a side surface of the fourth opening portion.

10. The semiconductor device according to claim 1
wherein the first memory cell is configured to retain first data,
wherein the second memory cell is configured to retain second data, and
wherein the first data and the second data differ in type.

11. The semiconductor device according to claim 10,
wherein the first data or the second data is program data.

12. The semiconductor device according to claim 6,
wherein the first memory cell is configured to retain first data,
wherein the second memory cell is configured to retain second data, and
wherein the first data and the second data differ in type.

13. The semiconductor device according to claim 12,
wherein the first data or the second data is program data.
